(19) United States
(12) Patent Application Publication
(10) Pub. No.: US 2015/0102859 A1
(43) Pub. Date: Apr. 16, 2015

(54) AMPLIFYING APPARATUS, COMMUNICATION APPARATUS AND AMPLIFICATION METHOD

(71) Applicant: FUJITSU LIMITED, Kawasaki-shi (JP)

(72) Inventors: TORU MANIWA, Setagaya (JP); TOSHIO KAWASAKI, Kawasaki (JP); TOMONORI SATO, Kawasaki (JP); Shigekazu Kimura, Yokohama (JP); NAOJI FUJINO, Yokohama (JP)

(21) Appl. No.: 14/482,663

(22) Filed: Sep. 10, 2014

(30) Foreign Application Priority Data
Oct. 16, 2013 (JP) 2013-215870

(51) Int. Cl. H03F 3/21; H03F 3/19

(52) U.S. Cl. CPC H03F 3/211; H03F 3/19; H03F 2200/105; H03F 2200/207
USPC 330/295

(57) ABSTRACT

An amplifying apparatus includes a decomposer, two amplifiers, a combiner, and a controller. The decomposer decomposes an input signal into two signals having different phases. The two amplifiers amplify the decomposed two signals, respectively. The combiner combines output of the amplifiers. The controller controls at least one of waveform information of at least one of the two signals and an operating state of the two amplifiers such that an output characteristic of the combiner matches a desired characteristic.

### CROSS-REFERENCE TO RELATED APPLICATION

This application is based upon and claims the benefit of priority of the prior Japanese Patent application No. 2013-215870, filed on Oct. 16, 2013, the entire contents of which are incorporated herein by reference.

### FIELD

The present invention relates to an amplifying apparatus, a communication apparatus, and an amplification method.

### BACKGROUND

An amplifying apparatus using a Chireix combiner and following an Outphasing method is known (for example, Japanese Laid-open Patent Publication No. 2007-174148; Japanese Laid-open Patent Publication No. 2008-135829; Japanese National Publication of International Patent Application No. 2009-533947; Japanese National Publication of International Patent Application No. 2012-531095; H. Chireix, “High power outphasing modulation”, Proceedings of the Institute of Radio Engineers, vol. 23, pp. 1370-1392, November 1935; and F. H. Raab, “Efficiency of outphasing RF power-amplifier systems”, IEEE Transactions on Communications, Vol. COM-33, No. 10, pp. 1094-1099, October 1985). In the Outphasing method, the amplifying apparatus decomposes an input signal into two signals having different phases. For example, when the amplitude of an input signal is 0, the amplifying apparatus decomposes the input signal into two signals having opposite phases (having a phase difference of 180 degrees) and when the amplitude of an input signal is maximum, the amplifying apparatus decomposes the input signal into two signals of the same phase (having a phase difference of 0 degrees).

Further, the amplifying apparatus amplifies the decomposed signals by two amplifiers, respectively, and combines output of each amplifier. The amplifier amplifiers signals having a fixed amplitude and so can operate with greater efficiency than when amplifying signals having a variable amplitude.

### SUMMARY

By reducing losses of a combiner combining output of each amplifier, the amplifying apparatus can be made more efficient. Thus, a lossless combiner such as a Chireix combiner may be used as the combiner in the Outphasing method.

In this case, however, the output of one amplifier influences characteristics of the other amplifier. Further, the magnitude of the influence changes depending on the amplitude of an input signal. Thus, an apparent input impedance of a circuit connected to the output side of each amplifier changes depending on the amplitude of the input signal. As a result, the output characteristic of the combiner is hardly matched to a desired characteristic.

FIG. 1 is a graph illustrating a relationship between the amplitude of an input signal and the amplitude of an output signal of a combiner. A broken line C1 in FIG. 1 represents, as an example of the desired characteristic, a characteristic in which the relationship between the amplitude of an input signal and the amplitude of an output signal is a linear relationship. A solid line C2 in FIG. 1 represents an example of the output characteristic of the combiner. As illustrated in FIG. 1, when the amplitude of the input signal is 0, the output characteristic C2 of the combiner does not yield 0 as the amplitude of the output signal. Also, the output characteristic C2 of the combiner has a nonlinear relationship as the relationship between the amplitude of the input signal and the amplitude of the output signal. In this example, the output characteristic C2 of the combiner has a square-law characteristic. The square-law characteristic is a characteristic in which the relationship between the amplitude of the input signal and the amplitude of the output signal is represented by a quadratic function. In such a case, the waveform of the output signal is distorted.

Incidentally, in the Outphasing method using a lossless combiner such as a Chireix combiner, the output of one amplifier influences the characteristic of the other amplifier. Thus, if the same decomposition method of an input signal as that of the LINC method is used, the desired amplification characteristic as indicated by the broken line C1 in FIG. 1 is hardly obtained. LINC is an abbreviation of Linear Amplification with Nonlinear Components. However, none of above documents presents a method of improving the output characteristic (amplification characteristic) of the combiner.

In one aspect, an amplifying apparatus includes a decomposer, two amplifiers, a combiner, and a controller.

The decomposer decomposes an input signal into two signals having different phases. The two amplifiers amplify the decomposed two signals, respectively. The combiner combines output of the amplifiers. The controller controls at least one of waveform information of at least one of the two signals and an operating state of the two amplifiers such that an output characteristic of the combiner matches a desired characteristic.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a graph illustrating a relationship between the amplitude of an input signal and the amplitude of an output signal of a combiner in an amplifying apparatus according to a related technology;

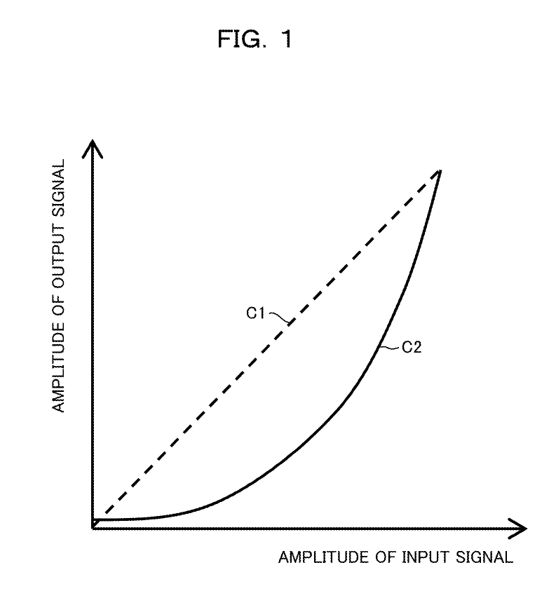

FIG. 2 is a block diagram illustrating an example of a configuration of an amplifying apparatus according to a first embodiment;

FIG. 3 is a block diagram illustrating a configuration example of an amplitude phase converter in FIG. 2;

FIG. 4 is a diagram illustrating an example of a first table held by the amplitude phase converter in FIG. 2;

FIG. 5 is a diagram illustrating an example of a relationship between phases of a first decomposed signal and a second decomposed signal and a second normalized amplitude in the amplifying apparatus in FIG. 2;

FIG. 6 is a Smith chart illustrating an example of a relationship between an electric length of a transmission line and a load impedance in the amplifying apparatus in FIG. 2;

FIG. 7 is a block diagram illustrating a configuration example of a combiner in the amplifying apparatus in FIG. 2;

FIG. 8 is a Smith chart illustrating an example of a relationship between the magnitude of a reactance of a reactive element and the load impedance in the amplifying apparatus using the combiner in FIG. 7;

FIG. 9 is a block diagram illustrating a configuration of an amplifying apparatus according to a first modified example of the first embodiment;

FIG. 10 is a block diagram illustrating a configuration of an amplifying apparatus according to a second modified example of the first embodiment;

FIG. 11 is a block diagram illustrating an example of a configuration of an amplifying apparatus according to a second embodiment;

FIG. 12 is a block diagram illustrating a configuration example of an amplitude phase converter in FIG. 11;

FIG. 13 is a diagram illustrating an example of a second table held by the amplitude phase converter in FIG. 11;

FIG. 14 is a graph illustrating an example of a relationship between a normalized output amplitude and a phase difference in the amplifying apparatus in FIG. 11;

FIG. 15 is a graph illustrating an example of a relationship between a normalized output amplitude and a phase difference in the amplifying apparatus according to the related technology;

FIG. 16 is a block diagram illustrating an example of a configuration of an amplifying apparatus according to a third embodiment;

FIG. 17 is a block diagram illustrating a configuration example of an amplitude phase converter in FIG. 16;

FIG. 18 is a diagram illustrating an example of a third table held by the amplitude phase converter in FIG. 16;

FIG. 19 is a diagram illustrating another example of the third table held by the amplitude phase converter in FIG. 16;

FIG. 20 is a block diagram illustrating another configuration example of the amplitude phase converter in FIG. 16;

FIG. 21 is a block diagram illustrating an example of a configuration of an amplifying apparatus according to a fourth embodiment;

FIG. 22 is a block diagram illustrating a configuration example of an amplitude phase converter in FIG. 21;

FIG. 23 is a block diagram illustrating a configuration of an amplifying apparatus according to a modified example of the fourth embodiment;

FIG. 24 is a block diagram illustrating a configuration example of a first output matching unit and a second output matching unit in FIG. 23;

FIG. 25 is a graph illustrating waveforms of a current and a voltage when an amplifier operates as an F-class amplifier and a harmonic processing circuit is connected;

FIG. 26 is a graph illustrating waveforms of the current and the voltage when an amplifier operates as the F-class amplifier and no harmonic processing circuit is connected;

FIG. 27 is a block diagram illustrating an example of a configuration of an amplifying apparatus according to a fifth embodiment;

FIG. 28 is a block diagram illustrating a configuration example of an amplitude phase converter in FIG. 27;

FIG. 29 is a block diagram illustrating another configuration example of the amplitude phase converter in FIG. 27;

FIG. 30 is a block diagram illustrating an example of a configuration of an amplifying apparatus according to a sixth embodiment;

FIG. 31 is a block diagram illustrating a configuration example of an amplitude phase converter in FIG. 30;

FIG. 32 is a graph illustrating an example of changes in first waveform information, second waveform information, and a normalized amplitude of the output signal on a complex plane when the first waveform information is not corrected;

FIG. 33 is a graph illustrating an example of changes in the first waveform information, the second waveform information, and the normalized amplitude of the output signal on the complex plane when the first waveform information is corrected;

FIG. 34 is a block diagram illustrating an example of a configuration of an amplifying apparatus according to a seventh embodiment;

FIG. 35 is a block diagram illustrating a configuration example of an amplitude phase converter in FIG. 34;

FIG. 36 is a block diagram illustrating a configuration example of an output characteristic estimator in FIG. 34;

FIG. 37 is a block diagram illustrating a configuration of an amplifying apparatus according to a modified example of the seventh embodiment;

FIG. 38 is a block diagram illustrating a configuration example of an amplitude phase converter in FIG. 37;

FIG. 39 is a graph illustrating an example of a relationship between a normalized output amplitude and a phase difference in an amplifying apparatus;

FIG. 40 is a block diagram illustrating a configuration example of an output characteristic estimator in FIG. 37;

FIG. 41 is a block diagram illustrating an example of a configuration of an amplifying apparatus according to an eighth embodiment;

FIG. 42 is a block diagram illustrating a configuration example of an amplitude phase converter in FIG. 41;

FIG. 43 is a block diagram illustrating an example of a configuration of an amplifying apparatus according to a ninth embodiment;

FIG. 44 is a block diagram illustrating a configuration example of an amplitude phase converter in FIG. 43;

FIG. 45 is a block diagram illustrating a configuration example of an output characteristic estimator in FIG. 43;

FIG. 46 is a block diagram illustrating a configuration of an amplifying apparatus as a modified example of the ninth embodiment;

FIG. 47 is a block diagram illustrating a configuration example of an amplitude phase converter in FIG. 46;

FIG. 48 is a block diagram illustrating a configuration example of an output characteristic estimator in FIG. 46;

FIG. 49 is a block diagram illustrating an example of a configuration of an amplifying apparatus according to a tenth embodiment;

FIG. 50 is a block diagram illustrating a configuration example of an amplitude phase converter in FIG. 49;

FIG. 51 is a block diagram illustrating a configuration of an amplifying apparatus as a modified example of the tenth embodiment;

FIG. 52 is a block diagram illustrating a configuration example of an inverse characteristic estimator in FIG. 51;

FIG. 53 is a block diagram illustrating an example of a configuration of an amplifying apparatus according to an eleventh embodiment;

FIG. 54 is a block diagram illustrating a configuration example of an amplitude phase converter in FIG. 53;

FIG. 55 is a block diagram illustrating a configuration of an amplifying apparatus according to a modified example of the eleventh embodiment;

FIG. 56 is a block diagram illustrating a configuration example of a table corrector in FIG. 55;

FIG. 57 is a block diagram illustrating an example of a configuration of an amplifying apparatus according to a twelfth embodiment;

FIG. 58 is a block diagram illustrating a configuration example of an amplitude phase converter in FIG. 57;

FIG. 59 is a block diagram illustrating an example of a configuration of an amplifying apparatus according to a thirteenth embodiment; and

FIG. 60 is a block diagram illustrating an example of a configuration of an amplifying apparatus according to a fourteenth embodiment.

### DESCRIPTION OF EMBODIMENT(S)

Hereinafter, the embodiments of the present invention will be described with reference to the drawings. However, the embodiments described below are merely examples. Thus, application of various modified examples or technologies not explicitly described below to the embodiments is not excluded. Incidentally, in the drawings used for the following embodiments, portions to which the same reference numerals are attached represent the same or similar portions unless changes or modifications are expressly provided.

### First Embodiment

### Overview

An amplifying apparatus according to the first embodiment includes a decomposer, two amplifiers, a combiner, and a controller.

The decomposer decomposes an input signal into two signals having different phases. The two amplifiers amplify the two signals decomposed by the decomposer, respectively. The combiner combines output of each of the amplifiers. The controller controls waveform information of the two signals such that an output characteristic of the combiner matches a desired characteristic.

According to the first embodiment, the output characteristic of the combiner can be matched to the desired characteristic. For example, when the amplitude of an input signal is 0, the amplitude of an output signal of the combiner can be brought closer to 0. In addition, the relationship between the amplitude of the input signal and the amplitude of the output signal can be brought closer to a linear relationship. As a result, an output characteristic (amplification characteristic) of the amplifying apparatus can be improved.

An amplifying apparatus according to the first embodiment will be described in detail below.

(Configuration)

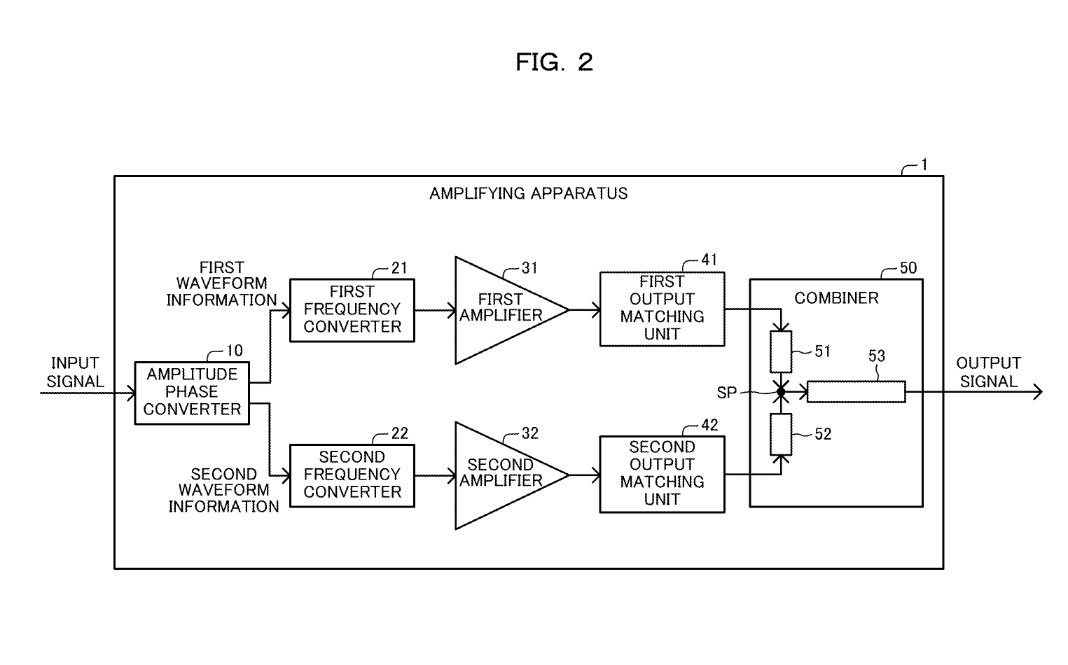

As illustrated in FIG. 2, an amplifying apparatus 1 according to the first embodiment includes an amplitude phase converter 10, a first frequency converter 21, a second frequency converter 22, a first amplifier 31, a second amplifier 32, a first output matching unit 41, a second output matching unit 42, and a combiner 50.

The amplitude phase converter 10, the first frequency converter 21, and the second frequency converter 22 are an example of the decomposer that decomposes an input signal into two signals having different phases. The amplitude phase converter 10 is also an example of the controller that controls waveform information of decomposed two signals such that the output characteristic of the combiner matches the desired characteristic.

In this example, the amplifying apparatus 1 modulates and amplifies the input signal according to the Outphasing method and outputs the amplified signal as an output signal.

For example, the input signal is a baseband modulated signal. For example, the baseband modulated signal is a signal modulated according to the modulation method such as QPSK, 16QAM, 64QAM or the like or a signal obtained by multiplexing such signals by OFDM, CDM or the like. QPSK is an abbreviation of Quadrature Phase Shift Keying. 16QAM is an abbreviation of 16 Quadrature Amplitude Modulation. 64QAM is an abbreviation of 64 Quadrature Amplitude Modulation. OFDM is an abbreviation of Orthogonal Frequency Division Multiplex. CDM is an abbreviation of Code Division Multiplex.

When an input signal is input, the amplitude phase converter 10 generates first waveform information and second waveform information based on the input signal and outputs the generated first waveform information and the generated second waveform information to the first frequency converter 21 and the second frequency converter 22 respectively. The first waveform information and the second waveform information will be described later.

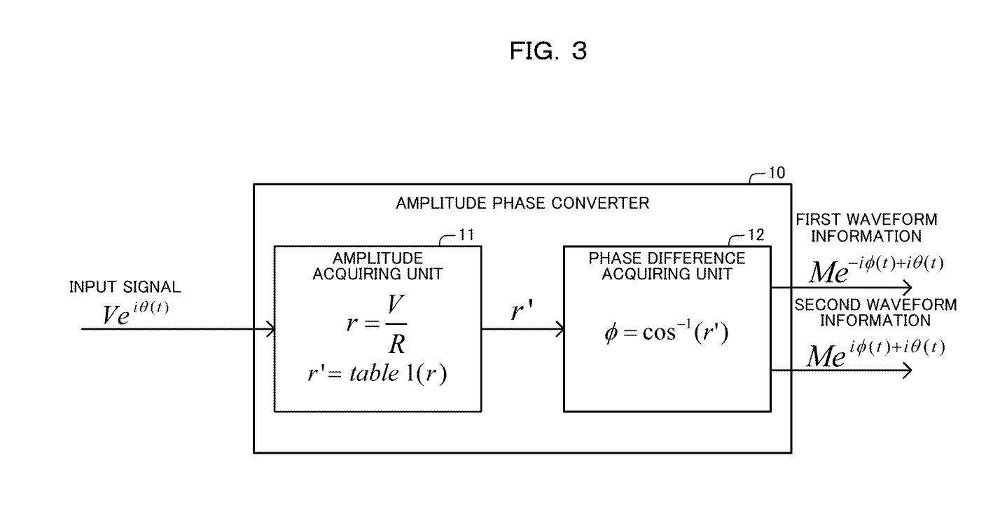

As illustrated in FIG. 3, the amplitude phase converter 10 includes an amplitude acquiring unit 11 and a phase difference acquiring unit 12.

The amplitude acquiring unit 11 acquires, based on an input signal, an amplitude (first normalized amplitude) r of the input signal normalized so that the maximum value thereof is 1.

In this example, a case in which an input signal s(t) is represented by Formula 1 is assumed.

s(t)=V(t)e^{iθ(t)} [Mathematical Formula 1]

In the above formula, V represents an actual amplitude (real amplitude) component of the input signal s(t). θ(t) represents a phase component of the input signal s(t).

When the maximum value of the real amplitude (maximum input real amplitude) of the input signal s(t) is represented by R, the amplitude acquiring unit 11 acquires the first normalized amplitude r based on Formula 2.

$$r = \frac{V}{R} \qquad [ Mathematical Formula 2 ]$$

The amplitude acquiring unit 11 holds a first table associating an amplitude before a correction and an amplitude after the correction in advance (for example, stored in a memory). The first table is set such that the output characteristic of the combiner 50 matches the desired characteristic. The desired characteristic includes, for example, a first characteristic, a second characteristic, or both. The first characteristic is a characteristic in which the amplitude of an output signal from the combiner 50 is 0 when the real amplitude of an input signal is 0. The second characteristic is a characteristic in which a relationship between the real amplitude of an input signal and the amplitude of an output signal from the combiner 50 is a linear relationship.

For example, a relationship between the first table and the output characteristic of the combiner 50 may be determined by an experiment or a simulation to set the first table based on the relationship.

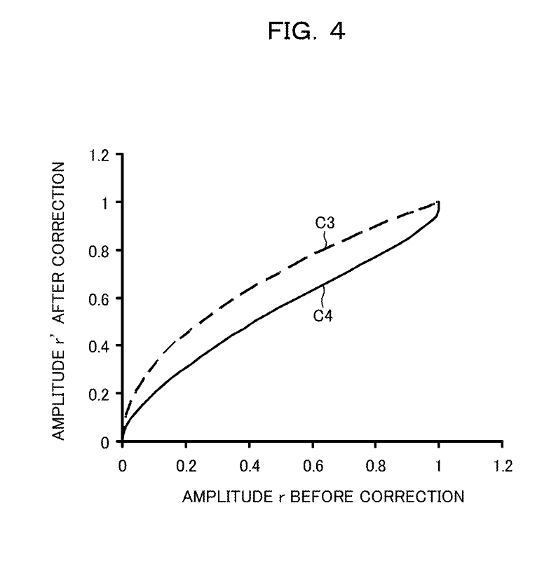

In this example, as indicated by a solid line C4 in FIG. 4, the amplitude before a correction and the amplitude after the correction are associated in the first table. The amplitude before the correction and the amplitude after the correction are associated in the first table in such a way that the amplitude after the correction monotonously increases with an increase of the amplitude before the correction. Incidentally, in the first table, the amplitude before the correction and the amplitude after the correction may be associated as indicated by a broken line C3 in FIG. 4. In this case, the broken line C3 is a curve indicating that an amplitude r′ after the correction having the same value as the square root of an amplitude r before the correction and the amplitude r before the correction are associated.

As represented in Formula 3, the amplitude acquiring unit 11 acquires, as a second normalized amplitude r′, the amplitude after the correction associated with the acquired first normalized amplitude r as the amplitude before the correction in the held first table. table1(r) represents that the first normalized amplitude r is corrected (or converted) by the first table.

r′=table1(r) [Mathematical Formula 3]

The amplitude acquiring unit 11 outputs the acquired second normalized amplitude r′ to the phase difference acquiring unit 12. The first normalized amplitude r is an example of a first amplitude and the second normalized amplitude r′ is an example of a second amplitude.

The phase difference acquiring unit 12 acquires a decomposition phase φ based on the second normalized amplitude r′ output by the amplitude acquiring unit 11. The decomposition phase φ is used, as will be described later, to generate a first decomposed signal and a second decomposed signal. In this example, the phase difference acquiring unit 12 acquires, as represented in Formula 4, an arc cosine of the second normalized amplitude r′ as the decomposition phase φ.

φ=cos⁻¹ (r′) [Mathematical Formula 4]

The phase difference acquiring unit 12 generates first waveform information and second waveform information based on the acquired decomposition phase φ and outputs the generated first waveform information to the first frequency converter 21 and also outputs the generated second waveform information to the second frequency converter 22. The first waveform information and the second waveform information are information indicating a waveform represented by the amplitude and the phase.

In this example, the first waveform information is, as represented in Formula 5, information indicating a waveform (for example, a cosine wave or a sine wave) in which the amplitude is M and the phase is represented as −φ+θ. i represents an imaginary unit. M represents an amplification factor for the first amplifier 31 and the second amplifier 32 to perform a saturated operation. The amplification factor M has a predetermined value. The saturated operation will be described later. Similarly, the second waveform information is, as represented in Formula 6, information indicating a waveform in which the amplitude is M and the phase is represented as φ+θ.

Me^{-iφ+iθ} [Mathematical Formula 5]

Me^{iφ+iθ} [Mathematical Formula 6]

In this example, therefore, the waveform indicated by the first waveform information and the waveform indicated by the second waveform information have a phase difference of a value obtained by doubling the decomposition phase φ. The phase difference matches, as will be described later, a phase difference between a first decomposed signal output by the first frequency converter 21 and a second decomposed signal output by the second frequency converter 22.

Therefore, the amplitude phase converter 10 determines the phase difference between the first decomposed signal and the second decomposed signal based on the second normalized amplitude r′ obtained by correcting the first normalized amplitude r in accordance with the first normalized amplitude r. The first waveform information and the second waveform information are an example of information containing the phase difference between the first decomposed signal and the second decomposed signal. Correcting the first normalized amplitude r by the amplitude acquiring unit 11 is an example of controlling the first waveform information and the second waveform information.

The first frequency converter 21 generates the first decomposed signal based on the first waveform information output by the amplitude phase converter 10 and the input signal. In this example, the first frequency converter 21 includes a D/A (Digital to Analog) converter (not illustrated) and generates the first decomposed signal by converting a digital signal into an analog signal.

The first frequency converter 21 outputs the generated first decomposed signal to the first amplifier 31. The first decomposed signal is one of two signals generated by a decomposition of the input signal and having mutually different phases. The decomposition may be called a vector resolution.

In this example, the first frequency converter 21 generates, as represented in Formula 7, a first decomposed signal s₁(t) based on the first waveform information and a carrier frequency f.

s₁(t)=M cos(2πft−φ(t)+θ(t)) [Mathematical Formula 7]

Similarly, the second frequency converter 22 generates the second decomposed signal based on the second waveform information output by the amplitude phase converter 10 and the input signal. In this example, the second frequency converter 22 includes a D/A converter (not illustrated) and generates the second decomposed signal by converting a digital signal into an analog signal.

The second frequency converter 22 outputs the generated second decomposed signal to the second amplifier 32. The second decomposed signal is another of two signals generated by a decomposition of the input signal and having mutually different phases and is different from the first decomposed signal. In this example, the second frequency converter 22 generates, as represented in Formula 8, a second decomposed signal s₂(t) based on the second waveform information, the carrier frequency f, and an initial phase θ.

s₂(t)=M cos(2πft+φ(t)+θ(t)) [Mathematical Formula 8]

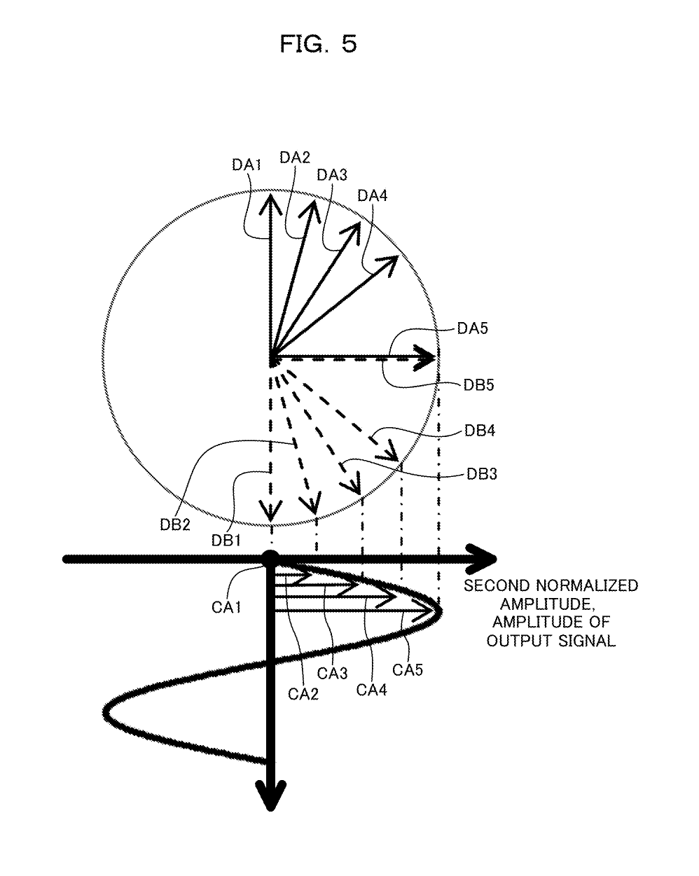

A relationship between the phases of the first decomposed signal and the second decomposed signal and the second normalized amplitude will be described with reference to FIG. 5. To simplify the description, as represented in Formula 9, a case in which an arc cosine of the first normalized amplitude r is acquired as the decomposition phase φ will be described.

φ=cos⁻¹ (r) [Mathematical Formula 9]

As indicated by a black circle CA1 in FIG. 5, when the second normalized amplitude is 0, the difference between a phase DA1 of the first decomposed signal and a phase DB1 of the second decomposed signal is 180 degrees. As indicated by an arrow CA5 in FIG. 5, when the second normalized amplitude is 1, the difference between a phase DA5 of the first decomposed signal and a phase DB5 of the second decomposed signal is 0 degrees. Similarly, the second normalized amplitudes indicated by arrows CA2 to CA4 in FIG. 5, and phases DA2 to DA4 of the first decomposed signal and phases DB2 to DB4 of the second decomposed signal correspond to each other.

In this example, the first frequency converter 21 and the second frequency converter 22 perform quadrature modulation. The first frequency converter 21 may be called a first quadrature modulator. Also, the second frequency converter 22 may be called a second quadrature modulator.

The first amplifier 31 amplifies the first decomposed signal output by the first frequency converter 21 by a first amplification factor and outputs the amplified signal (first amplified signal) to the first output matching unit 41. For example, the first amplifier 31 may be realized by using an FET (Field Effect Transistor). The first amplifier 31 may also be realized by using an amplifying element other than the FET.

In this example, the first amplifier 31 amplifies the first decomposed signal by performing the saturated operation and outputs the amplified signal. In this example, the first amplifier 31 amplifies the first decomposed signal by operating as an AB-class or B-class amplifier. The first amplifier 31 may operate as an A-class, C-class, E-class, or F-class amplifier. The operation of the first amplifier 31 as an A-class, AB-class, B-class, C-class, E-class, or F-class amplifier is an example of the saturated operation of the first amplifier 31.

The second amplifier 32 has a function similar to that of the first amplifier 31. Thus, the second amplifier 32 amplifies the second decomposed signal output by the second frequency converter 22 by a second amplification factor and outputs the amplified signal (second amplified signal) to the second output matching unit 42. In this example, the second amplifier 32 amplifies the second decomposed signal by performing the saturated operation and outputs the amplified signal. In this example, the second amplification factor is the same as the first amplification factor.

The first amplified signal is an example of an output of the first amplifier 31. Similarly, the second amplified signal is an example of an output of the second amplifier 32.

The first output matching unit 41 outputs the first amplified signal output by the first amplifier 31 to the combiner 50 by transmitting the signal thereto. The first output matching unit 41 includes a fundamental wave matching circuit that matches an output impedance of the first amplifier 31 to a default characteristic impedance for a fundamental wave component of the first amplified signal output by the first amplifier 31. The fundamental wave component is a component having the same frequency as the carrier frequency f.

The first output matching unit 41 may also contain a harmonic processing circuit that processes harmonic components of the first amplified signal. Harmonic components are components having frequencies that are integral multiples of the carrier frequency f. For example, the harmonic processing circuit shorts or opens the first amplifier 31 and the combiner 50 for harmonic components of the first amplified signal.

The second output matching unit 42 has a function similar to that of the first output matching unit 41. The second output matching unit 42 outputs the second amplified signal output by the second amplifier 32 to the combiner 50 by transmitting the signal thereto. The second output matching unit 42 includes a fundamental wave matching circuit that matches an output impedance of the second amplifier 32 to a default characteristic impedance for a fundamental wave component of the second amplified signal output by the second amplifier 32. The second output matching unit 42 may contain a harmonic processing circuit that processes harmonic components of the second amplified signal.

The combiner 50 combines the first amplified signal output by the first output matching unit 41 and the second amplified signal output by the second output matching unit 42 and outputs the combined signal as an output signal. The combination may be called a vector synthesis.

A relationship between the phases of the first amplified signal and the second amplified signal and the amplitude of the output signal will be described with reference to FIG. 5.

When the difference between the phase DA1 of the first amplified signal and the phase DB1 of the second amplified signal is 180 degrees, as indicated by the black circle CA1 in FIG. 5, the amplitude of the output signal is 0. When the difference between the phase DA5 of the first amplified signal and the phase DB5 of the second amplified signal is 0 degrees, as indicated by the arrow CA5 in FIG. 5, the amplitude of the output signal is maximum. Similarly, the phases DA2 to DA4 of the first amplified signal and the phases DB2 to DB4 of the second amplified signal, and the amplitudes of the output signals indicated by the arrows CA2 to CA4 in FIG. 5 correspond to each other.

In this example, the combiner 50 is a lossless combiner. The lossless combiner is, for example, a Chireix combiner.

The combiner 50 includes a first transmission line 51, a second transmission line 52, and an impedance converter 53.

The first transmission line 51 is a line that transmits the first amplified signal output by the first output matching unit 41. The first transmission line 51 connects the first output matching unit 41 and a combination point SP. The second transmission line 52 is a line that transmits the second amplified signal output by the second output matching unit 42.

The second transmission line 52 connects the second output matching unit 42 and the combination point SP.

An electric length (first electric length) a of the first transmission line 51 and an electric length (second electric length) β of the second transmission line 52 are set such that Formula 10 is satisfied. λ represents a wavelength of the fundamental wave component of the first amplified signal in the first transmission line 51. λ also represents a wavelength of the fundamental wave component of the second amplified signal in the second transmission line 52. The first electric length α and the second electric length β will be described later.

$$α + β = \frac{λ}{2} \qquad [ Mathematical Formula 10 ]$$

The combiner 50 combines the first amplified signal transmitted by the first transmission line 51 and the second amplified signal transmitted by the second transmission line 52 at the combination point SP.

The impedance converter 53 transmits the combined signal at the combination point SP. The impedance converter 53 adjusts an output impedance of the combiner 50. For example, the impedance converter 53 may adjust the output impedance of the combiner 50 from 25Ω to 50Ω. The combiner 50 outputs the signal, which is transmitted by the impedance converter 53, as the output signal.

Here, the first electric length α and the second electric length β will be described.

A case in which the first amplified signal output by the first output matching unit 41 is represented by Formula 11 and the second amplified signal output by the second output matching unit 42 is represented by Formula 12 is assumed. G represents the first amplification factor and the second amplification factor.

GM cos(2πft−φ(t)+θ(t)) [Mathematical Formula 11]

GM cos(2πft+φ(t)+θ(t)) [Mathematical Formula 12]

In this case, the phase of the first amplified signal is a value in the negative direction with respect to the phase of the second amplified signal. In other words, the phase of the second amplified signal is a value in the positive direction with respect to the phase of the first amplified signal.

A case in which the first electric length α and the second electric length β are 0 is assumed, an impedance z of a circuit connected to the output side of the first amplifier 31 or the second amplifier 32 is represented by Formula 13 using a reflection coefficient ρ of the circuit. The impedance z may be called a load impedance or an input impedance.

$$z = \frac{1 + ρ}{1 - ρ} \qquad [ Mathematical Formula 13 ]$$

The combination point SP of the combiner 50 is a three-terminal circuit and thus, a scattering matrix A is represented by, for example, Formula 14. In this case, a terminal on the first output matching unit 41 side from the combination point SP is used as the first terminal, a terminal on the second output matching unit 42 side from the combination point SP is used as the second terminal, and a terminal on the output side from the combination point SP is used as the third terminal.

$$A = [ \begin{matrix}- 0.5 & 0.5 & \sqrt{0.5} \\ 0.5 & - 0.5 & \sqrt{0.5} \\ \sqrt{0.5} & \sqrt{0.5} & 0\end{matrix} ] \qquad [ Mathematical Formula 14 ]$$

Therefore, a reflection coefficient ρ₁ to the first output matching unit 41 side at the combination point SP is represented by Formula 15.

$$[ Mathematical Formula 15 ]$$

$$\begin{matrix}{ρ}_{1} = \frac{- 0.5 GM {e}^{i ( - φ ( t ) + θ ( t ) )} + 0.5 GM {e}^{i ( + φ ( t ) + θ ( t ) )}}{GM {e}^{i ( - φ ( t ) + θ ( t ) )}} \\ = 0.5 ( - 1 + {e}^{i2φ ( t )} )\end{matrix}$$

Similarly, a reflection coefficient ρ₂ to the second output matching unit 42 side at the combination point SP is represented by Formula 16.

ρ₂=0.5(−1+e^{-i2φ(t)}) [Mathematical Formula 16]

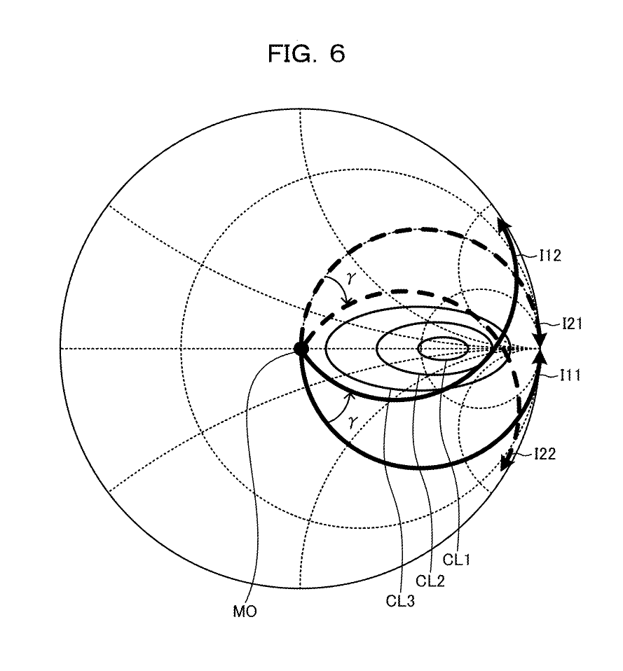

Therefore, a case in which the first electric length α and the second electric length β are equal (that is, the first electric length α and the second electric length β are equal to λ/4), a first load impedance changes as indicated by a solid-line curve Ill in FIG. 6 when the decomposition phase φ changes from 0 degrees to 90 degrees. FIG. 6 is a Smith chart. A black circle MO in FIG. 6 represents a state in which the amplitude of the output signal is maximum (that is, the decomposition phase φ is 0 degrees).

The first load impedance is a load impedance of a circuit connected to the output terminal of the first amplifier 31. As described above, changing in the decomposition phase φ from 0 degrees to 90 degrees corresponds to changing in the phase difference between the first decomposed signal and the second decomposed signal from 0 degrees to 180 degrees.

Similarly, the case in which the first electric length α and the second electric length β are equal, a second load impedance changes as indicated by a broken-line curve 121 in FIG. 6 when the decomposition phase φ changes from 0 degrees to 90 degrees. The second load impedance is a load impedance of a circuit connected to the output terminal of the second amplifier 32.

Ellipses CL1 to CL3 in FIG. 6 illustrate iso-efficiency curves representing a load impedance in which the efficiency of the first amplifier 31 and the second amplifier 32 is constant. The efficiency of the iso-efficiency curve CL1 is higher than that of the iso-efficiency curve CL2. The efficiency of the iso-efficiency curve CL2 is higher than that of the iso-efficiency curve CL3.

It is evident from FIG. 6 that the case in which the first electric length α and the second electric length β are equal, the first load impedance Ill and the second load impedance 121 change in a region where the efficiency is sufficiently lower than the efficiency represented by the iso-efficiency curve CL3.

A case in which the first electric length α is shorter than the second electric length β, on the other hand, the first load impedance changes as indicated by a solid-line curve 112 in FIG. 6 when the decomposition phase φ changes from 0 degrees to 90 degrees. Similarly, the case in which the first electric length α is shorter than the second electric length β, the second load impedance changes as indicated by a broken-line curve 122 in FIG. 6 when the decomposition phase φ changes from 0 degrees to 90 degrees.

It is evident from FIG. 6 that the case in which the first electric length α is shorter than the second electric length β, the first load impedance 112 and the second load impedance 122 change in a region of the efficiency relatively close to the efficiency represented by the iso-efficiency curve CL3. Thus, the efficiency of the first amplifier 31 and the second amplifier 32 can be enhanced when the first electric length α is shorter than the second electric length β than when the first electric length α and the second electric length β are equal.

In this example, therefore, the first transmission line 51 and the second transmission line 52 are formed such that the first electric length α is shorter than the second electric length β. For example, the first electric length α may be made shorter than the second electric length β by a length corresponding to an angle γ illustrated in FIG. 6.

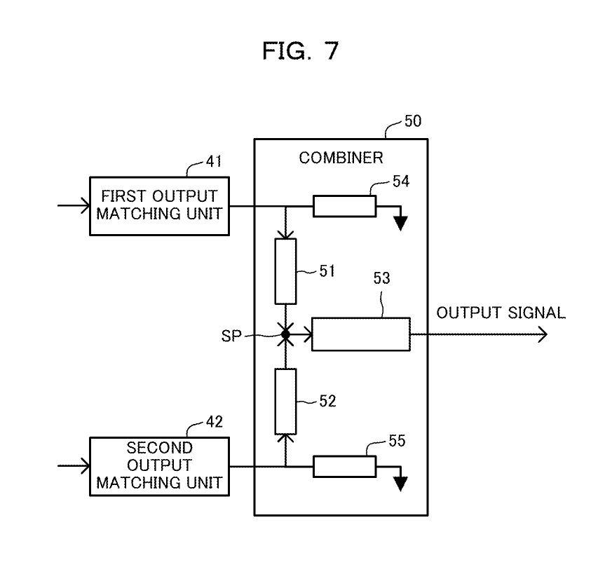

The combiner 50 may include, as illustrated in FIG. 7, a first reactive element 54 and a second reactive element 55. The first reactive element 54 is connected to a line connecting the first output matching unit 41 and the first transmission line 51 in parallel with the first transmission line 51. The second reactive element 55 is connected to a line connecting the second output matching unit 42 and the second transmission line 52 in parallel with the second transmission line 52.

In this case, the first electric length α and the second electric length β may be equal. The first electric length α and the second electric length β may be λ/4. Further, the reactance of the first reactive element 54 and the reactance of the second reactive element 55 may have the same magnitude with different signs. For example, the reactance of the first reactive element 54 may be −iX and the reactance of the second reactive element 55 may be +iX.

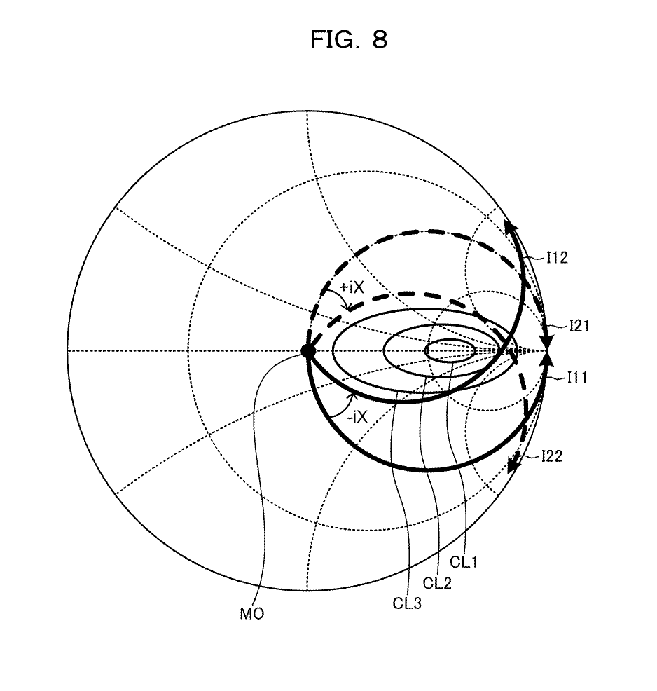

A case in which the first electric length α and the second electric length β are λ/4, the reactance of the first reactive element 54 is −iX, and the reactance of the second reactive element 55 is +iX is assumed. In this case, like the case in which the first electric length α is shorter than the second electric length β, as illustrated in FIG. 8, the first load impedance 112 and the second load impedance 122 change in a region of the efficiency relatively close to the efficiency represented by the iso-efficiency curve CL3.

The function of the amplitude phase converter 10 in the amplifying apparatus 1 may be realized by using LSI (Large Scale Integration). At least a portion of the function of the amplifying apparatus 1 may be realized by using a programmable logic circuit device (for example, PLD or FPGA). PLD is an abbreviation of Programmable Logic Device. FPGA is an abbreviation of Field-Programmable Gate Array.

(Operation)

Next, the operation of the amplifying apparatus 1 will be described.

First, when an input signal is input into the amplifying apparatus 1, the amplitude phase converter 10 acquires the first normalized amplitude r based on the input signal. Next, the amplitude phase converter 10 acquires the second normalized amplitude r′ based on the held first table and the first normalized amplitude r. Then, the amplitude phase converter 10 acquires the decomposition phase φ based on the acquired second normalized amplitude r′.

Next, the amplitude phase converter 10 generates the first waveform information and the second waveform information based on the acquired decomposition phase φ and outputs the generated first waveform information to the first frequency converter 21 and also outputs the generated second waveform information to the second frequency converter 22.

Then, the first frequency converter 21 generates the first decomposed signal based on the first waveform information output by the amplitude phase converter 10 and the input signal and outputs the generated first decomposed signal to the first amplifier 31. Similarly, the second frequency converter 22 generates the second decomposed signal based on the second waveform information output by the amplitude phase converter 10 and the input signal and outputs the generated second decomposed signal to the second amplifier 32.

Next, the first amplifier 31 amplifies the first decomposed signal output by the first frequency converter 21 by the first amplification factor and outputs the amplified signal (first amplified signal) to the first output matching unit 41. Similarly, the second amplifier 32 amplifies the second decomposed signal output by the second frequency converter 22 by the second amplification factor and outputs the amplified signal (second amplified signal) to the second output matching unit 42.

Then, the first output matching unit 41 outputs the first amplified signal output by the first amplifier 31 to the combiner 50 by transmitting the signal thereto. Similarly, the second output matching unit 42 outputs the second amplified signal output by the second amplifier 32 to the combiner 50 by transmitting the signal thereto.

Next, the combiner 50 combines the first amplified signal output by the first output matching unit 41 and the second amplified signal output by the second output matching unit 42 and outputs the combined signal as an output signal.

Accordingly, the amplifying apparatus 1 amplifies the input signal by an amplification factor and outputs the amplified signal as the output signal. In this example, the amplification factor of the amplifying apparatus 1 is equal to the amplification factor (first amplification factor) of the first amplifier 31 and the amplification factor (second amplification factor) of the second amplifier 32.

As described above, the amplifying apparatus 1 according to the first embodiment controls waveform information of two signals (the first decomposed signal and the second decomposed signal in this example) obtained by decomposing the input signal such that the output characteristic of the combiner 50 matches the desired characteristic.

Accordingly, the output characteristic of the combiner 50 can be matched to the desired characteristic. For example, the relationship between the real amplitude of an input signal and the amplitude of an output signal from the combiner 50 can be brought closer to a linear relationship. As a result, the output characteristic (amplification characteristic) of the amplifying apparatus 1 can be improved.

In the amplifying apparatus 1 according to the first embodiment, the waveform information contains the phase difference between the two signals. Further, the amplifying apparatus 1 determines the phase difference between the two signals based on the second normalized amplitude r′ obtained by correcting the first normalized amplitude r in accordance with the first normalized amplitude r.

Accordingly, the output characteristic of the combiner 50 can be matched to the desired characteristic by appropriately setting a correction amount in accordance with the first normalized amplitude r. As a result, the amplification characteristic can be improved more than when the phase difference is determined based on the first normalized amplitude r.

Instead of holding the first table, the amplifying apparatus 1 according to the first embodiment may correct the first normalized amplitude r by using a function. In this case, for example, the amplifying apparatus 1 may acquire, as represented in Formula 17, a square root of the first normalized amplitude r as the second normalized amplitude r′.

r′=\sqrt{r} [Mathematical Formula 17]

The amplifying apparatus 1 according to the first embodiment may also hold a first decomposed signal table and a second decomposed signal table as the first table. The first decomposed signal table is used to generate the first decomposed signal. The second decomposed signal table is used to generate the second decomposed signal. Accordingly, even if the first amplifier 31 and the second amplifier 32 have different characteristics, the amplification characteristic can be improved by making the first decomposed signal table and the second decomposed signal table different.

### First Modified Example of the First Embodiment

Next, an amplifying apparatus according to the first modified example of the first embodiment will be described. The amplifying apparatus according to the first modified example of the first embodiment is different from the amplifying apparatus according to the first embodiment in that the first table is corrected based on power consumption consumed by amplifiers and power of an output signal. The following description focuses on such a difference.

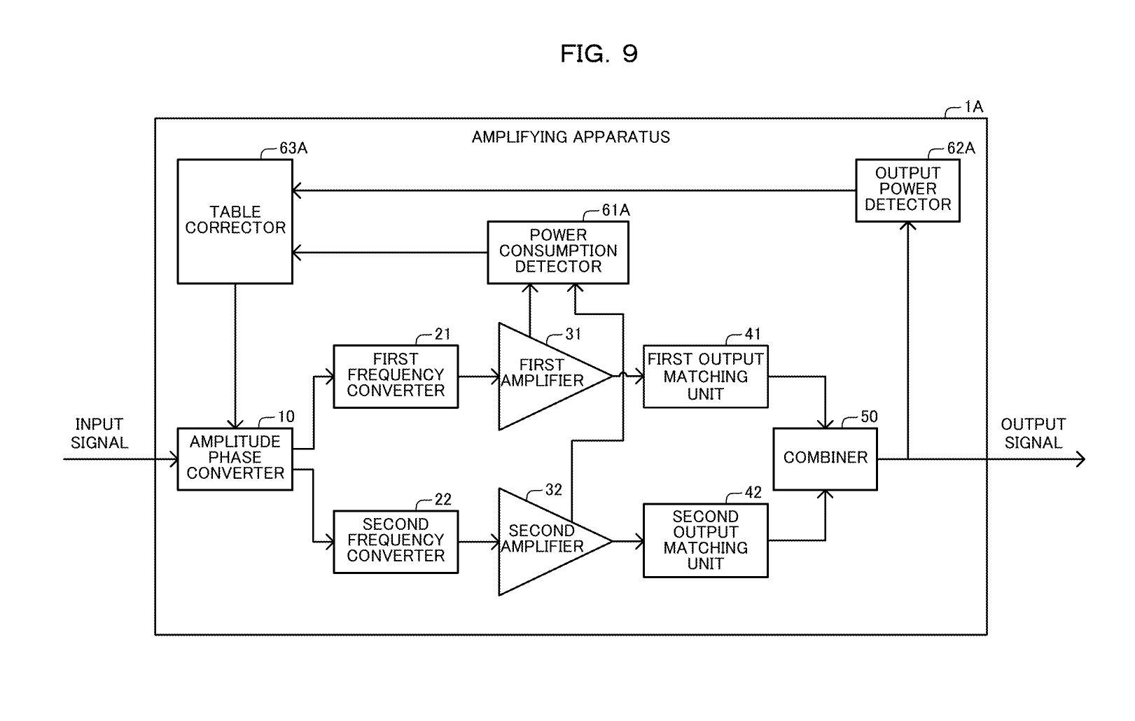

As illustrated in FIG. 9, an amplifying apparatus 1A according to the first modified example is different from the amplifying apparatus 1 in FIG. 2 in that a power consumption detector 61A, an output power detector 62A, and a table corrector 63A are additionally included. The power consumption detector 61A, the output power detector 62A, and the table corrector 63A are examples of the controller.

The power consumption detector 61A detects a first power consumption consumed by the first amplifier 31 and a second power consumption consumed by the second amplifier 32. For example, the power consumption detector 61A detects the first power consumption (or the second power consumption) by calculating a product of the voltage and the current supplied from a power supply to the first amplifier 31 (or the second amplifier 32). The power consumption detector 61A outputs a sum (total power consumption) of the detected first power consumption and the detected second power consumption to the table corrector 63A.

The output power detector 62A detects power (output power) of an output signal output by the combiner 50. The output power detector 62A outputs the detected output power to the table corrector 63A.

The table corrector 63A corrects the first table held by the amplitude phase converter 10 based on the total power consumption output by the power consumption detector 61A and the output power output by the output power detector 62A. In this example, the table corrector 63A calculates a value, which is obtained by dividing the output power by the total power consumption, as an efficiency and corrects the first table such that the calculated efficiency is increased. For example, the table corrector 63A prepares a plurality of candidate tables as candidates of the first table and calculates the efficiency for each candidate table. Then, the table corrector 63A replaces the first table held by the amplitude phase converter 10 by the candidate table with the highest calculated efficiency.

In this example, the table corrector 63A includes an A/D (Analog to Digital) converter (not illustrated) and corrects the first table by converting an analog signal into a digital signal.

As described above, in addition to the function of the amplifying apparatus 1 according to the first embodiment, the amplifying apparatus 1A according to the first modified example corrects the first table based on power consumption consumed by the amplifiers 31, 32 and power of the output signal.

Accordingly, the first table can be corrected in such a way that the ratio of output power to power consumption is made higher. As a result, the efficiency of the amplifying apparatus 1A can be enhanced.

### Second Modified Example of the First Embodiment

Next, an amplifying apparatus according to the second modified example of the first embodiment will be described. The amplifying apparatus according to the second modified example of the first embodiment is different from the amplifying apparatus according to the first embodiment in that the first table is corrected based on the input signal and the output signal. The following description focuses on such a difference.

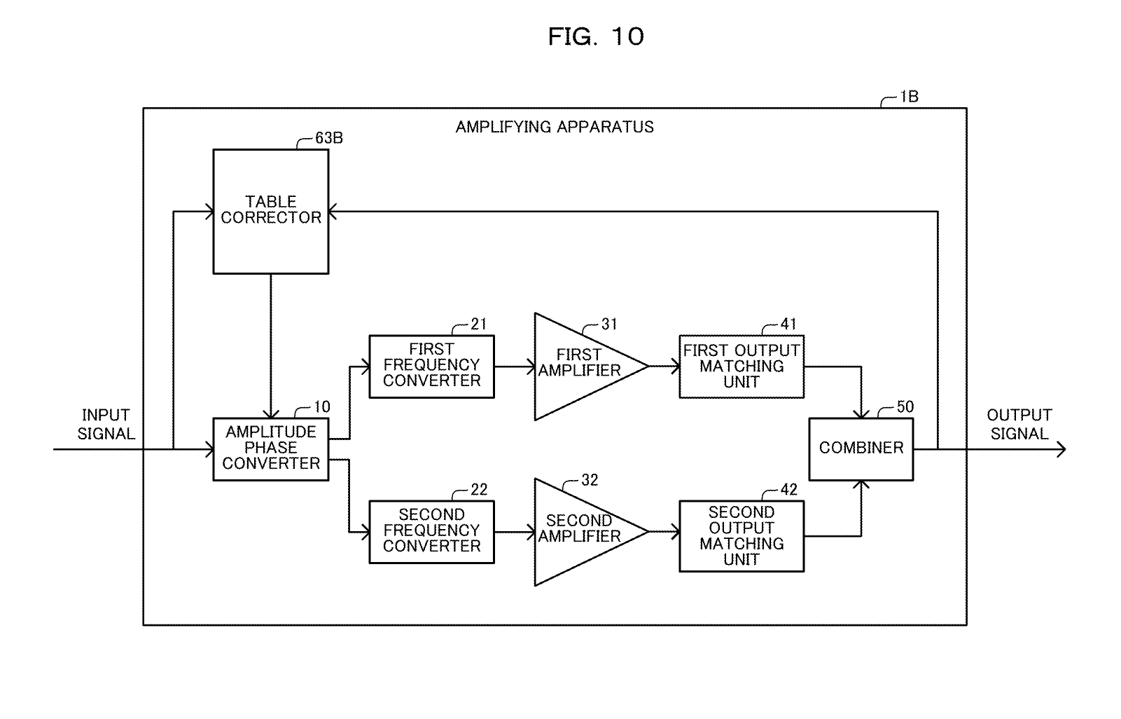

As illustrated in FIG. 10, an amplifying apparatus 1B according to the second modified example is different from the amplifying apparatus 1 in FIG. 2 in that a table corrector 63B is additionally included. The table corrector 63B is an example of the controller.

The table corrector 63B corrects the first table held by the amplitude phase converter 10 based on the input signal and the output signal. In this example, the table corrector 63B corrects the first table such that the waveform obtained by linearly amplifying the waveform of the input signal and the waveform of the output signal are matched. For example, the table corrector 63B prepares a plurality of candidate tables as candidates of the first table and calculates the degree of matching for each candidate table. The degree of matching indicates the extent to which the waveform obtained by linearly amplifying the waveform of the input signal and the waveform of the output signal match. Then, the table corrector 63B replaces the first table held by the amplitude phase converter 10 by the candidate table with the highest calculated degree of matching.

In this example, the table corrector 63B includes an A/D converter (not illustrated) and corrects the first table by converting an analog signal into a digital signal.

As described above, in addition to the function of the amplifying apparatus 1 according to the first embodiment, the amplifying apparatus 1B according to the second modified example corrects the first table based on the input signal and the output signal.

Accordingly, the first table can be corrected in such a way that the waveform obtained by linearly amplifying the waveform of the input signal and the waveform of the output signal are matched. As a result, the amplification characteristic can be improved.

### Second Embodiment

Next, an amplifying apparatus according to the second embodiment will be described. The amplifying apparatus according to the second embodiment is different from the amplifying apparatus according to the first embodiment in that a value larger than 180 degrees is determined as the phase difference between the first decomposed signal and the second decomposed signal. The following description focuses on such a difference.

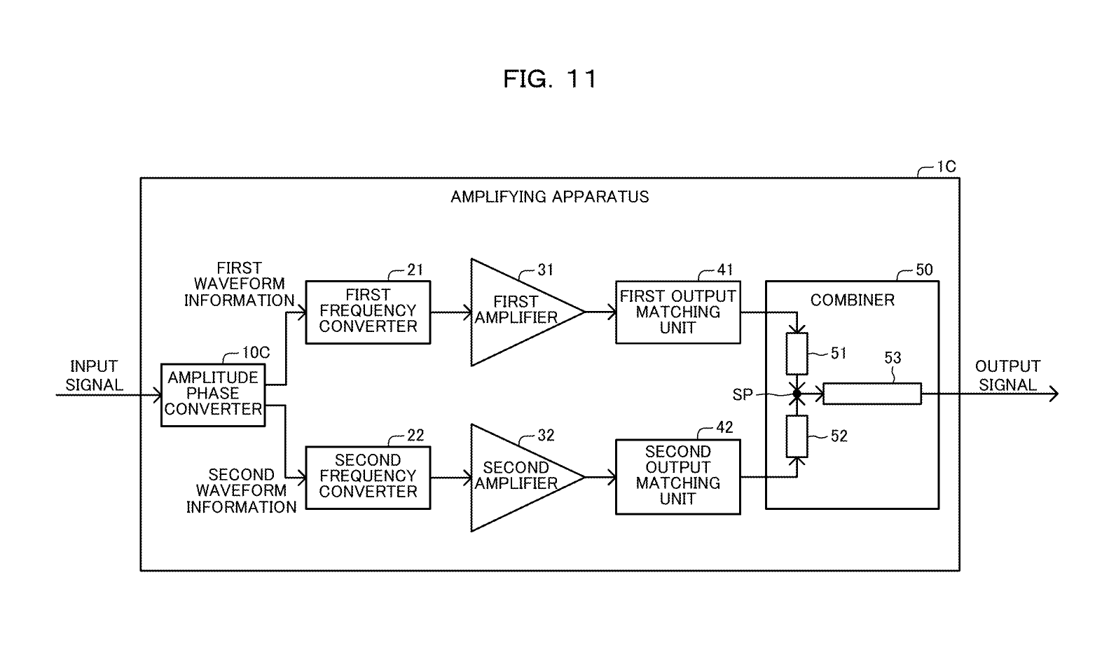

As illustrated in FIG. 11, an amplifying apparatus 1C according to the second embodiment includes, instead of the amplitude phase converter 10 of the amplifying apparatus 1 in FIG. 2, an amplitude phase converter 10C.

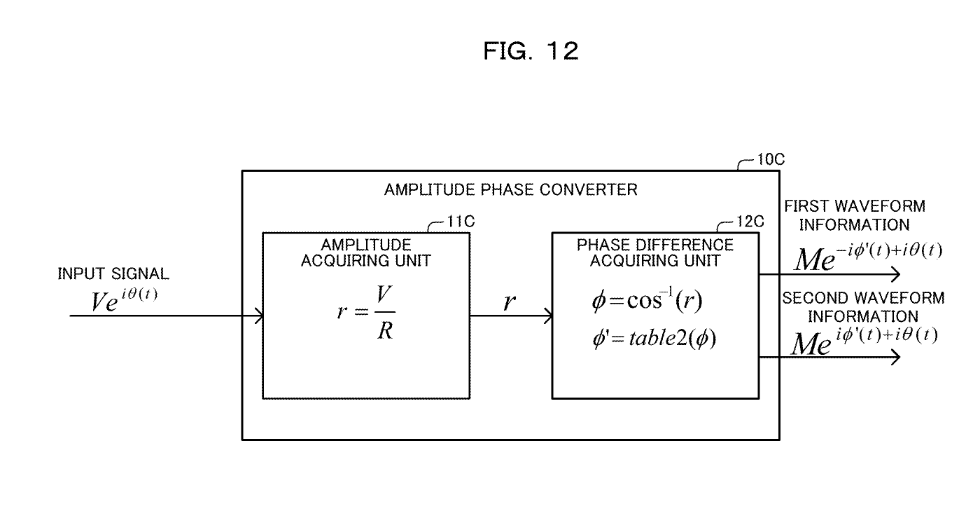

The amplitude phase converter 10C includes, as illustrated in FIG. 12, an amplitude acquiring unit 11C and a phase difference acquiring unit 12C.

The amplitude acquiring unit 11C acquires, based on the input signal, the amplitude (normalized amplitude) r of the input signal normalized so that the maximum value thereof is 1 based on the Formula 2. The amplitude acquiring unit 11C outputs the acquired normalized amplitude r without a correction to the phase difference acquiring unit 12C.

The phase difference acquiring unit 12C holds a second table associating a decomposition phase before a correction and a decomposition phase after the correction in advance (for example, stored in a memory). The second table is set such that the output characteristic of the combiner 50 matches a desired characteristic. The desired characteristic includes, for example, a first characteristic, a second characteristic, or both. The first characteristic is a characteristic in which the amplitude of an output signal from the combiner 50 is 0 when the real amplitude of an input signal is 0. The second characteristic is a characteristic in which a relationship between the real amplitude of an input signal and the amplitude of an output signal from the combiner 50 is a linear relationship.

For example, a relationship between the second table and the output characteristic of the combiner 50 may be determined by an experiment or a simulation to set the second table based on the relationship.

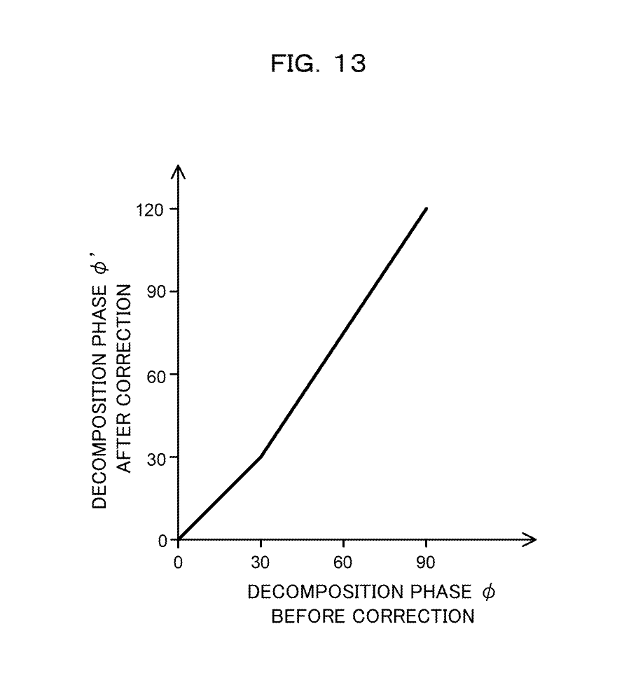

In this example, as illustrated in FIG. 13, the decomposition phase before a correction and the decomposition phase after the correction are associated in the second table. The decomposition phase before the correction and the decomposition phase after the correction are associated in the second table in such a way that the decomposition phase after the correction monotonously increases with an increase of the decomposition phase before the correction.

In this example, when a decomposition phase φ before a correction is equal to or smaller than a phase threshold (for example, 30 degrees), a decomposition phase φ′ after the correction having the same value as the decomposition phase φ before the correction and the decomposition phase φ before the correction are associated in the second table. Further, when the decomposition phase φ before the correction is larger than the phase threshold, the decomposition phase φ′ after the correction having a larger value than the decomposition phase φ before the correction and the decomposition phase φ before the correction are associated in the second table.

When the decomposition phase φ before the correction is equal to or smaller than the phase threshold, the decomposition phase φ before the correction and the decomposition phase φ′ after the correction are associated in the second table by a linear function whose gradient is 1. Further, when the decomposition phase φ before the correction is larger than the phase threshold, the decomposition phase φ before the correction and the decomposition phase φ′ after the correction are associated in the second table by a linear function whose gradient is larger than 1.

Thus, in the second table, the decomposition phase φ before the correction in the range of 0 degrees to 90 degrees and the decomposition phase φ′ after the correction in the range of 0 degrees to an upper limit (for example, 120 degrees) larger than 90 degrees are associated.

In the second table, the decomposition phase φ before the correction and the decomposition phase φ′ after the correction may be associated such that the relationship between the decomposition phase φ before the correction and the decomposition phase φ′ after the correction is represented by a curve in the graph of FIG. 13. For example, the decomposition phase φ before the correction and the decomposition phase φ′ after the correction may be associated by a nonlinear function in the second table.

The phase difference acquiring unit 12C acquires a first decomposition phase φ based on the normalized amplitude r output by the amplitude acquiring unit 11C. In this example, the phase difference acquiring unit 12C acquires, as represented in Formula 18, an arc cosine of the normalized amplitude r as the first decomposition phase φ.

φ=cos⁻¹ (r) [Mathematical Formula 18]

The phase difference acquiring unit 12C acquires, as represented in Formula 19, the decomposition phase after the correction, which is associated with the acquired first decomposition phase φ as the decomposition phase before the correction in the held second table, as a second decomposition phase φ′. table2φ indicates that the first decomposition phase φ is corrected (converted) by the second table.

φ′=table2(φ) [Mathematical Formula 19]

Correcting the first decomposition phase φ by the second table is an example of correcting the first decomposition phase φ in the range of 0 degrees to 90 degrees to the second decomposition phase φ′ in the range of 0 degrees to an upper limit larger than 90 degrees in accordance with the first decomposition phase φ. As will be described later, a value obtained by doubling the second decomposition phase φ′ is used as the phase difference between the first decomposed signal and the second decomposed signal. A value obtained by doubling the first decomposition phase φ is an example of a first phase difference and a value obtained by doubling the second decomposition phase φ′ is an example of a second phase difference.

Therefore, correcting the first decomposition phase φ by the second table is an example of correcting the first phase difference in the range of 0 degrees to 180 degrees to the second phase difference in the range of 0 degrees to the upper limit larger than 180 degrees in accordance with the first phase difference.

The phase difference acquiring unit 12C generates first waveform information and second waveform information based on the acquired second decomposition phase φ′ and outputs the generated first waveform information to the first frequency converter 21 and also outputs the generated second waveform information to the second frequency converter 22. Each of the first waveform information and the second waveform information is information indicating a waveform indicated by the amplitude and the phase.

In this example, the first waveform information is, as represented in Formula 20, information indicating a waveform (for example, a cosine wave or a sine wave) in which the amplitude is the amplification factor M and the phase is represented as −φ′+θ. Similarly, the second waveform information is, as represented in Formula 21, information indicating a waveform in which the amplitude is the amplification factor M and the phase is represented as φ′+θ.

Me^{-iφ′+iθ} [Mathematical Formula 20]

Me^{iφ′+iθ} [Mathematical Formula 21]

In this example, therefore, the waveform indicated by the first waveform information and the waveform indicated by the second waveform information have a phase difference equal to a value obtained by doubling the second decomposition phase φ′. The phase difference matches the phase difference between the first decomposed signal output by the first frequency converter 21 and the second decomposed signal output by the second frequency converter 22.

(Operation)

Next, the operation of the amplifying apparatus 1C will be described.

First, when an input signal is input into the amplifying apparatus 1C, the amplitude phase converter 10C acquires the normalized amplitude r based on the input signal. Next, the amplitude phase converter 10C acquires the first decomposition phase φ based on the acquired normalized amplitude r. Then, the amplitude phase converter 10C acquires the second decomposition phase φ′ based on the held second table and the first decomposition phase φ.

Then, the amplitude phase converter 10C generates the first waveform information and the second waveform information based on the acquired second decomposition phase φ′ and outputs the generated first waveform information to the first frequency converter 21 and also outputs the generated second waveform information to the second frequency converter 22.

Thereafter, the amplifying apparatus 1C amplifies the input signal by the amplification factor and outputs the amplified signal as an output signal by operating in the same manner as the amplifying apparatus 1.

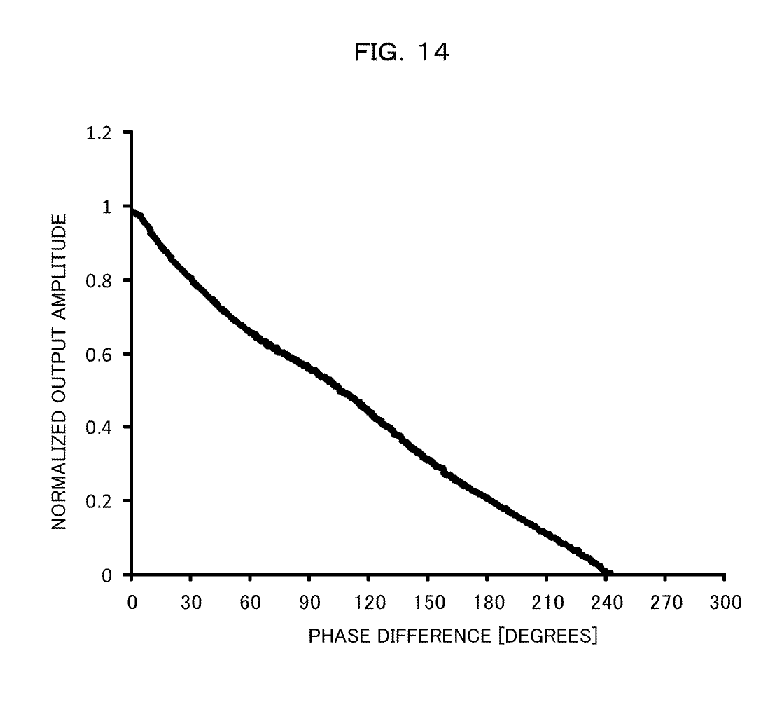

FIG. 14 is a graph illustrating a relationship between a normalized output amplitude and a phase difference in the amplifying apparatus 1C. The normalized output amplitude in the vertical axis is a value normalized such that the maximum value of the amplitude of an output signal is 1. The phase difference in the horizontal axis is the phase difference between the first decomposed signal and the second decomposed signal. According to the amplifying apparatus 1C in the second embodiment, as illustrated in FIG. 14, the normalized output amplitude can be brought sufficiently closer to 0 by determining a value larger than 180 degrees as the phase difference.

According to the amplifying apparatus 1C in the second embodiment, as described above, just like the amplifying apparatus 1 according to the first embodiment, waveform information, on which the first decomposed signal and the second decomposed signal decomposed from the input signal are based, is controlled such that the output characteristic of the combiner 50 matches the desired characteristic.

Accordingly, the output characteristic of the combiner 50 can be matched to the desired characteristic. For example, when the real amplitude of the input signal is 0, the amplitude of the output signal from the combiner 50 can be brought closer to 0. As a result, the output characteristic (amplification characteristic) of the amplifying apparatus 1C can be improved.

Also, in the amplifying apparatus 1C according to the second embodiment, waveform information contains the phase difference between the two signals. Further, the amplifying apparatus 1C determines a value larger than 180 degrees as the phase difference between the two signals.

Accordingly, the amplification characteristic can be improved more than when a value equal to or smaller than 180 degrees is determined as the phase difference between the two signals. For example, when the real amplitude of an input signal is 0, the amplitude of an output signal from the combiner 50 can be brought closer to 0.

Also, the amplifying apparatus 1C according to the second embodiment corrects the first decomposition phase φ in the range of 0 degrees to 90 degrees to the second decomposition phase φ′ defined in the range of 0 degrees to the upper limit (for example, 120 degrees) larger than 90 degrees according to the first decomposition phase φ. The first decomposition phase φ is defined based on the real amplitude of an input signal.

In other words, the amplifying apparatus 1C corrects the first phase difference in the range of 0 degrees to 180 degrees to the second phase difference defined in a range of 0 degrees to an upper limit (for example, 240 degrees) larger than 180 degrees in accordance with the first phase difference. Further, the amplifying apparatus 1C determines the corrected second phase difference as the phase difference of the two signals.

Accordingly, the amplification characteristic can be improved more than when the first phase difference is used as the phase difference of the two signals.

Also, the amplifying apparatus 1C according to the second embodiment may hold a first decomposed signal table and a second decomposed signal table as the second table. The first decomposed signal table is used to generate the first decomposed signal. The second decomposed signal table is used to generate the second decomposed signal. Accordingly, even if the first amplifier 31 and the second amplifier 32 have different characteristics, the amplification characteristic can be improved by making the first decomposed signal table and the second decomposed signal table different.

### First Modified Example of the Second Embodiment

Next, an amplifying apparatus according to a first modified example of the second embodiment will be described. The amplifying apparatus according to the first modified example of the second embodiment is different from the amplifying apparatus according to the second embodiment in that the second table is corrected based on power consumption consumed by amplifiers and power of an output signal. The following description focuses on such a difference.

The amplifying apparatus according to the first modified example of the second embodiment includes, just like the amplifying apparatus 1A in FIG. 9, a power consumption detector, an output power detector, and a table corrector.

The power consumption detector and the output power detector according to the first modified example of the second embodiment have functions similar to those of the power consumption detector 61A and the output power detector 62A in FIG. 9 respectively.

The table corrector according to the first modified example of the second embodiment is different from the table corrector 63A in FIG. 9 in that, instead of the first table, the second table is corrected.

The table corrector according to the first modified example of the second embodiment corrects the second table based on power consumption consumed by the amplifiers 31, 32 and power of the output signal in addition to the function of the amplifying apparatus 1C according to the second embodiment.

Accordingly, the second table can be corrected in such a way that the ratio of output power to power consumption is made higher. As a result, the efficiency of the amplifying apparatus can be enhanced.

### Second Modified Example of the Second Embodiment

Next, an amplifying apparatus according to a second modified example of the second embodiment will be described. The amplifying apparatus according to the second modified example of the second embodiment is different from the amplifying apparatus according to the second embodiment in that the second table is corrected based on the input signal and the output signal. The following description focuses on such a difference.

The amplifying apparatus according to the second modified example of the second embodiment includes, just like the amplifying apparatus 1B in FIG. 10, a table corrector.

The table corrector according to the second modified example of the second embodiment is different from the table corrector 63B in FIG. 10 in that, instead of the first table, the second table is corrected.

The amplifying apparatus according to the second modified example of the second embodiment corrects the second table based on the input signal and the output signal in addition to the function of the amplifying apparatus 1C according to the second embodiment.

Accordingly, the second table can be corrected in such a way that the waveform obtained by linearly amplifying the waveform of the input signal and the waveform of the output signal are matched. As a result, the amplification characteristic can be improved.

### Third Embodiment

Next, an amplifying apparatus according to the third embodiment will be described. The amplifying apparatus according to the third embodiment is different from the amplifying apparatus according to the first embodiment in that when the normalized amplitude of the input signal is equal to or smaller than a first amplitude threshold, the amplitudes of waveforms indicated by the first waveform information and the second waveform information are made smaller than the amplification factor M. The following description focuses on such a difference.

(Amplifying Apparatus According to Related Technology)

First, an example of challenges of an amplifying apparatus according to related technology will be described.

The amplifying apparatus according to related technology acquires an amplitude (normalized amplitude) r of an input signal normalized so that the maximum value thereof is 1 based on the input signal and Formula 22. Next, the amplifying apparatus acquires a decomposition phase φ based on the acquired normalized amplitude r and Formula 23. Then, the amplifying apparatus generates first waveform information and second waveform information based on the acquired decomposition phase φ.

$$\begin{matrix}r = \frac{V}{R} & [ Mathematical Formula 22 ] \\ φ = {cos}^{- 1} ( r ) & [ Mathematical Formula 23 ]\end{matrix}$$

The first waveform information is, as represented in Formula 24, information indicating a waveform in which the amplitude is the amplification factor M and the phase is represented as −φ+0. Similarly, the second waveform information is, as represented in Formula 25, information indicating a waveform in which the amplitude is the amplification factor M and the phase is represented as φ+θ.

Me^{-iφ+iθ} [Mathematical Formula 24]

Me^{iφ+iθ} [Mathematical Formula 25]

Then, the amplifying apparatus generates a first decomposed signal and a second decomposed signal based on the first waveform information, the second waveform information, and the input signal. Next, the amplifying apparatus amplifies the first decomposed signal and the second decomposed signal by two amplifiers. Next, the amplifying apparatus combines the two amplified signals by a combiner and outputs the combined signal as an output signal.

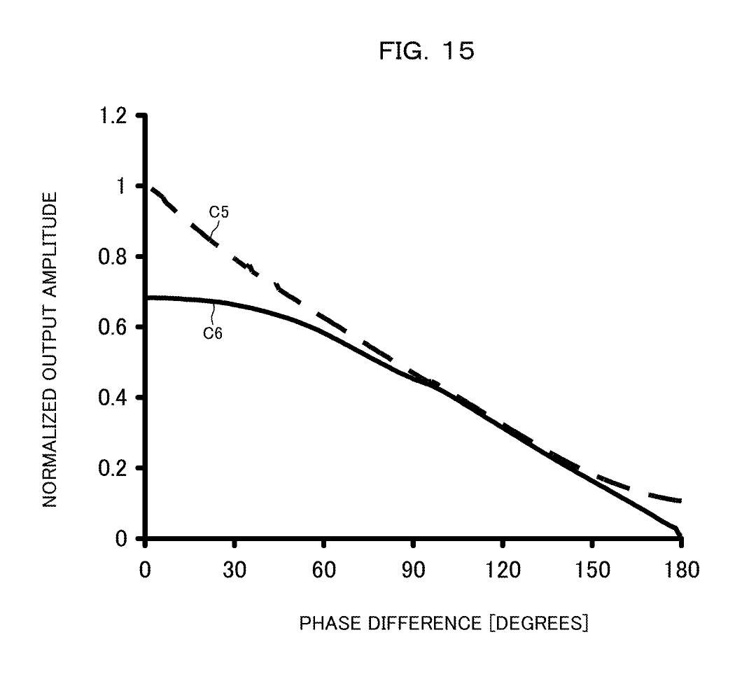

FIG. 15 is a graph illustrating a relationship between a normalized output amplitude and a phase difference in the amplifying apparatus according to the related technology. The normalized output amplitude in the vertical axis is a value normalized such that the maximum value of the amplitude of the output signal is 1. The phase difference in the horizontal axis is a phase difference between the first decomposed signal and the second decomposed signal.

A broken line C5 in FIG. 15 represents a case in which power of a signal input into each amplifier is first power. A solid line C6 in FIG. 15, on the other hand, represents a case in which power of the signal input into each amplifier is second power, which is smaller than the first power.

It is evident from FIG. 15 that a case in which power of the signal input into each amplifier is sufficiently small in the amplifying apparatus according to the related technology, the normalized output amplitude when the phase difference is 180 degrees can sufficiently be brought closer to 0.

(Amplifying Apparatus According to the Third Embodiment)

Thus, when the normalized amplitude of the input signal is larger than the first amplitude threshold, an amplifying apparatus according to the third embodiment uses the amplification factor M as the amplitudes of waveforms indicated by the first waveform information and the second waveform information. On the other hand, when the normalized amplitude of the input signal is equal to or smaller than the first amplitude threshold, the amplifying apparatus according to the third embodiment uses a value smaller than the amplification factor M as the amplitudes of waveforms indicated by the first waveform information and the second waveform information.

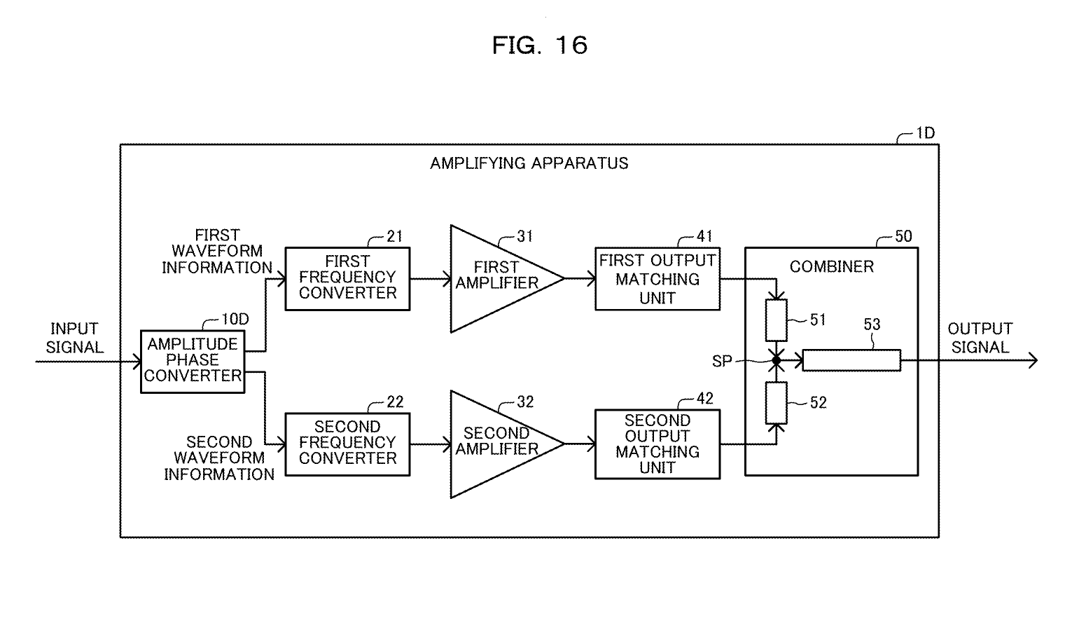

As illustrated in FIG. 16, an amplifying apparatus 1D according to the third embodiment includes, instead of the amplitude phase converter 10 of the amplifying apparatus 1 in FIG. 2, an amplitude phase converter 10D.

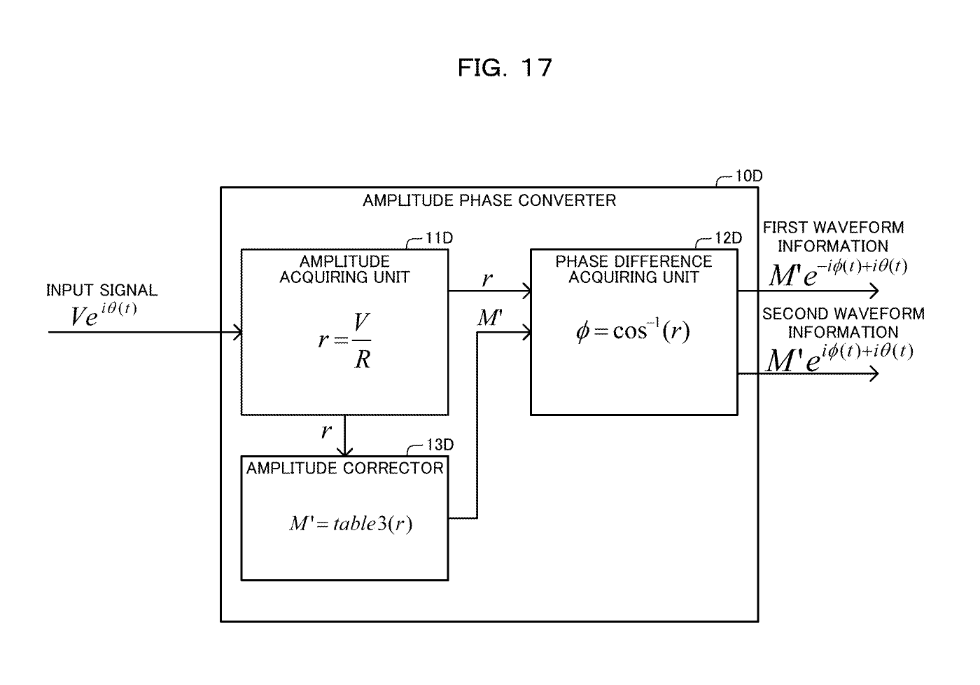

As illustrated in FIG. 17, the amplitude phase converter 10D includes an amplitude acquiring unit 11D, a phase difference acquiring unit 12D, and an amplitude corrector 13D.

The amplitude acquiring unit 11D acquires the amplitude (normalized amplitude) r of the input signal normalized so that the maximum value thereof is 1 based on the input signal and the Formula 2. The amplitude acquiring unit 11D outputs the acquired normalized amplitude r without a correction to each of the phase difference acquiring unit 12D and the amplitude corrector 13D.

The amplitude corrector 13D holds a third table associating the amplitude after a correction and the normalized amplitude in advance (for example, stored in a memory). The third table is set such that the output characteristic of the combiner 50 matches a desired characteristic. The desired characteristic includes, for example, a first characteristic, a second characteristic, or both. The first characteristic is a characteristic in which the amplitude of an output signal from the combiner 50 is 0 when the real amplitude of an input signal is 0. The second characteristic is a characteristic in which a relationship between the real amplitude of an input signal and the amplitude of an output signal from the combiner 50 is a linear relationship.

For example, a relationship between the third table and the output characteristic of the combiner 50 may be determined by an experiment or a simulation to set the third table based on the relationship.

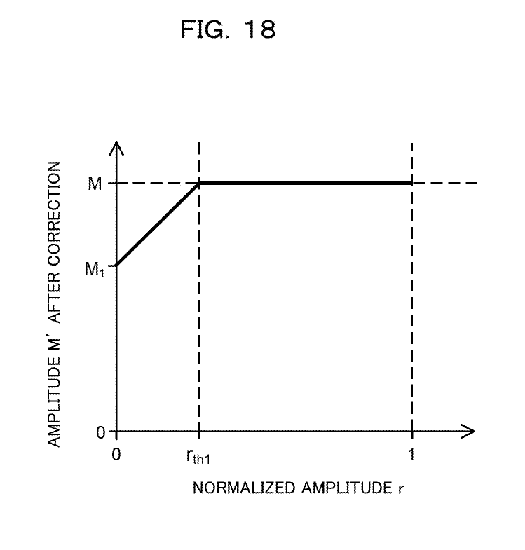

In this example, as illustrated in FIG. 18, the amplitude after the correction and the normalized amplitude are associated in the third table. In this example, when the normalized amplitude r is larger than a first amplitude threshold rₜₕ₁, an amplitude M′ after the correction having a fixed value (the amplification factor M in this example) and the normalized amplitude r are associated in the third table.

Further, when the normalized amplitude r is equal to or smaller than the first amplitude threshold rₜₕ₁, the amplitude M′ after the correction having a value smaller than the amplification factor M and the normalized amplitude r are associated in the third table. In the third table, when the normalized amplitude r is equal to or smaller than the first amplitude threshold rₜₕ₁, the normalized amplitude and the amplitude after the correction are associated in such a way that the amplitude after the correction monotonously increases with an increase of the normalized amplitude. Also in the third table, when the normalized amplitude r is equal to or smaller than the first amplitude threshold rₜₕ₁, the amplitude M′ after the correction and the normalized amplitude r are associated by a linear function having a positive value as the gradient thereof.

In the third table, the amplitude M′ after the correction and the normalized amplitude r may be associated such that the relationship between the amplitude M′ after the correction and the normalized amplitude r is represented by a curve in the graph of FIG. 18. For example, the amplitude M′ after the correction and the normalized amplitude r may be associated by a nonlinear function in the third table.

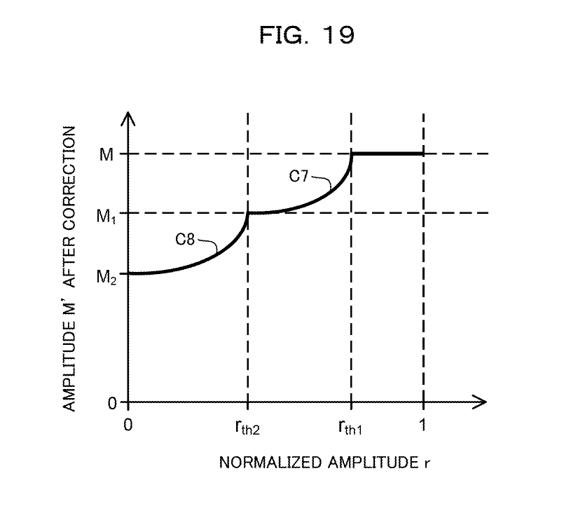

Also in the third table, the amplitude after the correction and the normalized amplitude may be associated as illustrated in FIG. 19. In this case, when the normalized amplitude r is larger than the first amplitude threshold rₜₕ₁, the amplitude M′ after the correction having a fixed value (the amplification factor M in this example) and the normalized amplitude r are associated in the third table.

Further, when the normalized amplitude r is equal to or smaller than the first amplitude threshold rₜₕ₁ and larger than a second amplitude threshold rₜₕ₂, the amplitude M′ after the correction and the normalized amplitude r are associated by a first curve C7 in the third table. The second amplitude threshold rₜₕ₂ is smaller than the first amplitude threshold rₜₕ₁. In addition, when the normalized amplitude r is equal to or smaller than the second amplitude threshold rₜₕ₂, the amplitude M′ after the correction and the normalized amplitude r are associated by a second curve C8 in the third table.

Also in this case, when the normalized amplitude r is equal to or smaller than the first amplitude threshold rₜₕ₁, the normalized amplitude r and the amplitude M′ after the correction in the third table are associated in such a way that the amplitude M′ after the correction monotonously increases with an increase of the normalized amplitude r.

The amplitude corrector 13D acquires, as represented in Formula 26, the amplitude (decomposition amplitude) M′ after the correction associated with the normalized amplitude r output by the amplitude acquiring unit 11D in the held third table. The decomposition amplitude M′ is used, as will be described later, to generate the first decomposed signal and the second decomposed signal. table3(r) represents that the normalized amplitude r is converted by the third table.

M′=table3(r) [Mathematical Formula 26]

The amplitude corrector 13D outputs the acquired decomposition amplitude M′ to the phase difference acquiring unit 12D. The first amplitude threshold rₜₕ₁ is an example of a first threshold. The decomposition amplitude M′ (the amplification factor M in this example) when the normalized amplitude r is larger than the first amplitude threshold rₜₕ₁ is an example of a third amplitude. The decomposition amplitude M′ when the normalized amplitude r is equal to or smaller than the first amplitude threshold rₜₕ₁ is an example of a fourth amplitude, which is smaller than the third amplitude. The decomposition amplitude M′ when the normalized amplitude r is equal to or smaller than the first amplitude threshold rₜₕ₁ is a value that changes in accordance with the normalized amplitude r (or the real amplitude of the input signal).

The phase difference acquiring unit 12D acquires the decomposition phase φ based on the normalized amplitude r output by the amplitude acquiring unit 11D. In this example, the phase difference acquiring unit 12D acquires, as represented in Formula 27, an arc cosine of the normalized amplitude r as the decomposition phase φ.

φ=cos⁻¹ (r) [Mathematical Formula 27]

The phase difference acquiring unit 12D generates first waveform information and second waveform information based on the acquired decomposition phase φ and the decomposition amplitude M′ output by the amplitude corrector 13D. The phase difference acquiring unit 12D outputs the generated first waveform information to the first frequency converter 21 and also outputs the generated second waveform information to the second frequency converter 22. Each of the first waveform information and the second waveform information is information indicating a waveform represented by the amplitude and the phase.

In this example, the first waveform information is, as represented in Formula 28, information indicating a waveform (for example, a cosine wave or a sine wave) in which the amplitude is the decomposition amplitude M′ and the phase is −φ+0. Similarly, the second waveform information is, as represented in Formula 29, information indicating a waveform in which the amplitude is the decomposition amplitude M′ and the phase is φ+θ.

M′e^{-iφ+iθ} [Mathematical Formula 28]

M′e^{iφ+iθ} [Mathematical Formula 29]

In this example, therefore, the waveform indicated by the first waveform information and the waveform indicated by the second waveform information have a phase difference equal to a value obtained by doubling the decomposition phase φ. The phase difference matches, as described above, the phase difference between the first decomposed signal output by the first frequency converter 21 and the second decomposed signal output by the second frequency converter 22.

(Operation)

Next, the operation of the amplifying apparatus 1D will be described.

First, when an input signal is input into the amplifying apparatus 1D, the amplitude phase converter 10D acquires the normalized amplitude r based on the input signal. Next, the amplitude phase converter 10D acquires the decomposition phase φ based on the acquired normalized amplitude r.

Further, the amplitude phase converter 10D acquires the decomposition amplitude M′ based on the acquired normalized amplitude r and the held third table. Then, the amplitude phase converter 10D generates the first waveform information and the second waveform information based on the acquired decomposition phase φ and the acquired decomposition amplitude M′.

Next, the amplitude phase converter 10D outputs the generated first waveform information to the first frequency converter 21 and also outputs the generated second waveform information to the second frequency converter 22.

Then, the amplifying apparatus 1D amplifies the input signal by the amplification factor and outputs the amplified signal as an output signal by operating in the same manner as the amplifying apparatus 1.

According to the amplifying apparatus 1D in the third embodiment, as described above, just like the amplifying apparatus 1 according to the first embodiment, waveform information, on which the first decomposed signal and the second decomposed signal decomposed from the input signal are based, is controlled such that the output characteristic of the combiner 50 matches the desired characteristic.

Accordingly, the output characteristic of the combiner 50 can be matched to the desired characteristic. For example, when the real amplitude of the input signal is 0, the amplitude of the output signal from the combiner 50 can be brought closer to 0. As a result, the output characteristic (amplification characteristic) of the amplifying apparatus 1D can be improved.

Also, in the amplifying apparatus 1D according to the third embodiment, waveform information contains the amplitudes of the two signals. Further, when the normalized amplitude r is larger than the first amplitude threshold rₜₕ₁, the amplifying apparatus 1D determines on the amplification factor M as the amplitudes of the two signals. On the other hand, when the normalized amplitude r is equal to or smaller than the first amplitude threshold rₜₕ₁, the amplifying apparatus 1D determines on a value smaller than the amplification factor M as the amplitudes of the two signals.

Accordingly, the amplification characteristic can be improved more than when the amplification factor M is determined as the amplitudes of the two signals independently of the real amplitude of the input signal.

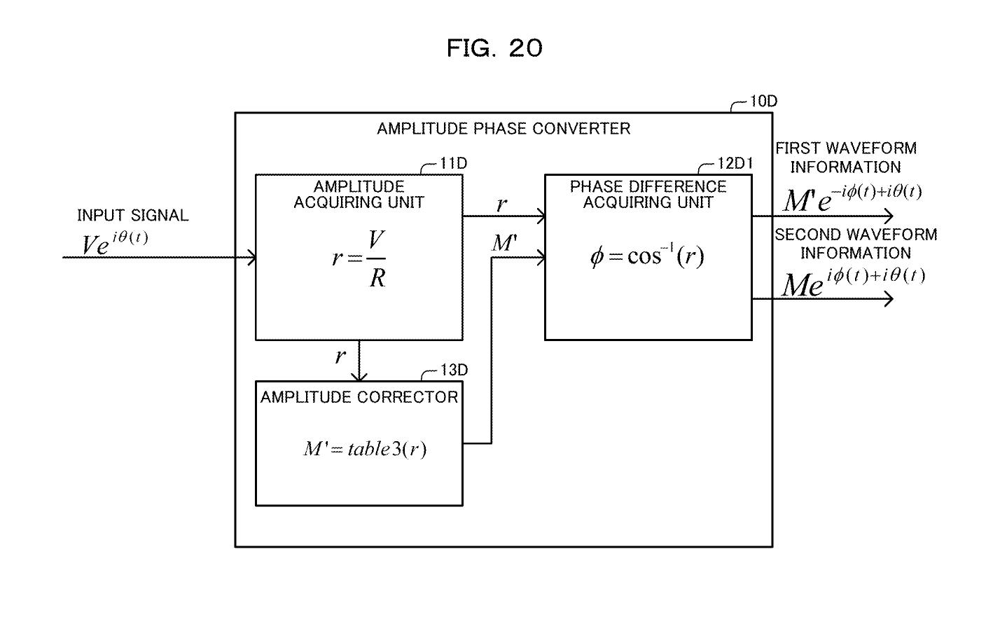

As illustrated in FIG. 20, the amplitude phase converter 10D according to the third embodiment may include, instead of the phase difference acquiring unit 12D, a phase difference acquiring unit 12D1. The phase difference acquiring unit 12D1 is different from the phase difference acquiring unit 12D in that the decomposition amplitude M′ is used as the amplitude of the waveform indicated by the first waveform information and the amplification factor M is used as the amplitude of the waveform indicated by the second waveform information. The phase difference acquiring unit 12D1 may also use the amplification factor M as the amplitude of the waveform indicated by the first waveform information and the decomposition amplitude M′ as the amplitude of the waveform indicated by the second waveform information.

The first waveform information is an example of waveform information on which a signal input into the transmission line (the first transmission line 51 in this example) whose electric length of shorter of the two transmission lines 51, 52 included in the combiner 50 is based. The second waveform information is an example of waveform information on which a signal input into the transmission line (the second transmission line 52 in this example) whose electric length of longer of the two transmission lines 51, 52 included in the combiner 50 is based.

The amplitude phase converter 10D according to the third embodiment acquires the decomposition amplitude M′ based on the normalized amplitude r, but may also acquire the decomposition amplitude M′ based on the real amplitude of the input signal or an instantaneous value of power of the input signal. For example, the amplitude phase converter 10D calculates, as the instantaneous value of power, a product of the instantaneous value of the voltage and the instantaneous value of the current. The instantaneous value of power may be a representative value (for example, the average value, minimum value, or maximum value) of power in a very short time with respect to the period of fundamental wave components of the input signal.

The amplifying apparatus 1D according to the third embodiment may hold a first decomposed signal table and a second decomposed signal table as the third table. The first decomposed signal table is used to generate the first decomposed signal. The second decomposed signal table is used to generate the second decomposed signal. Accordingly, even if the first amplifier 31 and the second amplifier 32 have different characteristics, the amplification characteristic can be improved by making the first decomposed signal table and the second decomposed signal table different.

### First Modified Example of the Third Embodiment

Next, an amplifying apparatus according to a first modified example of the third embodiment will be described. The amplifying apparatus according to the first modified example of the third embodiment is different from the amplifying apparatus according to the third embodiment in that the third table is corrected based on power consumption consumed by amplifiers and power of an output signal. The following description focuses on such a difference.

The amplifying apparatus according to the first modified example of the third embodiment includes, just like the amplifying apparatus 1A in FIG. 9, a power consumption detector, an output power detector, and a table corrector.

The power consumption detector and the output power detector according to the first modified example of the third embodiment have functions similar to those of the power consumption detector 61A and the output power detector 62A in FIG. 9 respectively.

The table corrector according to the first modified example of the third embodiment is different from the table corrector 63A in FIG. 9 in that, instead of the first table, the third table is corrected.

The table corrector according to the first modified example of the third embodiment corrects the third table based on power consumption consumed by the amplifiers 31, 32 and power of the output signal in addition to the function of the amplifying apparatus 1D according to the third embodiment.

Accordingly, the third table can be corrected in such a way that the ratio of output power to power consumption is made higher. As a result, the efficiency of the amplifying apparatus can be enhanced.

### Second Modified Example of the Third Embodiment

Next, an amplifying apparatus according to a second modified example of the third embodiment will be described. The amplifying apparatus according to the second modified example of the third embodiment is different from the amplifying apparatus according to the third embodiment in that the third table is corrected based on the input signal and the output signal. The following description focuses on such a difference.

The amplifying apparatus according to the second modified example of the third embodiment includes, just like the amplifying apparatus 1B in FIG. 10, a table corrector.

The table corrector according to the second modified example of the third embodiment is different from the table corrector 63B in FIG. 10 in that, instead of the first table, the third table is corrected.

The amplifying apparatus according to the second modified example of the third embodiment corrects the third table based on the input signal and the output signal in addition to the function of the amplifying apparatus 1D according to the third embodiment.

Accordingly, the third table can be corrected in such a way that the waveform obtained by linearly amplifying the waveform of the input signal and the waveform of the output signal are matched. As a result, the amplification characteristic can be improved.

### Fourth Embodiment

Next, an amplifying apparatus according to the fourth embodiment will be described. The amplifying apparatus according to the fourth embodiment is different from the amplifying apparatus according to the first embodiment in that, instead of waveform information of the two signals, operating states of the two amplifiers are controlled. The following description focuses on such a difference.

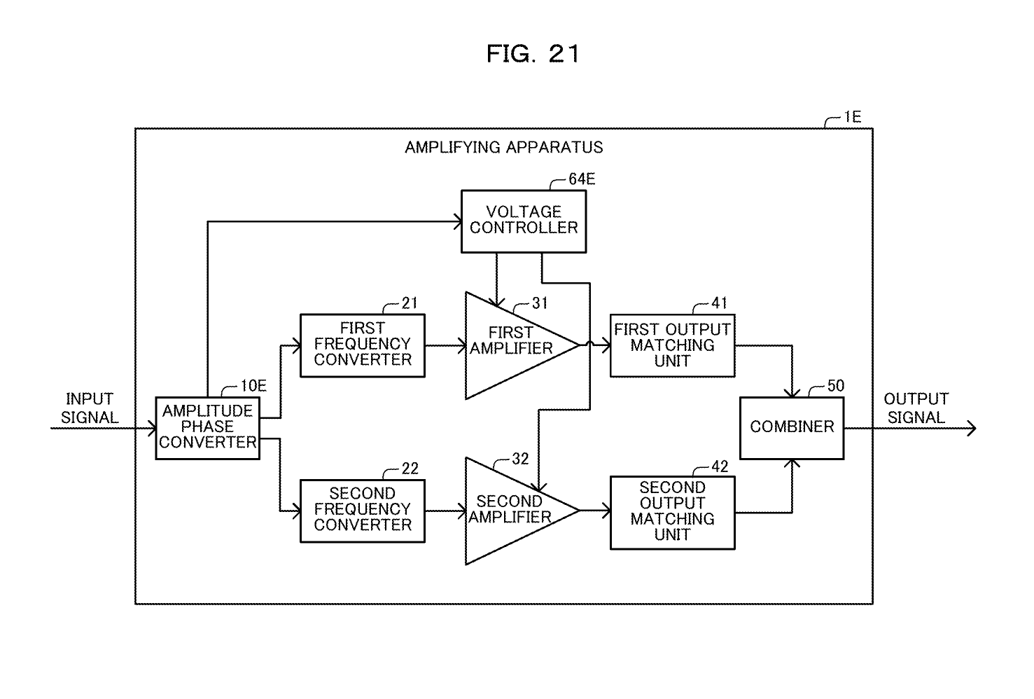

As illustrated in FIG. 21, an amplifying apparatus 1E according to the fourth embodiment includes, instead of the amplitude phase converter 10 of the amplifying apparatus 1 in FIG. 2, an amplitude phase converter 10E.

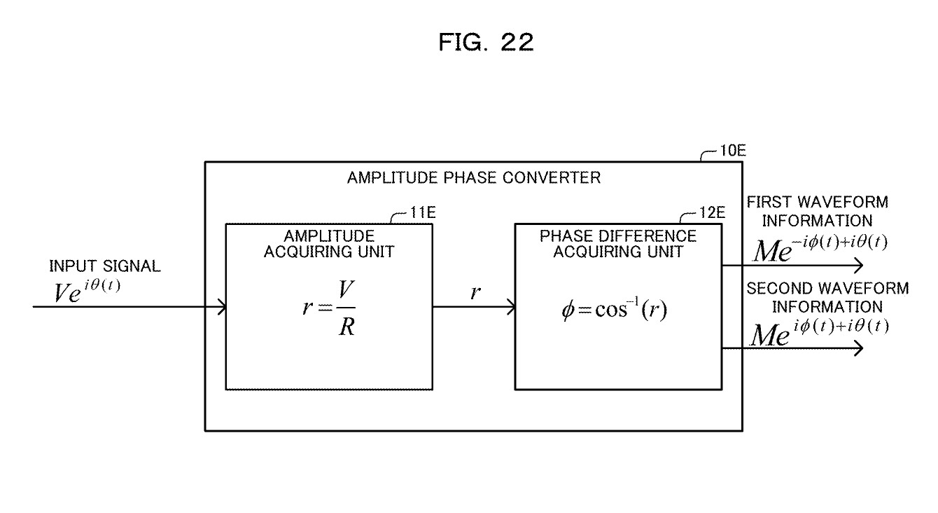

The amplitude phase converter 10E includes, as illustrated in FIG. 22, an amplitude acquiring unit 11E and a phase difference acquiring unit 12E.

The amplitude acquiring unit 11E acquires, based on the input signal, the amplitude (normalized amplitude) r of the input signal normalized so that the maximum value thereof is 1 based on the Formula 2. The amplitude acquiring unit 11E outputs the acquired normalized amplitude r without a correction to the phase difference acquiring unit 12E.

The phase difference acquiring unit 12E acquires the decomposition phase φ based on the normalized amplitude r output by the amplitude acquiring unit 11E. In this example, the phase difference acquiring unit 12E acquires, as represented in the Formula 27, the arc cosine of the normalized amplitude r as the decomposition phase φ.

The phase difference acquiring unit 12E generates first waveform information and second waveform information based on the acquired decomposition phase φ and outputs the generated first waveform information to the first frequency converter 21 and also outputs the generated second waveform information to the second frequency converter 22. Each of the first waveform information and the second waveform information is information indicating a waveform represented by the amplitude and the phase.

In this example, the first waveform information is, as represented in Formula 5, information indicating a waveform (for example, a cosine wave or a sine wave) in which the amplitude is M and the phase is represented as −φ+θ. Similarly, the second waveform information is, as represented in Formula 6, information indicating a waveform in which the amplitude is M and the phase is represented as φ+θ.

In this example, therefore, the waveform indicated by the first waveform information and the waveform indicated by the second waveform information have a phase difference of a value obtained by doubling the decomposition phase φ. The phase difference matches, as will be described later, the phase difference between the first decomposed signal output by the first frequency converter 21 and the second decomposed signal output by the second frequency converter 22.

Further, as illustrated in FIG. 21, the amplifying apparatus 1E according to the fourth embodiment is different from the amplifying apparatus 1 in FIG. 2 in that a voltage controller 64E is additionally included. The voltage controller 64E is an example of the controller.

In this example, the first amplifier 31 amplifies the first decomposed signal by operating as an AB-class or B-class amplifier. Similarly, the second amplifier 32 amplifies the second decomposed signal by operating as an AB-class or B-class amplifier. The operation of the first amplifier 31 (or the second amplifier 32) as an AB-class or B-class amplifier is an example of the saturated operation of the first amplifier 31 (or the second amplifier 32).

When the amplitude of the input signal is larger than a third threshold, the voltage controller 64E controls a power supply voltage supplied (or applied) to each of the first amplifier 31 and the second amplifier 32 to a first voltage. In the case of, for example, a source-grounded FET, the power supply voltage is a voltage applied to between a source terminal and a drain terminal. When, instead of the FET, an amplifying element other than the FET is used, for example, an emitter-grounded bipolar transistor is used, the power supply voltage may be a voltage applied to between an emitter terminal and a collector terminal. In this example, the amplitude of the input signal is the amplitude (normalized amplitude) of the input signal normalized such that the maximum value thereof is 1. The amplitude of the input signal may be the real amplitude of the input signal.

The first voltage is a voltage causing each of the first amplifier 31 and the second amplifier 32 to operate as a B-class amplifier.

The voltage controller 64E may control, after acquiring the instantaneous value of power of the input signal, the power supply voltage supplied to each of the first amplifier 31 and the second amplifier 32 based on whether the acquired instantaneous value is larger than a power threshold. For example, the voltage controller 64E calculates, as the instantaneous value of power, a product of the instantaneous value of the voltage and the instantaneous value of the current. The instantaneous value of power may be a representative value (for example, the average value, minimum value, or maximum value) of power in a very short time with respect to the period of fundamental wave components of the input signal. A state in which the instantaneous value is larger than a power threshold is an example of a state in which the amplitude of an input signal is larger than a third amplitude threshold.

On the other hand, when the amplitude of the input signal is equal to or smaller than the third amplitude threshold, the voltage controller 64E controls the power supply voltage supplied to each of the first amplifier 31 and the second amplifier 32 to a second voltage, which is larger than the first voltage. The third amplitude threshold is an example of a second threshold.

In this example, the second voltage is a voltage causing each of the first amplifier 31 and the second amplifier 32 to operate as an AB-class amplifier. The state in which the first amplifier 31 (or the second amplifier 32) operates as an AB-class amplifier is closer to an unsaturated operation state than the state in which the first amplifier 31 (or the second amplifier 32) operates as a B-class amplifier. The unsaturated operation state is a state in which the first amplifier 31 (or the second amplifier 32) performs the unsaturated operation. For example, the operation of the first amplifier 31 (or the second amplifier 32) as an A-class amplifier is an example of the unsaturated operation of the first amplifier 31 (or the second amplifier 32).

The second voltage may be a voltage higher than the voltage causing each of the first amplifier 31 and the second amplifier 32 to operate as an AB-class amplifier. Also, the second voltage may be a voltage lower than the voltage causing each of the first amplifier 31 and the second amplifier 32 to operate as an AB-class amplifier.

(Operation)

Next, the operation of the amplifying apparatus 1E will be described.

First, when an input signal is input into the amplifying apparatus 1E, the amplitude phase converter 10E acquires the normalized amplitude r based on the input signal.

When the normalized amplitude r acquired by the amplitude phase converter 10E is larger than the third amplitude threshold, the voltage controller 64E controls the power supply voltage supplied to each of the first amplifier 31 and the second amplifier 32 to the first voltage. Accordingly, each of the first amplifier 31 and the second amplifier 32 operates as a B-class amplifier.

On the other hand, when the normalized amplitude r acquired by the amplitude phase converter 10E is equal to or smaller than the third amplitude threshold, the voltage controller 64E controls the power supply voltage supplied to each of the first amplifier 31 and the second amplifier 32 to the second voltage. Accordingly, each of the first amplifier 31 and the second amplifier 32 operates as an AB-class amplifier.

Next, the amplitude phase converter 10E acquires the decomposition phase φ based on the acquired normalized amplitude r. Then, the amplitude phase converter 10E generates the first waveform information and the second waveform information based on the acquired decomposition phase φ and the amplification factor M. Next, the amplitude phase converter 10E outputs the generated first waveform information to the first frequency converter 21 and also outputs the generated second waveform information to the second frequency converter 22.

Thereafter, the amplifying apparatus 1E amplifies the input signal by the amplification factor and outputs the amplified signal as an output signal by operating in the same manner as the amplifying apparatus 1.

According to the amplifying apparatus 1E in the fourth embodiment, as described above, just like the amplifying apparatus 1 according to the first embodiment, operating states of the two amplifiers 31, 32 are controlled such that the output characteristic of the combiner 50 matches the desired characteristic.

Accordingly, the output characteristic of the combiner 50 can be matched to the desired characteristic. For example, when the real amplitude of the input signal is 0, the amplitude of the output signal from the combiner 50 can be brought closer to 0. As a result, the output characteristic (amplification characteristic) of the amplifying apparatus 1E can be improved.

In the amplifying apparatus 1E according to the fourth embodiment, each of the two amplifiers 31, 32 performs amplification by performing the saturated operation. Further, when the normalized amplitude r is smaller than the third amplitude threshold, the amplifying apparatus 1E controls the two amplifiers 31, 32 such that the states of the amplifiers 31, 32 are brought closer to the unsaturated operation state in which the amplifiers 31, 32 perform the unsaturated operation.

In a situation in which the normalized amplitude r is very small, the output characteristic of the combiner 50 can be matched to the desired characteristic when the amplifiers 31, 32 are in the unsaturated operation state rather than in the saturated operation state. Therefore, according to the amplifying apparatus 1E, the amplification characteristic can be improved.

The amplifying apparatus 1E according to the fourth embodiment makes the power supply voltage supplied to the amplifiers 31, 32 larger when the normalized amplitude r is smaller than the third amplitude threshold than when the normalized amplitude r is larger than the third amplitude threshold. In this manner, the amplifying apparatus 1E brings the states of the amplifiers 31, 32 closer to the unsaturated operation state.

Accordingly, the states of the amplifiers 31, 32 can be brought closer to the unsaturated operation state. As a result, the amplification characteristic can be improved.

The voltage controller 64E according to the fourth embodiment may control the power supply voltage of only one of the first amplifier 31 and the second amplifier 32.

Also, the amplifying apparatus 1E according to the fourth embodiment may include, instead of the amplitude phase converter 10E, the amplitude phase converter 10 in FIG. 3, the amplitude phase converter 10C in FIG. 12, or the amplitude phase converter 10D in FIG. 17.

The voltage controller 64E according to the fourth embodiment may control, instead of the power supply voltage of the first amplifier 31 and the second amplifier 32, a bias voltage of the first amplifier 31 and the second amplifier 32.

In the case of, for example, a source-grounded FET, the bias voltage is a voltage applied to between a source terminal and a gate terminal. When, instead of the FET, an amplifying element other than the FET is used, for example, an emitter-grounded bipolar transistor is used, the bias voltage may be a voltage applied to between an emitter terminal and a base terminal.

In this case, when the amplitude of the input signal is larger than the third amplitude threshold, the voltage controller 64E controls the bias voltage supplied (or applied) to each of the first amplifier 31 and the second amplifier 32 to a third voltage. On the other hand, when the amplitude of the input signal is equal to or smaller than the third amplitude threshold, the voltage controller 64E controls the bias voltage supplied to each of the first amplifier 31 and the second amplifier 32 to a fourth voltage, which is larger than the third voltage.

For example, each of the third voltage and the fourth voltage have negative values. In this case, the absolute value of the third voltage is larger than the absolute value of the fourth voltage.

The third voltage is a voltage causing each of the first amplifier 31 and the second amplifier 32 to operate as a B-class amplifier. The fourth voltage is a voltage causing each of the first amplifier 31 and the second amplifier 32 to operate as an AB-class amplifier.

The fourth voltage may be a voltage higher than the voltage causing each of the first amplifier 31 and the second amplifier 32 to operate as an AB-class amplifier. Also, the fourth voltage may be a voltage lower than the voltage causing each of the first amplifier 31 and the second amplifier 32 to operate as an AB-class amplifier.

Also in this case, just like the amplifying apparatus 1E according to the fourth embodiment, the amplification characteristic can be improved.

### Modified Example of the Fourth Embodiment

Next, an amplifying apparatus according to the modified example of the fourth embodiment will be described. The amplifying apparatus according to the modified example of the fourth embodiment is different from the amplifying apparatus according to the fourth embodiment in that the states of amplifiers are brought closer to an unsaturated state by disconnecting a harmonic processor from a line on which an amplified signal is transmitted. The following description focuses on such a difference.

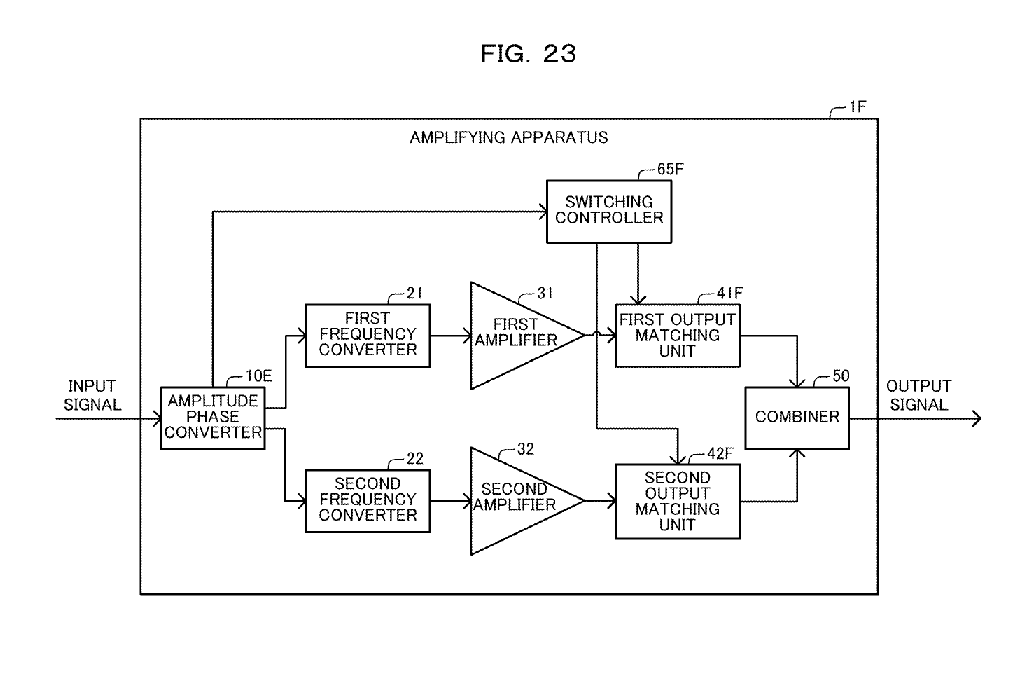

As illustrated in FIG. 23, an amplifying apparatus 1F according to the modified example of the fourth embodiment includes, instead of the voltage controller 64E of the amplifying apparatus 1E in FIG. 21, a switching controller 65F. Further, the amplifying apparatus 1F includes, instead of the first output matching unit 41 and the second output matching unit 42 of the amplifying apparatus 1E in FIG. 21, a first output matching unit 41F and a second output matching unit 42F respectively. The switching controller 65F is an example of the controller.

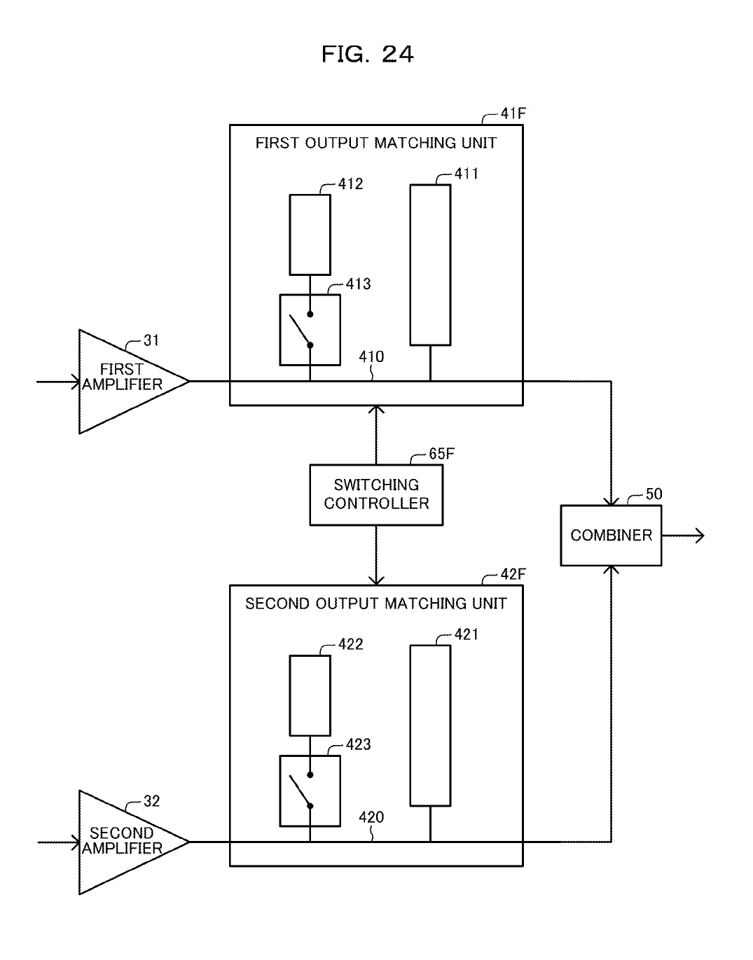

As illustrated in FIG. 24, the first output matching unit 41F includes a transmission line 410, a fundamental wave matching circuit 411, a harmonic processing circuit 412, and a switch 413.

The transmission line 410 outputs the first amplified signal output by the first amplifier 31 to the combiner 50 by transmitting the signal thereto.

The fundamental wave matching circuit 411 is connected to the transmission line 410. The fundamental wave matching circuit 411 matches the output impedance of the first amplifier 31 and an input impedance of the combiner 50 for the fundamental wave component of the first amplified signal output by the first amplifier 31. The fundamental wave component is a component having the same frequency as that of an input signal of the first amplifier 31.

The harmonic processing circuit 412 is connected to the transmission line 410 via the switch 413. The harmonic processing circuit 412 processes harmonic components of the first amplified signal output by the first amplifier 31. The harmonic components are components having frequencies that are integral multiples of the frequency of the input signal of the first amplifier 31. The n-th (n is a natural number) order harmonic component is a component having a frequency obtained by multiplying the frequency of the input signal of the first amplifier 31 by n.

For example, the harmonic processing circuit 412 shorts the first amplifier 31 and the combiner 50 for even-order (for example, the second order, fourth order or the like) harmonic components of the first amplified signal. Further, the harmonic processing circuit 412 opens the first amplifier 31 and the combiner 50 for odd-order (for example, the third order, fifth order or the like) harmonic components of the first amplified signal.

For example, the harmonic processing circuit 412 may have an electric length of λ/8. In this case, the harmonic processing circuit 412 shorts the first amplifier 31 and the combiner 50 for the second-order harmonic component of the first amplified signal. λ represents the wavelength of the fundamental wave component of the first amplified signal on the transmission line 410.

The switch 413 switches between a state (connected state) in which the transmission line 410 and the harmonic processing circuit 412 are connected and a state (disconnected state) in which the transmission line 410 and the harmonic processing circuit 412 are disconnected.

As illustrated in FIG. 24, the second output matching unit 42F includes a transmission line 420, a fundamental wave matching circuit 421, a harmonic processing circuit 422, and a switch 423. The transmission line 420, the fundamental wave matching circuit 421, the harmonic processing circuit 422, and the switch 423 have functions similar to those of the transmission line 410, the fundamental wave matching circuit 411, the harmonic processing circuit 412, and the switch 413 respectively.

When the amplitude of the input signal is larger than the third amplitude threshold, the switching controller 65F controls each state of the switch 413 and the switch 423 to the connected state. In this example, the amplitude of the input signal is the amplitude (normalized amplitude) r of the input signal normalized so that the maximum value thereof is 1. The amplitude of the input signal may be the real amplitude of the input signal.

The switching controller 65F may control, after acquiring the instantaneous value of power of the input signal, the switch 413 and the switch 423 based on whether the acquired instantaneous value is larger than a power threshold. For example, the switching controller 65F calculates, as the instantaneous value of power, a product of the instantaneous value of the voltage and the instantaneous value of the current. The instantaneous value of power may be a representative value (for example, the average value, minimum value, or maximum value) of power in a very short time with respect to the period of fundamental wave components of the input signal. A state in which the instantaneous value is larger than the power threshold is an example of a state in which the amplitude of an input signal is larger than the third amplitude threshold.

On the other hand, when the amplitude of the input signal is equal to or smaller than the third amplitude threshold, the switching controller 65F controls each state of the switch 413 and the switch 423 to the disconnected state. The third amplitude threshold is an example of the second threshold.

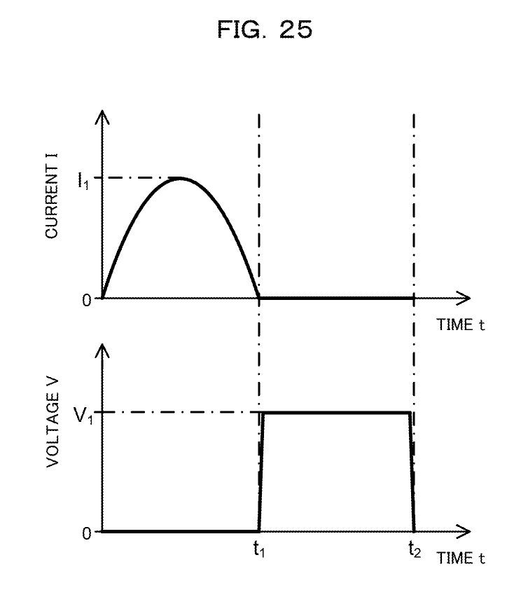

A case in which the first amplifier 31 operates as an F-class amplifier is assumed. In this case, a case in which the state of the switch 413 is controlled to the connected state is assumed. In this case, as illustrated in FIG. 25, the waveform of a current I of the first amplified signal output by the first amplifier 31 is a half-wave rectification waveform. That is, the current I matches a sine wave having a predetermined amplitude (I₁ in this example) in a period of time t ranging from 0 to t₁ and is 0 in a period of time t ranging from t₁ to t₂. The waveform of a voltage V of the first amplified signal is, as illustrated in FIG. 25, a rectangular wave. That is, the voltage V is 0 in the period of time t ranging from 0 to t₁ and has a fixed positive value φ′₂ in this example) in the period of time t ranging from t₁ to t₂.

In this case, power P₁ for the fundamental wave component of the first amplified signal is represented by Formula 30.

$${P}_{1} = \frac{{I}_{1} {V}_{1}}{2 π} \approx 0.16 {I}_{1} {V}_{1} \qquad [ Mathematical Formula 30 ]$$

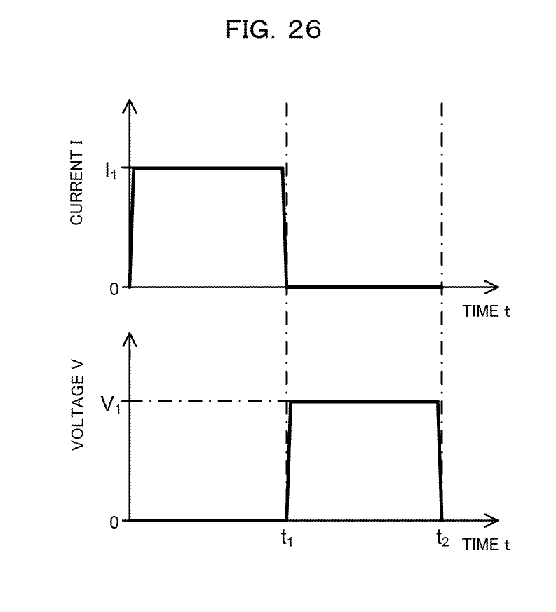

On the other hand, a case in which the state of the switch 413 is controlled to the disconnected state is assumed. In this case, as illustrated in FIG. 26, the waveform of the current I of the first amplified signal output by the first amplifier 31 is a rectangular wave. That is, the current I has a fixed positive value (I₁ in this example) in a period of time t ranging from 0 to t₁ and is 0 in a period of time t ranging from t₁ to t₂. The waveform of the voltage V of the first amplified signal is, as illustrated in FIG. 26, a rectangular wave. That is, the voltage V is 0 in the period of time t ranging from 0 to t₁ and has a fixed positive value φ′₁ in this example) in the period of time t ranging from t₁ to t₂.

In this case, power P₂ for the fundamental wave component of the first amplified signal is represented by Formula 31.

$${P}_{2} = \frac{2 {I}_{1} {V}_{1}}{{π}^{2}} \approx 0.20 {I}_{1} {V}_{1} \qquad [ Mathematical Formula 31 ]$$

Thus, in a case in which the input level is the same, the power for the fundamental wave component of the first amplified signal is smaller when the switch 413 is in the connected state than when the switch 413 is in the disconnected state. The input level represents the magnitude of a signal (for example, the amplitude of a signal) input into the first amplifier 31.

Thus, the first amplifier 31 is more likely to perform the saturated operation when the switch 413 is in the connected state than when the switch 413 is in the disconnected state. In other words, the state of the first amplifier 31 (or the second amplifier 32) is closer to the unsaturated operation state when the state of the switch 413 (or the switch 423) is controlled to the disconnected state than when the state of the switch 413 (or the switch 423) is controlled to the connected state.

(Operation)

Next, the operation of the amplifying apparatus 1F will be described.

First, when an input signal is input into the amplifying apparatus 1F, the amplitude phase converter 10E acquires the normalized amplitude r based on the input signal.

When the normalized amplitude r acquired by the amplitude phase converter 10E is larger than the third amplitude threshold, the switching controller 65F controls each state of the switch 413 and the switch 423 to the connected state. On the other hand, when the normalized amplitude r acquired by the amplitude phase converter 10E is equal to or smaller than the third amplitude threshold, the switching controller 65F controls each state of the switch 413 and the switch 423 to the disconnected state.

Next, the amplitude phase converter 10E acquires the decomposition phase φ based on the acquired normalized amplitude r. Then, the amplitude phase converter 10E generates the first waveform information and the second waveform information based on the acquired decomposition phase φ and the amplification factor M. Next, the amplitude phase converter 10E outputs the generated first waveform information to the first frequency converter 21 and also outputs the generated second waveform information to the second frequency converter 22.

Thereafter, the amplifying apparatus 1F amplifies the input signal by the amplification factor and outputs the amplified signal as an output signal by operating in the same manner as the amplifying apparatus 1.

According to the amplifying apparatus 1F in the modified example of the fourth embodiment, as described above, just like the amplifying apparatus 1 according to the first embodiment, operating states of the two amplifiers 31, 32 are controlled such that the output characteristic of the combiner 50 matches the desired characteristic.

Accordingly, the output characteristic of the combiner 50 can be matched to the desired characteristic. For example, when the real amplitude of the input signal is 0, the amplitude of the output signal from the combiner 50 can be brought closer to 0. As a result, the output characteristic (amplification characteristic) of the amplifying apparatus 1F can be improved.

In the amplifying apparatus 1F according to the modified example of the fourth embodiment, each of the two amplifiers 31, 32 performs amplification by performing the saturated operation. Further, when the normalized amplitude r is smaller than the third amplitude threshold, the amplifying apparatus 1F controls the two amplifiers 31, 32 such that the states of the amplifiers 31, 32 are brought closer to the unsaturated operation state in which the amplifiers 31, 32 perform the unsaturated operation.

In a situation in which the normalized amplitude r is very small, the output characteristic of the combiner 50 can be matched to the desired characteristic when the amplifiers 31, 32 are in the unsaturated operation state rather than in the saturated operation state. Therefore, according to the amplifying apparatus 1F, the amplification characteristic can be improved.

When the normalized amplitude r is smaller than the third amplitude threshold, the amplifying apparatus 1F according to the modified example of the fourth embodiment disconnects the harmonic processing circuit 412 from the transmission line 410 and also disconnects the harmonic processing circuit 422 from the transmission line 420. Accordingly, the amplifying apparatus 1F brings the states of the amplifiers 31, 32 closer to an unsaturated state.

Accordingly, the states of the amplifiers 31, 32 can be brought closer to an unsaturated state. As a result, the amplification characteristic can be improved.

The switching controller 65F according to the modified example of the fourth embodiment may control only one of the first output matching unit 41F and the second output matching unit 42F.

The amplifying apparatus 1F according to the modified example of the fourth embodiment may include, instead of the amplitude phase converter 10E, the amplitude phase converter 10 in FIG. 3, the amplitude phase converter 10C in FIG. 12, or the amplitude phase converter 10D in FIG. 17.

### Fifth Embodiment

Next, an amplifying apparatus according to the fifth embodiment will be described. The amplifying apparatus according to the fifth embodiment is different from the amplifying apparatus according to the first embodiment in that the functions of the amplifying apparatuses according to the second and third embodiments are combined and used. The following description focuses on such a difference.

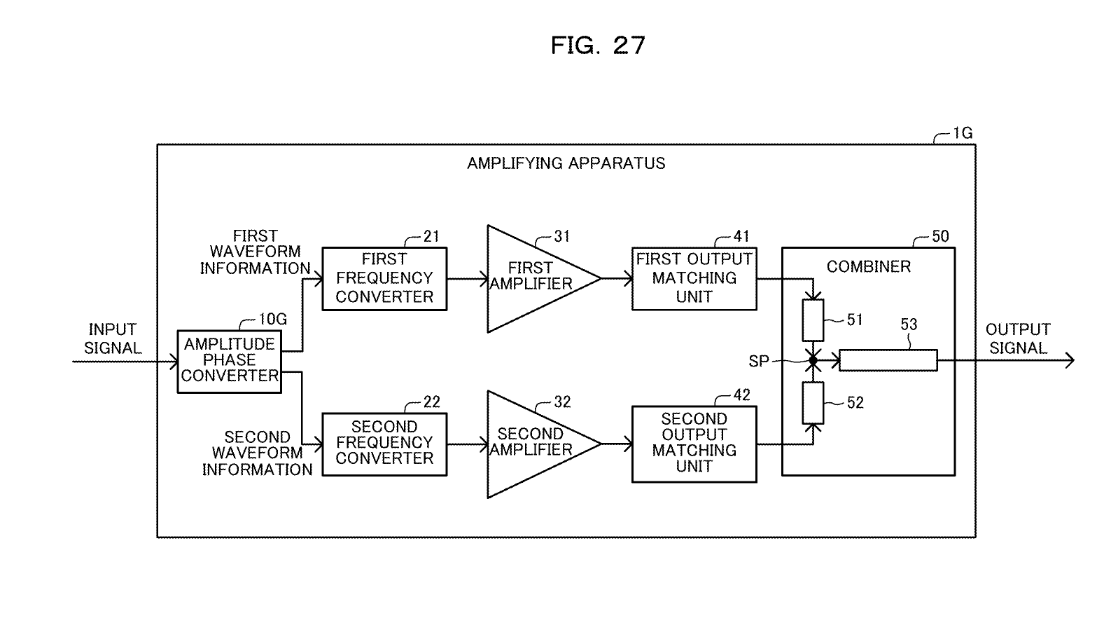

As illustrated in FIG. 27, an amplifying apparatus 1G according to the fifth embodiment includes, instead of the amplitude phase converter 10 of the amplifying apparatus 1 in FIG. 2, an amplitude phase converter 10G.

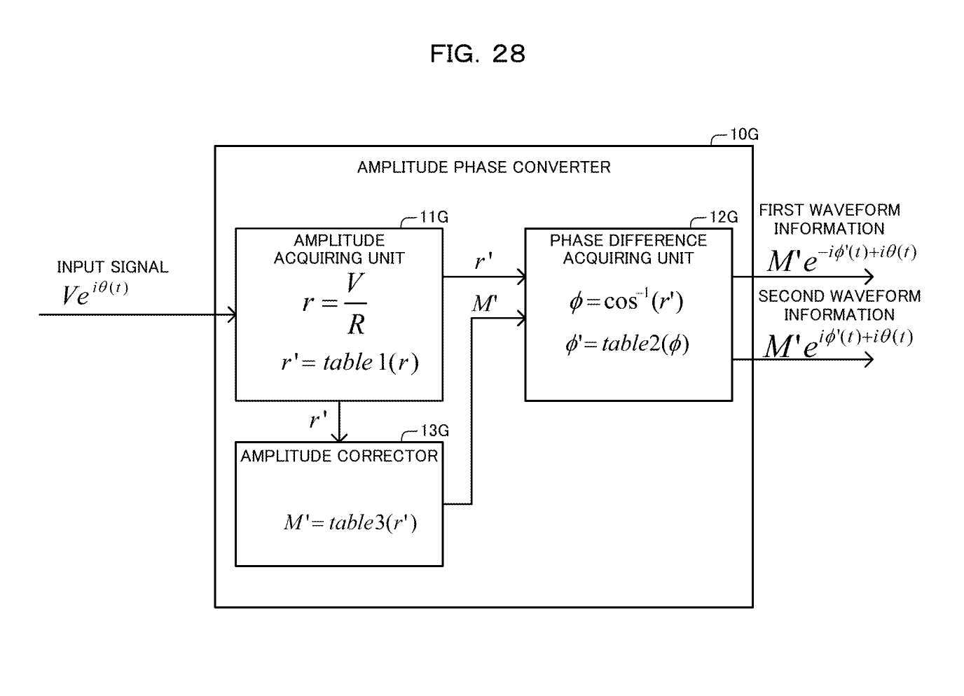

The amplitude phase converter 10G includes, as illustrated in FIG. 28, an amplitude acquiring unit 11G, a phase difference acquiring unit 12G and an amplitude corrector 13G.

The amplitude acquiring unit 11G acquires, based on the input signal, the amplitude (first normalized amplitude) r of the input signal normalized such that the maximum value thereof is 1 based on the Formula 2. The amplitude acquiring unit 11G holds a first table similar to that of the amplitude acquiring unit 11 according to the first embodiment in advance (for example, stored in a memory).

The amplitude acquiring unit 11G acquires, as represented in the Formula 3, the second normalized amplitude r′ based on the held first table and the acquired first normalized amplitude r. The amplitude acquiring unit 11G outputs the acquired second normalized amplitude r′ to each of the phase difference acquiring unit 12G and the amplitude corrector 13G.

The amplitude corrector 13G holds the third table similar to that of the amplitude corrector 13D according to the third embodiment in advance. The amplitude corrector 13G acquires, as represented in Formula 32, the amplitude (decomposition amplitude) M′ after the correction associated with the second normalized amplitude r′ output by the amplitude acquiring unit 11G in the held third table. The amplitude corrector 13G outputs the acquired decomposition amplitude M′ to the phase difference acquiring unit 12G.

M′=table3(r′) [Mathematical Formula 32]

The phase difference acquiring unit 12G acquires, as represented in the Formula 4, the first decomposition phase φ based on the second normalized amplitude r′ output by the amplitude acquiring unit 11G. The phase difference acquiring unit 12G holds the second table similar to that of the phase difference acquiring unit 12C according to the second embodiment in advance. The phase difference acquiring unit 12G acquires, as represented in the Formula 19, the second decomposition phase φ′ based on the held second table and the acquired first decomposition phase φ.

The phase difference acquiring unit 12G generates first waveform information and second waveform information based on the acquired second decomposition phase φ′ and the decomposition amplitude M′ output by the amplitude corrector 13G. Each of the first waveform information and the second waveform information is information indicating a waveform represented by the amplitude and the phase.

In this example, the first waveform information is, as represented in Formula 33, information indicating a waveform (for example, a cosine wave or a sine wave) in which the amplitude is the decomposition amplitude M′ and the phase is −φ′+θ. Similarly, the second waveform information is, as represented in Formula 34, information indicating a waveform in which the amplitude is the decomposition amplitude M′ and the phase is φ′+θ.

M′e^{-iφ′+iθ} [Mathematical Formula 28]

M′e^{iφ′+iθ} [Mathematical Formula 29]

In this example, therefore, the waveform indicated by the first waveform information and the waveform indicated by the second waveform information have a phase difference equal to a value obtained by doubling the second decomposition phase φ′. The phase difference matches, as described above, the phase difference between the first decomposed signal output by the first frequency converter 21 and the second decomposed signal output by the second frequency converter 22.

According to the amplifying apparatus 1G in the fifth embodiment, operations and effects similar to those of the amplifying apparatuses according to the first to third embodiments can be obtained.

In the amplifying apparatus 1G according to the fifth embodiment, the amplitude corrector 13G may acquire, as represented in the Formula 26, the decomposition amplitude M′ based on the third table and the first normalized amplitude r.

The amplifying apparatus 1G according to the fifth embodiment may hold a first decomposed signal table and a second decomposed signal table for each of the first to third tables. The first decomposed signal table is used to generate the first decomposed signal. The second decomposed signal table is used to generate the second decomposed signal. Accordingly, even if the first amplifier 31 and the second amplifier 32 have different characteristics, the amplification characteristic can be improved by making the first decomposed signal table and the second decomposed signal table different.

The amplifying apparatus 1G according to the fifth embodiment makes corrections of all of the normalized amplitude, the decomposition phase, and the decomposition amplitude, but may make corrections of any two of the normalized amplitude, the decomposition phase, and the decomposition amplitude.

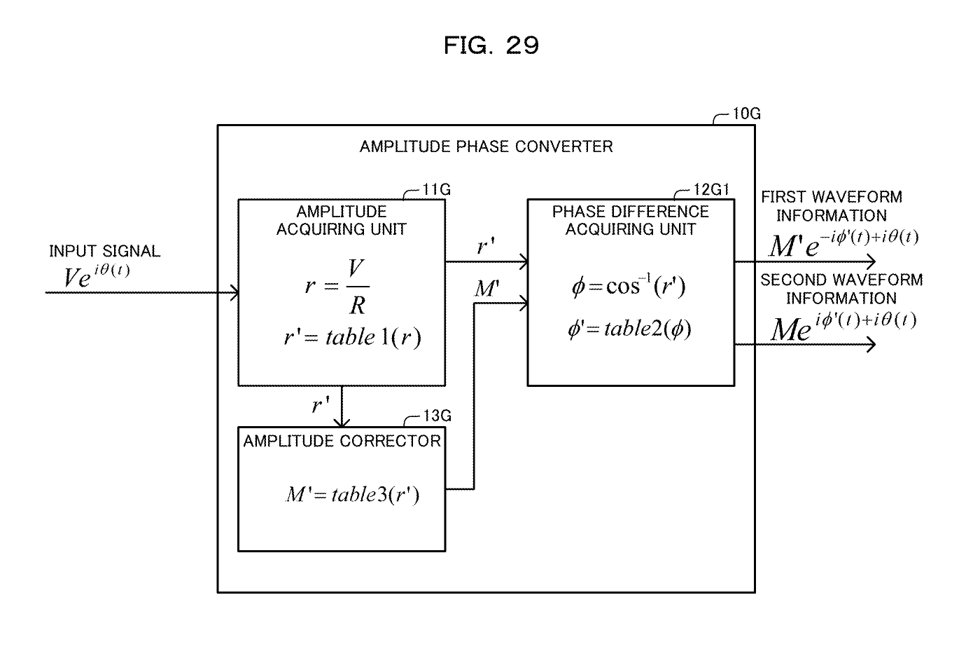

As illustrated in FIG. 29, a phase difference acquiring unit 12G1 is different from the phase difference acquiring unit 12G in that the decomposition amplitude M′ is used as the amplitude of the waveform indicated by the first waveform information and the amplification factor M is used as the amplitude of the waveform indicated by the second waveform information. The phase difference acquiring unit 12G1 may use the amplification factor M as the amplitude of the waveform indicated by the first waveform information and the decomposition amplitude M′ as the amplitude of the waveform indicated by the second waveform information.

### Sixth Embodiment

Next, an amplifying apparatus according to the sixth embodiment will be described. The amplifying apparatus according to the sixth embodiment is different from the amplifying apparatus according to the first embodiment in that the first waveform information is corrected such that a difference of output characteristics of the two amplifiers is compensated for. The following description focuses on such a difference.

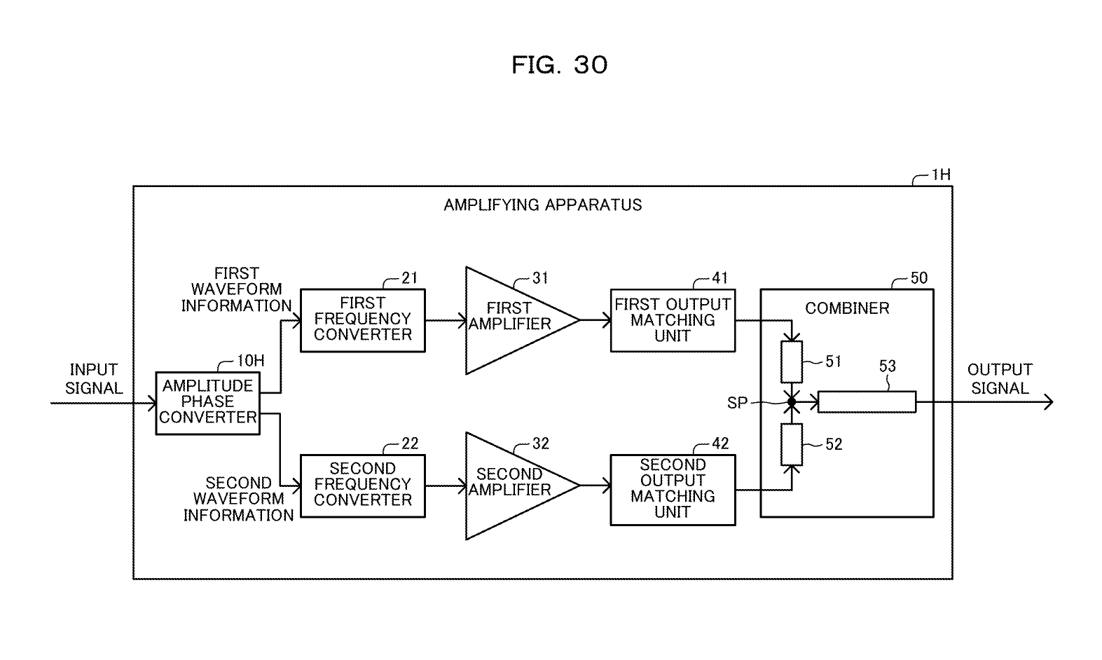

As illustrated in FIG. 30, an amplifying apparatus 1H according to the sixth embodiment includes, instead of the amplitude phase converter 10 of the amplifying apparatus 1 in FIG. 2, an amplitude phase converter 10H.

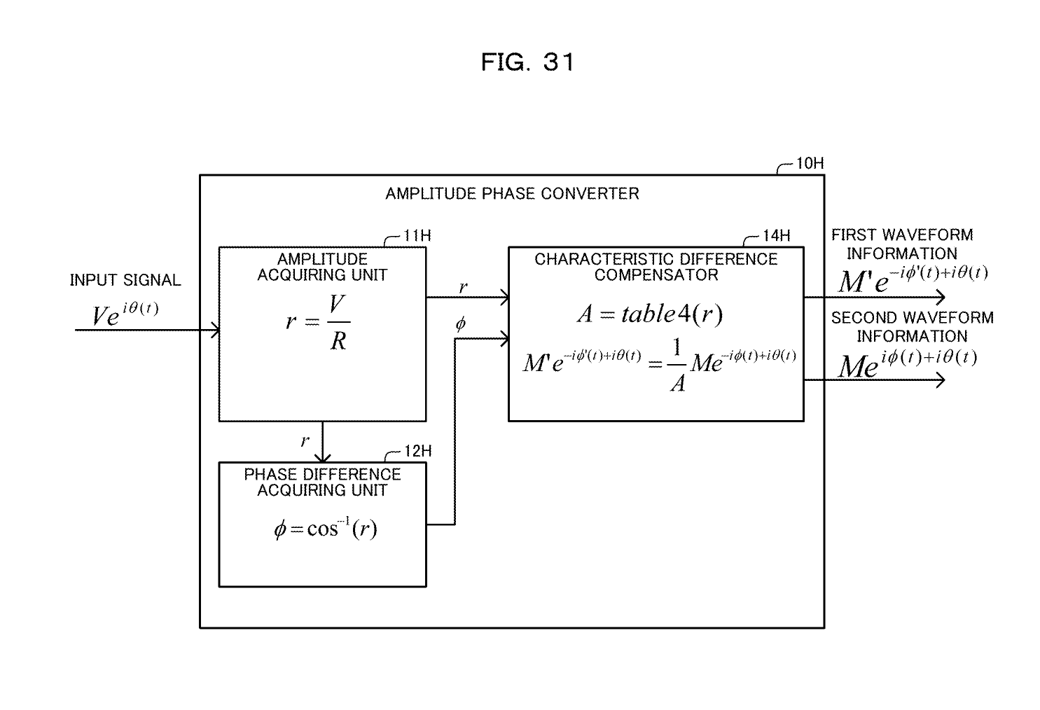

The amplitude phase converter 10H includes, as illustrated in FIG. 31, an amplitude acquiring unit 11H, a phase difference acquiring unit 12H, and a characteristic difference compensation unit 14H.

The amplitude acquiring unit 11H acquires, based on the input signal, the amplitude (normalized amplitude) r of the input signal normalized so that the maximum value thereof is 1 based on the Formula 2. The amplitude acquiring unit 11H outputs the acquired normalized amplitude r without a correction to each of the phase difference acquiring unit 12H and the characteristic difference compensation unit 14H.

The phase difference acquiring unit 12H acquires the decomposition phase φ based on the normalized amplitude r output by the amplitude acquiring unit 11H. In this example, the phase difference acquiring unit 12H acquires, as represented in the Formula 27, the arc cosine of the normalized amplitude r as the decomposition phase φ. The phase difference acquiring unit 12H outputs the acquired decomposition phase φ to the characteristic difference compensation unit 14H.

The characteristic difference compensation unit 14H generates first waveform information and second waveform information based on the normalized amplitude r output by the amplitude acquiring unit 11H and the decomposition phase φ output by the phase difference acquiring unit 12H.

In this example, the generated first waveform information is, as represented in Formula 35, information indicating a waveform (for example, a cosine wave or a sine wave) in which the amplitude is the amplification factor M and the phase is represented by −φ+θ. Similarly, the generated second waveform information is, as represented in Formula 36, information indicating a waveform in which the amplitude is the amplification factor M and the phase is represented by φ+θ.

Me^{-iφ+iθ} [Mathematical Formula 35]

Me^{iφ+iθ} [Mathematical Formula 36]

The characteristic difference compensation unit 14H holds a fourth table associating the normalized amplitude and an output characteristic value of the first amplifier 31 in advance (for example, stored in a memory). The output characteristic value is a value, which is obtained by dividing a value obtained by dividing the output of the first amplifier 31 by the input of the first amplifier 31 by the first amplification factor, for each normalized amplitude.

In this example, the output characteristic value is a value obtained by assuming that the output of the first amplifier 31 does not affect the characteristics of the second amplifier 32 due to the combiner 50 and the output of the second amplifier 32 affects the characteristics of the first amplifier 31 due to the combiner 50. In this example, therefore, the output characteristic value may also be interpreted as a value in a case where the second amplifier 32 is used as a reference. The output characteristic value is, for example, a complex number. The fourth table represents the output characteristics of the first amplifier 31.

The fourth table is set such that the output characteristic of the combiner 50 matches a desired characteristic. The desired characteristic includes, for example, a first characteristic, a second characteristic, or both. The first characteristic is a characteristic in which the amplitude of an output signal from the combiner 50 is 0 when the real amplitude of an input signal is 0. The second characteristic is a characteristic in which the relationship between the real amplitude of an input signal and the amplitude of an output signal from the combiner 50 is a linear relationship.

For example, a relationship between the fourth table and the output characteristic of the combiner 50 may be determined by an experiment or a simulation to set the fourth table based on the relationship. For example, the fourth table may be set such that a difference between output characteristics of the two amplifiers 31, 32 is compensated for.

As an example, the fourth table may be set such that the sum of a value obtained by multiplying the first decomposed signal by the output characteristic value and the second decomposed signal is matched to a value obtained by dividing the output signal from the combiner 50 by the first amplification factor. As another example, the fourth table may be set such that the magnitude of a difference between the sum of a value obtained by multiplying the first decomposed signal by the output characteristic value and the second decomposed signal and a value obtained by dividing the output signal from the combiner 50 by the first amplification factor is minimized (or is made equal to or smaller than a threshold).

The characteristic difference compensation unit 14H acquires, as represented in Formula 37, an output characteristic value A associated with the normalized amplitude r output by the amplitude acquiring unit 11H in the held fourth table.

A=table4(r) [Mathematical Formula 37]

The characteristic difference compensation unit 14H may hold, instead of the fourth table, a parameter to identify an output characteristic function as a function defining the relationship between the output characteristic value and the normalized amplitude to acquire the output characteristic value A based on the output characteristic function. For example, the output characteristic function is, as represented in Formula 38, a polynomial of the square of the normalized amplitude r. N represents a natural number. In this case, the parameter is the coefficient a₂ₘ₊₁. m represents an integer ranging from 0 to N. For example, when N is 3, the output characteristic function is represented by Formula 39. Incidentally, the square of the normalized amplitude r matches a product of the input signal and a conjugate complex number of the input signal.

$$\begin{matrix}A = {\sum }_{m = 0}^{N} {a}_{2 m + 1} {r}^{2 m} & [ Mathematical Formula 30 ] \\ A = {a}_{1} + {a}_{3} {r}^{2} + {a}_{5} {r}^{4} + {a}_{7} {r}^{6} & [ Mathematical Formula 39 ]\end{matrix}$$

The characteristic difference compensation unit 14H corrects the first waveform information by multiplying the generated first waveform information by a value of an inverse characteristic of the output characteristic of the first amplifier 31 (or by dividing the first waveform information by the output characteristic value A). In this example, the value of the inverse characteristic of the output characteristic of the first amplifier 31 is a reciprocal of the acquired output characteristic value A. The value of the inverse characteristic of the output characteristic of the first amplifier 31 may be a value other than the reciprocal of the output characteristic value A. The corrected first waveform information is, as represented in Formula 40, information indicating a waveform in which the amplitude is M′ and the phase is −φ′+θ.

M′e^{-iφ+iθ} [Mathematical Formula 40]

When the output characteristic value A is represented by Formula 41, the amplitude M′ and the phase φ′ are represented by Formula 42 and Formula 43 respectively

$$\begin{matrix}A = k {e}^{Δ φ} & [ Mathematical Formula 41 ] \\ {M}^{′} = \frac{M}{k} & [ Mathematical Formula 42 ] \\ {φ}^{′} = φ - Δ φ & [ Mathematical Formula 43 ]\end{matrix}$$

The characteristic difference compensation unit 14H outputs the corrected first waveform information to the first frequency converter 21 and also outputs the generated second waveform information to the second frequency converter 22.

(Operation)

Next, the operation of the amplifying apparatus 1H will be described.

First, when an input signal is input into the amplifying apparatus 1H, the amplitude phase converter 10H acquires the normalized amplitude r based on the input signal. Next, the amplitude phase converter 10H acquires the decomposition phase φ based on the acquired normalized amplitude r.

Then, the amplitude phase converter 10H generates the first waveform information and the second waveform information based on the acquired decomposition phase φ. Further, the amplitude phase converter 10H acquires the output characteristic value A based on the held fourth table and the acquired normalized amplitude r. Then, the amplitude phase converter 10H corrects the generated first waveform information based on the acquired output characteristic value A.

Next, the amplitude phase converter 10H outputs the corrected first waveform information to the first frequency converter 21 and also outputs the generated second waveform information to the second frequency converter 22.

Then, the amplifying apparatus 1H amplifies the input signal by the amplification factor and outputs the amplified signal as an output signal by operating in the same manner as the amplifying apparatus 1.

According to the amplifying apparatus 1H in the sixth embodiment, as described above, the waveform information, on which the first decomposed signal decomposed from the input signal is based, is controlled such that the output characteristic of the combiner 50 matches the desired characteristic.

Accordingly, the output characteristic of the combiner 50 can be matched to the desired characteristic. For example, when the real amplitude of the input signal is 0, the amplitude of the output signal from the combiner 50 can be brought closer to 0. Also, the relationship between the real amplitude of the input signal and the amplitude of the output signal from the combiner 50 can be brought closer to a linear relationship. As a result, the output characteristic (amplification characteristic) of the amplifying apparatus 1H can be improved.

Further, according to the amplifying apparatus 1H in the sixth embodiment, the difference of output characteristics of the two amplifiers 31, 32 can be compensated for. As a result, the amplification characteristic can be improved.

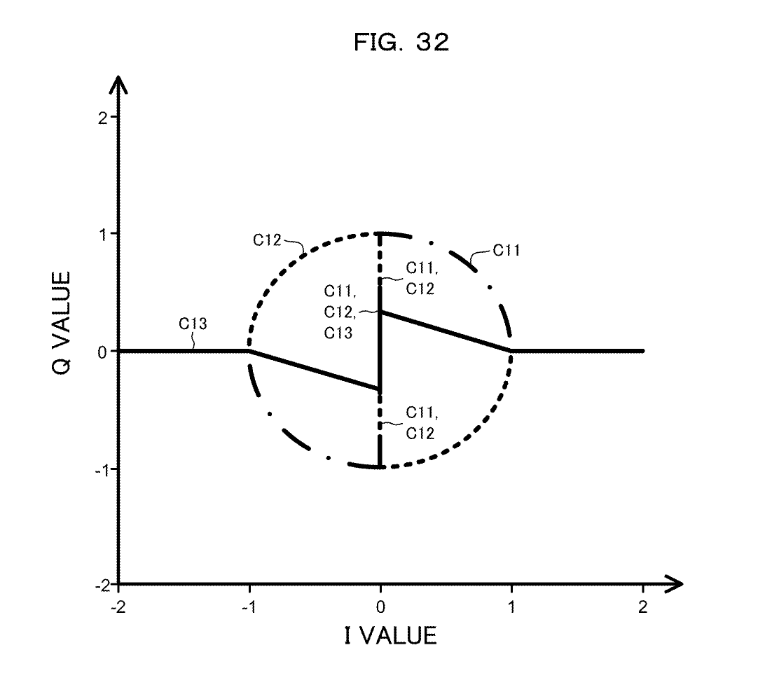

FIG. 32 is a graph illustrating an example of changes of first waveform information C11, second waveform information C12, and an output signal C13 for the normalized amplitude on a complex plane when the first waveform information is not corrected. The complex plane is a plane in which the vertical axis is an imaginary number axis and the horizontal axis is a real number axis. In this case, when the real number (I value) is in the range of −1 to 1, the output signal C13 has an imaginary number (Q value) that is different from 0 and changes discontinuously.

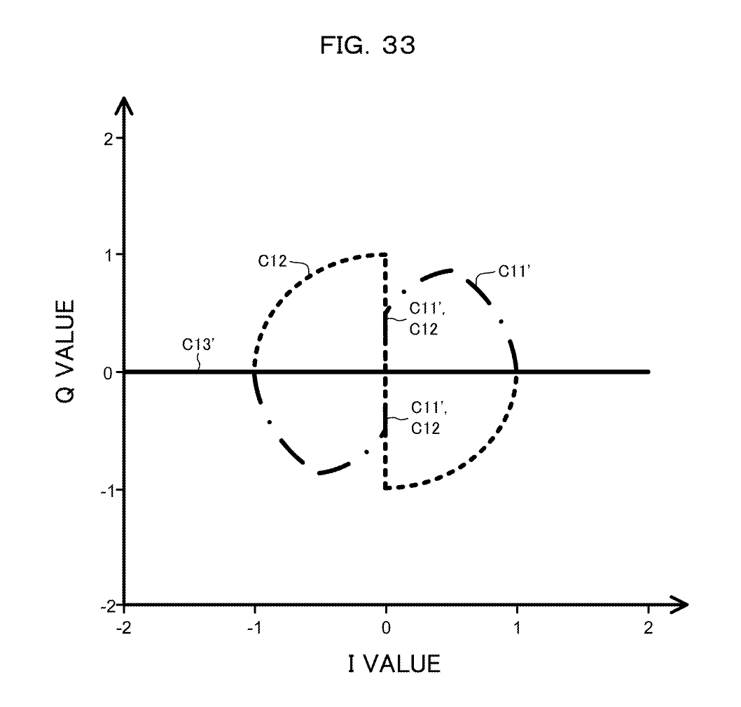

On the other hand, FIG. 33 is a graph illustrating an example of changes of first waveform information C11′, the second waveform information C12, and an output signal C13′ for the normalized amplitude on the complex plane when the first waveform information is corrected. In this case, the output signal C13′ has the imaginary number (Q value) of 0 and changes continuously even when the real number (I value) is in the range of −1 to 1. Thus, it is clear that the amplification characteristic can be improved by correcting the first waveform information.

The amplifying apparatus 1H according to the sixth embodiment corrects both of the amplitude and the phase of the first waveform information, but may correct only one of the amplitude and the phase.

The amplifying apparatus 1H according to the sixth embodiment may have a table, which is associating the normalized amplitude and an output characteristic value of the second amplifier 32, as the fourth table to correct second waveform information instead of first waveform information.

### Seventh Embodiment

Next, an amplifying apparatus according to the seventh embodiment will be described. The amplifying apparatus according to the seventh embodiment is different from the amplifying apparatus according to the sixth embodiment in that the output characteristic of the first amplifier 31 is estimated and the first waveform information is corrected based on the estimated output characteristic. The following description focuses on such a difference.

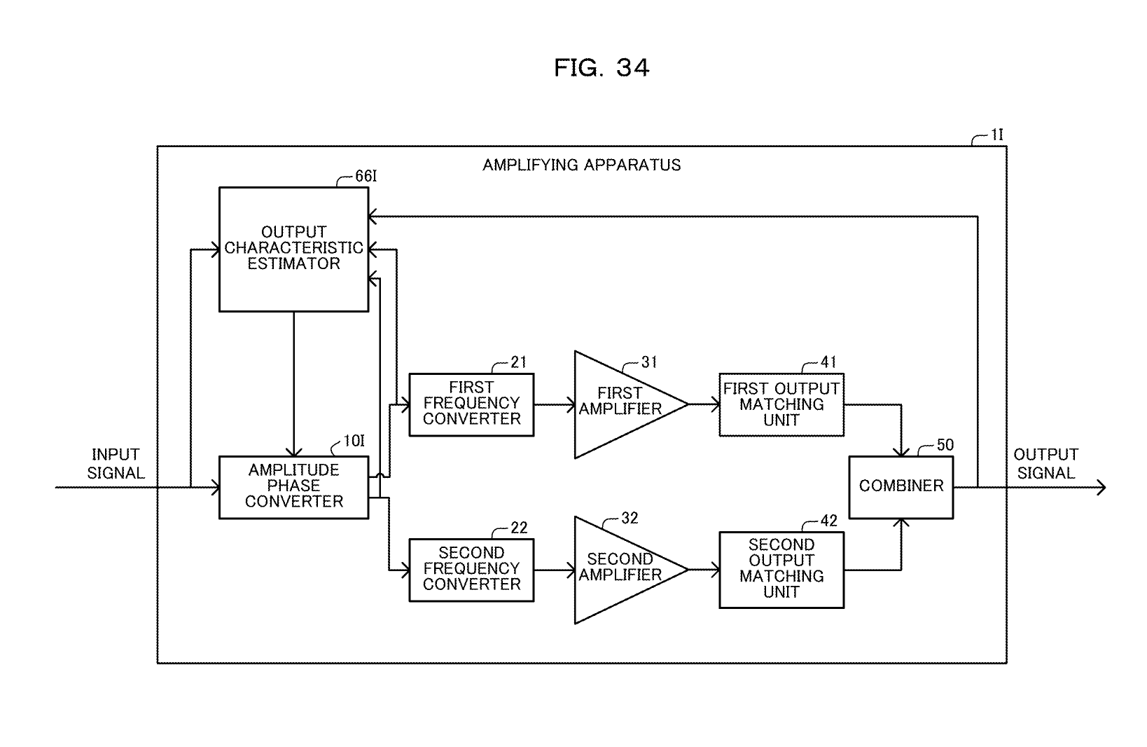

As illustrated in FIG. 34, an amplifying apparatus 1I according to the seventh embodiment includes, instead of the amplitude phase converter 10H of the amplifying apparatus 1H in FIG. 30, an amplitude phase converter 10I. Further, the amplifying apparatus 1I additionally includes an output characteristic estimator 66I when compared with the amplifying apparatus 1H in FIG. 30. The output characteristic estimator 66I is an example of the controller.

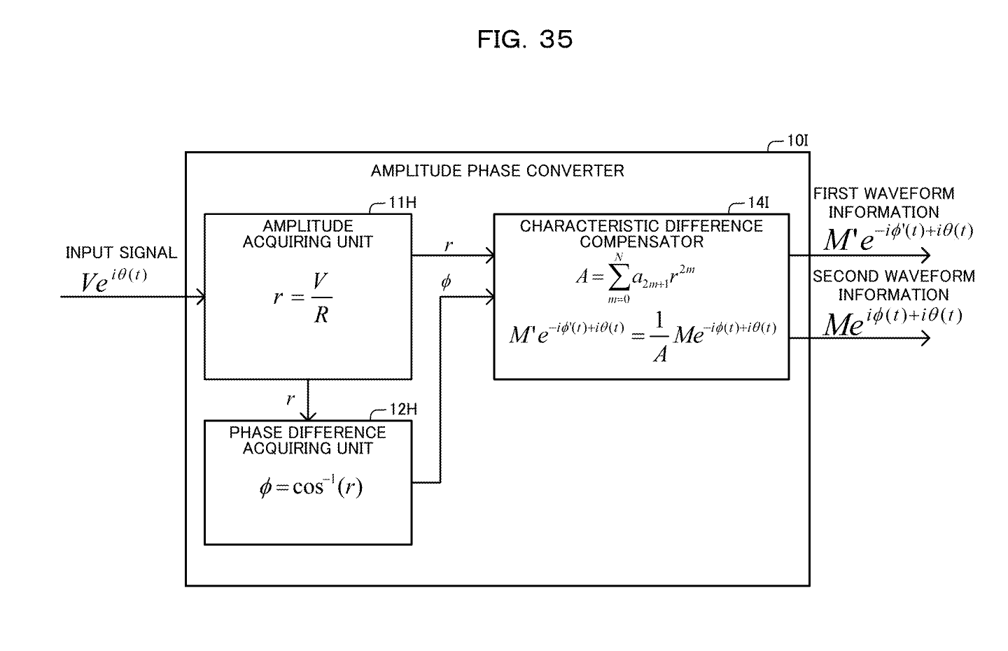

As illustrated in FIG. 35, the amplitude phase converter 10I includes, instead of the characteristic difference compensation unit 14H of the amplitude phase converter 10H in FIG. 31, a characteristic difference compensation unit 14I.

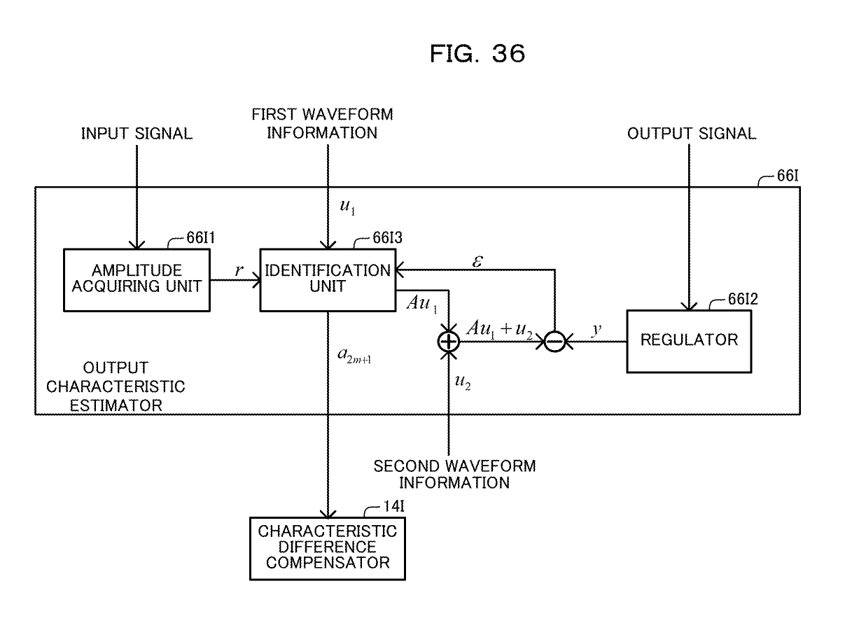

The output characteristic estimator 66I includes, as illustrated in FIG. 36, an amplitude acquiring unit 6611, a regulator 66I2, and an identification unit 6613.

The amplitude acquiring unit 6611 acquires, based on the input signal, the amplitude (normalized amplitude) r of the input signal normalized so that the maximum value thereof is 1 based on the Formula 2. The amplitude acquiring unit 6611 outputs the acquired normalized amplitude r to the identification unit 6613.

The regulator 66I2 regulates the amplitude and the phase of the output signal. In this example, the regulator 66I2 outputs a value, which is obtained by dividing the output signal by the first amplification factor, as a regulated output signal y.

The identification unit 6613 identifies the output characteristic function as a function that represents the output characteristic of the first amplifier 31. In this example, the output characteristic function is, as represented in the Formula 38, a polynomial of the square of the normalized amplitude r. N represents a natural number. For example, when N is 3, the output characteristic function is represented by the Formula 39. Incidentally, the square of the normalized amplitude r matches the product of the input signal and the conjugate complex number of the input signal.

The identification unit 6613 may identify the output characteristic function in the range in which the coefficient a₂ₘ₊₁ of the output characteristic function satisfies Formula 44. Accordingly, when the normalized amplitude r is the maximum value (1 in this example), the output characteristic value can be made a fixed value (1 in this example).

$${a}_{2 N + 1} = 1 - {\sum }_{m = 0}^{N - 1} {a}_{2 m + 1} \qquad [ Mathematical Formula 44 ]$$

The method of identifying the output characteristic function will be described later.

The identification unit 6613 acquires the output characteristic value for the normalized amplitude r based on the identified output characteristic function and the normalized amplitude r output by the amplitude acquiring unit 6611. The identification unit 6613 outputs a value Au₁ obtained by multiplying the acquired output characteristic value A by first waveform information u₁.

The output characteristic estimator 66I inputs a value, which is obtained by subtracting the regulated output signal y output by the regulator 66I2 from the sum of the value Au₁ output by the identification unit 6613 and second waveform information u₂, as an error ε into the identification unit 6613.

The identification unit 6613 identifies the coefficient a₂ₘ₊₁ of the output characteristic function based on Formula 45 by using the method of least squares. More specifically, the identification unit 6613 determines the coefficient a₂ₘ₊₁ of the output characteristic function such that the sum of squares of a plurality of errors ε acquired for a plurality of different normalized amplitudes r is minimized. For example, the output characteristic function is, as represented in the Formula 38, a polynomial of the square of the normalized amplitude r.

Au₁+u₂=y+ε [Mathematical Formula 45]

Thus, the output characteristic estimator 66I estimates the output characteristic of the first amplifier 31 such that the sum of the value obtained by multiplying the first waveform information by the output characteristic value and the second waveform information is brought closer to the value obtained by dividing the output signal by the first amplification factor. In this example, the output characteristic estimator 66I includes an A/D converter (not illustrated) and estimates the output characteristic by converting an analog signal into a digital signal.

The identification unit 6613 outputs the determined coefficient a₂ₘ₊₁ of the output characteristic function to the characteristic difference compensation unit 14I.

Referring to FIG. 35 again, the characteristic difference compensation unit 14I generates first waveform information and second waveform information based on the normalized amplitude r output by the amplitude acquiring unit 11H and the decomposition phase φ output by the phase difference acquiring unit 12H.

In this example, the generated first waveform information is, as represented in the Formula 35, information indicating a waveform (for example, a cosine wave or a sine wave) in which the amplitude is the amplification factor M and the phase is represented by −φ+θ. Similarly, the generated second waveform information is, as represented in the Formula 36, information indicating a waveform in which the amplitude is the amplification factor M and the phase is represented by φ+θ.

Further, the characteristic difference compensation unit 14I acquires the output characteristic value A based on the normalized amplitude r output by the amplitude acquiring unit 11H and the coefficient a₂ₘ₊₁ of the output characteristic function output by the output characteristic estimator 66I.

The characteristic difference compensation unit 14I corrects the first waveform information by multiplying the generated first waveform information by the value of the inverse characteristic of the output characteristic of the first amplifier 31 (or dividing the first waveform information by the output characteristic value A). In this example, the value of the inverse characteristic of the output characteristic of the first amplifier 31 is a reciprocal of the acquired output characteristic value A. The value of the inverse characteristic of the output characteristic of the first amplifier 31 may be a value other than the reciprocal of the output characteristic value A. The corrected first waveform information is, as represented in the Formula 40, information indicating a waveform in which the amplitude is M′ and the phase is −φ′+θ.

The characteristic difference compensation unit 14I outputs the corrected first waveform information to the first frequency converter 21 and also outputs the generated second waveform information to the second frequency converter 22.

(Operation)

Next, the operation of the amplifying apparatus 1I will be described.

First, when an input signal is input into the amplifying apparatus 1I, the amplitude phase converter 10I acquires the normalized amplitude r based on the input signal. Next, the amplitude phase converter 10I acquires the decomposition phase φ based on the acquired normalized amplitude r.

Then, the amplitude phase converter 10I generates the first waveform information and the second waveform information based on the acquired decomposition phase φ. Further, the amplitude phase converter 10I acquires the output characteristic value A based on the coefficient a₂ₘ₊₁ of the output characteristic function output by the output characteristic estimator 66I and the acquired normalized amplitude r. Then, the amplitude phase converter 10I corrects the generated first waveform information based on the acquired output characteristic value A.

Next, the amplitude phase converter 10I outputs the corrected first waveform information to the first frequency converter 21 and also outputs the generated second waveform information to the second frequency converter 22.

Then, the amplifying apparatus 1I amplifies the input signal by the amplification factor and outputs the amplified signal as an output signal by operating in the same manner as the amplifying apparatus 1.

Further, the output characteristic estimator 66I determines the coefficient a₂ₘ₊₁ of the output characteristic function based on the input signal, the first waveform information, the second waveform information, and the output signal and outputs the determined coefficient a₂ₘ₊₁ to the amplitude phase converter 10I.

For example, the output characteristic estimator 66I may determine and output the coefficient a₂ₘ₊₁ in a predetermined period such as a time when the amplifying apparatus 1I is activated. The output characteristic estimator 66I may also determine and output the coefficient a₂ₘ₊₁ each time a predetermined period passes. The output characteristic estimator 66I may continue to determine and output the coefficient a₂ₘ₊₁ while the amplifying apparatus 1I operates. For example, the amplitude phase converter 10I may hold the coefficient a₂ₘ₊₁ output by the output characteristic estimator 66I, and may acquire the output characteristic value using the held coefficient a₂ₘ₊₁ before the new coefficient a₂ₘ₊₁ is output.

The amplitude phase converter 10I may also generate a table associating the output characteristic value and the normalized amplitude based on the coefficient a₂ₘ₊₁ output by the output characteristic estimator 66I and the output characteristic value, and may acquire the output characteristic value based on the table.

According to the amplifying apparatus 1I in the seventh embodiment, as described above, just like the amplifying apparatus 1H in the sixth embodiment, the waveform information, on which the first decomposed signal decomposed from the input signal is based, is controlled such that the output characteristic of the combiner 50 matches the desired characteristic.

Accordingly, the output characteristic of the combiner 50 can be matched to the desired characteristic. For example, when the real amplitude of the input signal is 0, the amplitude of the output signal from the combiner 50 can be brought closer to 0. Also, the relationship between the real amplitude of the input signal and the amplitude of the output signal from the combiner 50 can be brought closer to a linear relationship. As a result, the output characteristic (amplification characteristic) of the amplifying apparatus 1I can be improved.

Further, according to the amplifying apparatus 1I in the seventh embodiment, the difference of output characteristics of the two amplifiers 31, 32 can be compensated for. As a result, the amplification characteristic can be improved.

The amplifying apparatus 1I according to the seventh embodiment corrects both of the amplitude and the phase of the first waveform information, but may correct only one of the amplitude and the phase.

The amplifying apparatus 1I according to the seventh embodiment may also estimate, instead of the first amplifier 31, an output characteristic of the second amplifier 32 to correct, instead of the first waveform information, the second waveform information based on the estimated output characteristic.

### Modified Example of the Seventh Embodiment

Next, an amplifying apparatus according to the modified example of the seventh embodiment will be described. The amplifying apparatus according to the modified example of the seventh embodiment is different from the amplifying apparatus according to the seventh embodiment in that the decomposition phase is acquired based on a linear function of the normalized amplitude. The following description focuses on such a difference.

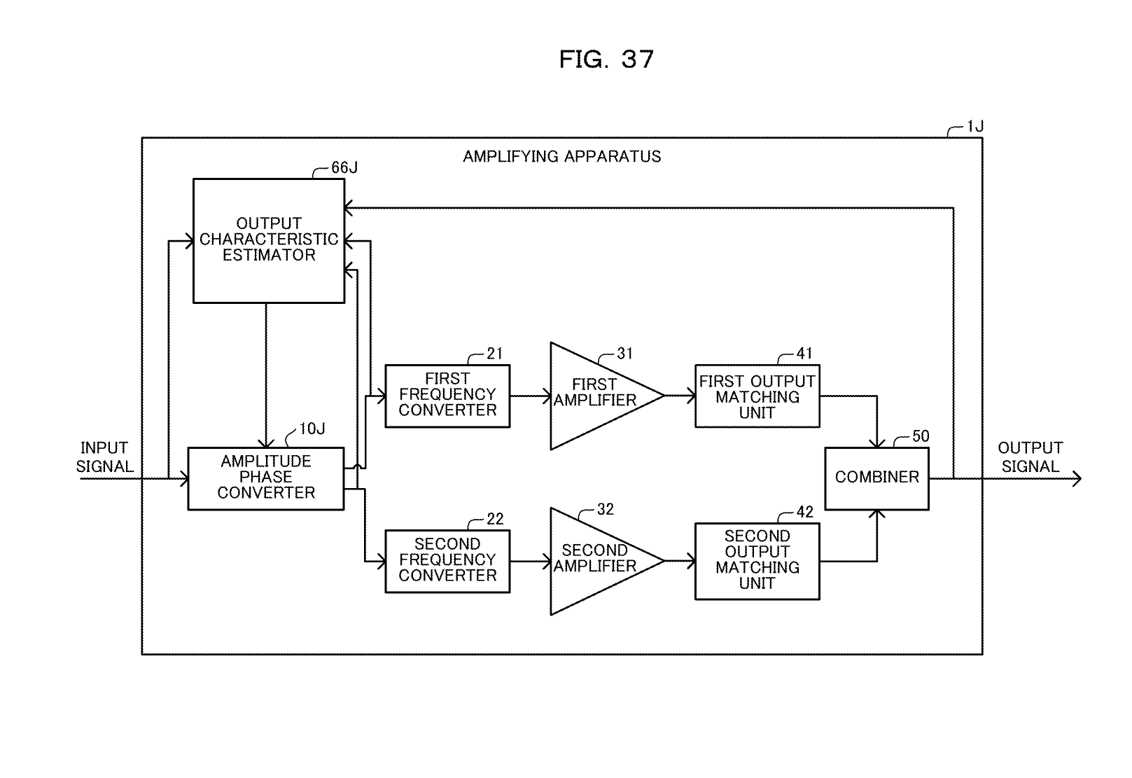

As illustrated in FIG. 37, an amplifying apparatus 1J according to the modified example includes, instead of the amplitude phase converter 10I of the amplifying apparatus 1I in FIG. 34, an amplitude phase converter 10J. Further, the amplifying apparatus 1J includes, instead of the output characteristic estimator 66I of the amplifying apparatus 1I in FIG. 34, an output characteristic estimator 66J.

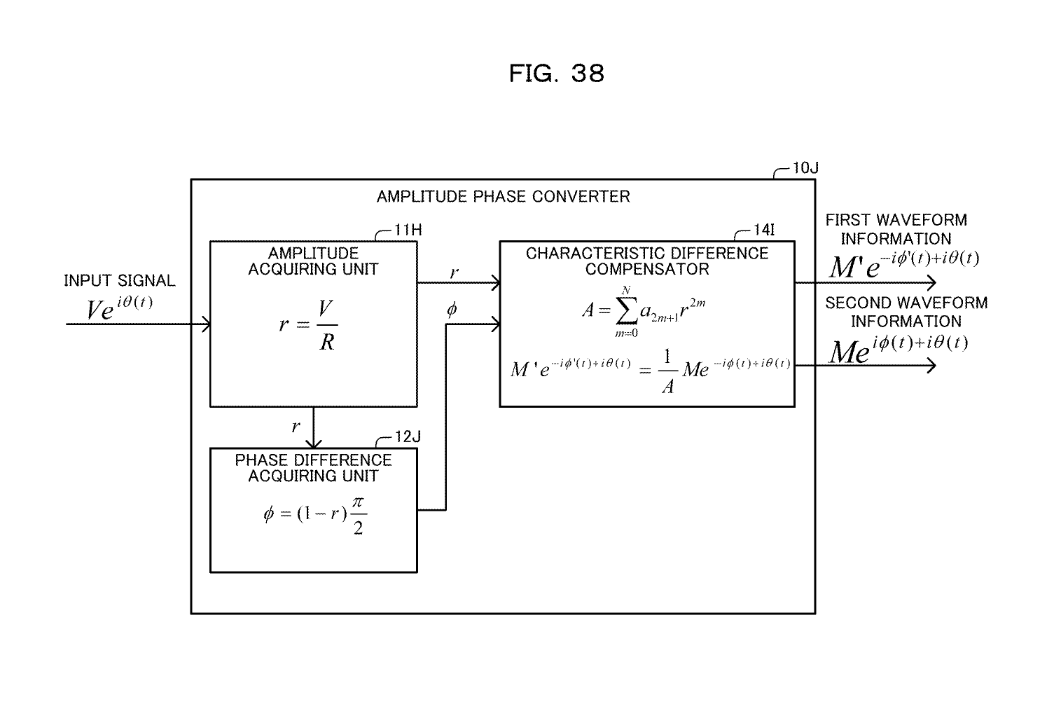

As illustrated in FIG. 38, the amplitude phase converter 10J according to the modified example includes, instead of the phase difference acquiring unit 12H of the amplitude phase converter 10I in FIG. 35, a phase difference acquiring unit 12J.

The phase difference acquiring unit 12J acquires the decomposition phase φ based on the normalized amplitude r output by the amplitude acquiring unit 11H.

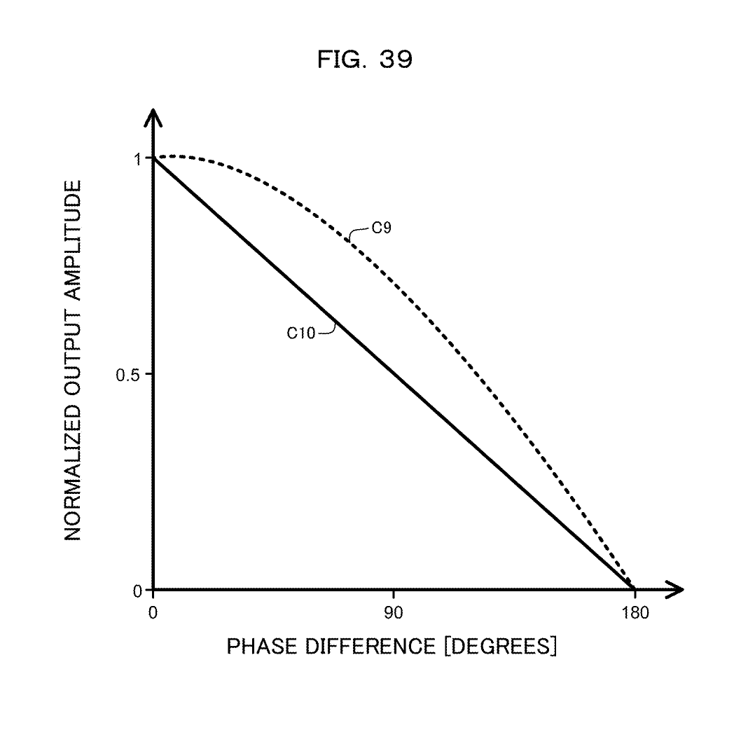

For example, as illustrated in FIG. 39, the relationship between the normalized output amplitude and the phase difference is represented by a curve C9 when a Wilkinson combiner is used as the combiner. On the other hand, the inventors found that the relationship between the normalized output amplitude and the phase difference may be represented by a straight line C10 when a Chireix combiner is used as the combiner.

Thus, in this example, the phase difference acquiring unit 12J determines, as represented in Formula 46, the decomposition phase φ based on a linear function of the normalized amplitude r. The phase difference acquiring unit 12J outputs the acquired decomposition phase φ to the characteristic difference compensation unit 14I.

$$φ = ( 1 - r ) \frac{π}{2} \qquad [ Mathematical Formula 46 ]$$

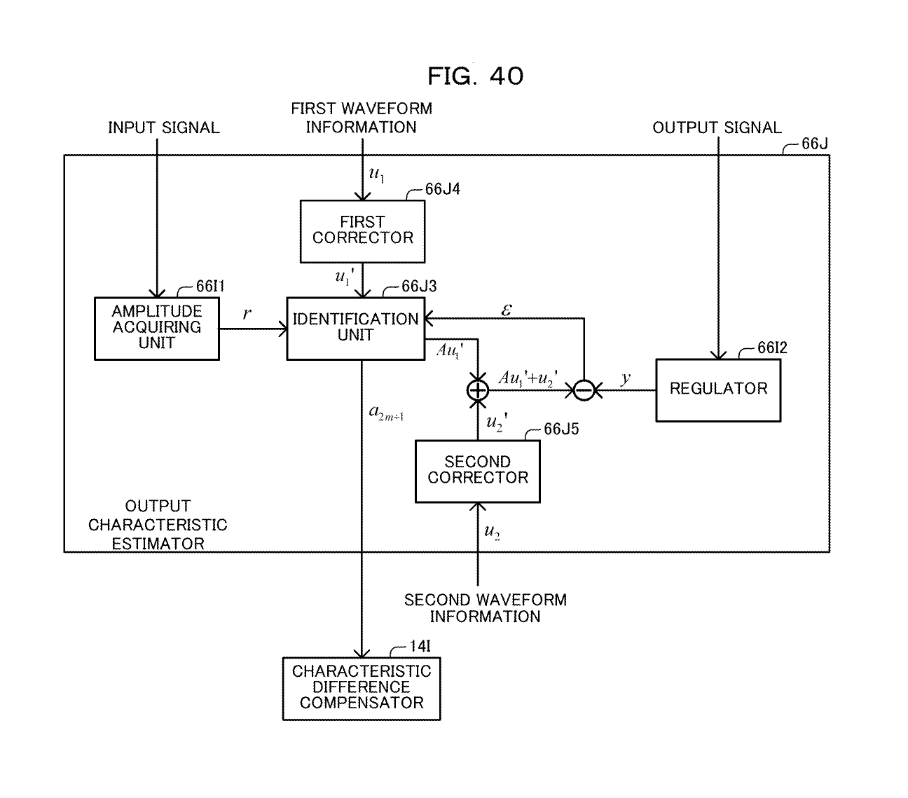

As illustrated in FIG. 40, the output characteristic estimator 66J according to the modified example includes, instead of the identification unit 6613 of the output characteristic estimator 66I in FIG. 36, an identification unit 66J3. Further, the output characteristic estimator 66J according to the modified example additionally includes a first corrector 66J4 and a second corrector 66J5 when compared with the output characteristic estimator 66I in FIG. 36.

The first corrector 66J4 corrects the first waveform information u₁ based on Formula 47 and Formula 48 and outputs first waveform information (first corrected waveform information) u₁′ after the correction to the identification unit 66J3.

$$\begin{matrix}{u}_{1}^{′} = {u}_{1} {e}^{iΔ φ} & [ Mathematical Formula 47 ] \\ Δ φ = {cos}^{- 1} ( r ) - ( 1 - r ) \frac{π}{2} & [ Mathematical Formula 48 ]\end{matrix}$$

The second corrector 66J5 corrects the second waveform information u₂ based on Formula 48 and Formula 49 and outputs second waveform information (second corrected waveform information) u₂′ after the correction to the identification unit 66J3.

u₂′=u₂e^{-iΔφ} [Mathematical Formula 49]

In this manner, the first corrector 66J4 and the second corrector 66J5 correct the first waveform information u₁ and the second waveform information u₂ respectively such that the first waveform information u₁ and the second waveform information u₂ have the value, which is obtained by doubling the arc cosine of the normalized amplitude r, as the phase difference thereof.

The identification unit 66J3 acquires the output characteristic value for the normalized amplitude r based on the identified output characteristic function and the normalized amplitude r output by the amplitude acquiring unit 6611. The identification unit 66J3 outputs a value Au₁′ obtained by multiplying the acquired output characteristic value A by the first corrected waveform information u₁′.

The output characteristic estimator 66J inputs a value, which is obtained by subtracting the regulated output signal y output by the regulator 66I2 from the sum of the value Au₁′ output by the identification unit 66J3 and the second corrected waveform information u₂′, as the error ε into the identification unit 66J3.

The identification unit 66J3 identifies the output characteristic function as a function representing the output characteristic of the first amplifier 31. The identification unit 66J3 identifies the coefficient a₂ₘ₊₁ of the output characteristic function based on Formula 50 by using the method of least squares. More specifically, the identification unit 66J3 determines the coefficient a₂ₘ₊₁ of the output characteristic function such that the sum of squares of a plurality of errors ε acquired for a plurality of different normalized amplitudes r is minimized. For example, the output characteristic function is, as represented in the Formula 38, a polynomial of the square of the normalized amplitude r.

Au₁′+u₂′=y+ε [Mathematical Formula 50]

Thus, the output characteristic estimator 66J estimates the output characteristic of the first amplifier 31 such that the sum of the value obtained by multiplying the first corrected waveform information by the output characteristic value and the second corrected waveform information is brought closer to the value obtained by dividing the output signal by the first amplification factor. In this example, the output characteristic estimator 66J includes an A/D converter (not illustrated) and estimates the output characteristic by converting an analog signal into a digital signal.

The identification unit 66J3 outputs the determined coefficient a₂ₘ₊₁ of the output characteristic function to the characteristic difference compensation unit 14I.

The amplifying apparatus 1J according to the modified example acquires, as described above, in contrast to the amplifying apparatus 1I according to the seventh embodiment, the decomposition phase based on a linear function of the normalized amplitude.

Accordingly, the amplification characteristic can be improved more than when a value, which is obtained by doubling the arc cosine of the normalized amplitude, is determined as the decomposition phase.

The amplifying apparatus 1J according to the modified example may use, instead of the output characteristic estimator 66J, the output characteristic estimator 66I according to the seventh embodiment.

When the normalized amplitude is 0, the amplifying apparatus 1J according to the modified example may use a function having a value larger than 180 degrees as a linear function.

Accordingly, the amplification characteristic can be improved more than when a value equal to or smaller than 180 degrees is determined as the phase difference between the two signals.

For example, the phase difference acquiring unit 12J determines, as represented in Formula 51, the decomposition phase φ based on a linear function of the normalized amplitude r. α is a value larger than 0 and smaller than π.

$$φ = ( 1 - r ) ( \frac{π}{2} + \frac{α}{2} ) \qquad [ Mathematical Formula 51 ]$$

In this case, the first corrector 66J4 and the second corrector 66J5 may use Formula 52 instead of the Formula 48.

$$Δ φ = {cos}^{- 1} ( r ) - ( 1 - r ) ( \frac{π}{2} + \frac{α}{2} ) \qquad [ Mathematical Formula 52 ]$$

### Eighth Embodiment

Next, an amplifying apparatus according to the eighth embodiment will be described. The amplifying apparatus according to the eighth embodiment is different from the amplifying apparatus according to the sixth embodiment in that the output characteristic value is acquired based on input signals at a plurality of different points in time. The following description focuses on such a difference.

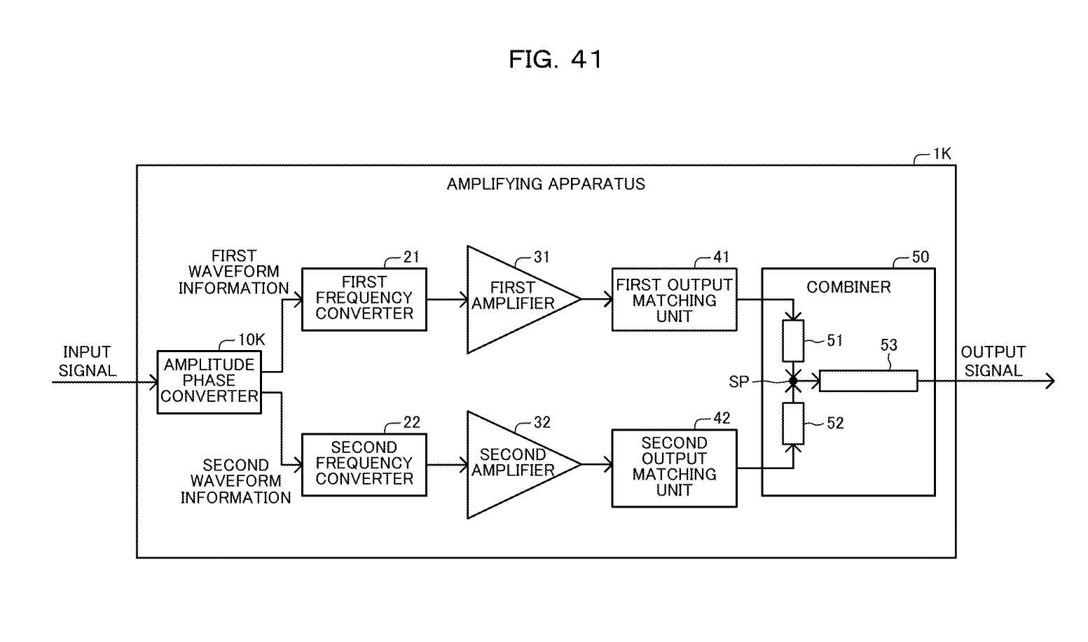

As illustrated in FIG. 41, an amplifying apparatus 1K according to the eighth embodiment includes, instead of the amplitude phase converter 10H of the amplifying apparatus 1H in FIG. 30, an amplitude phase converter 10K.

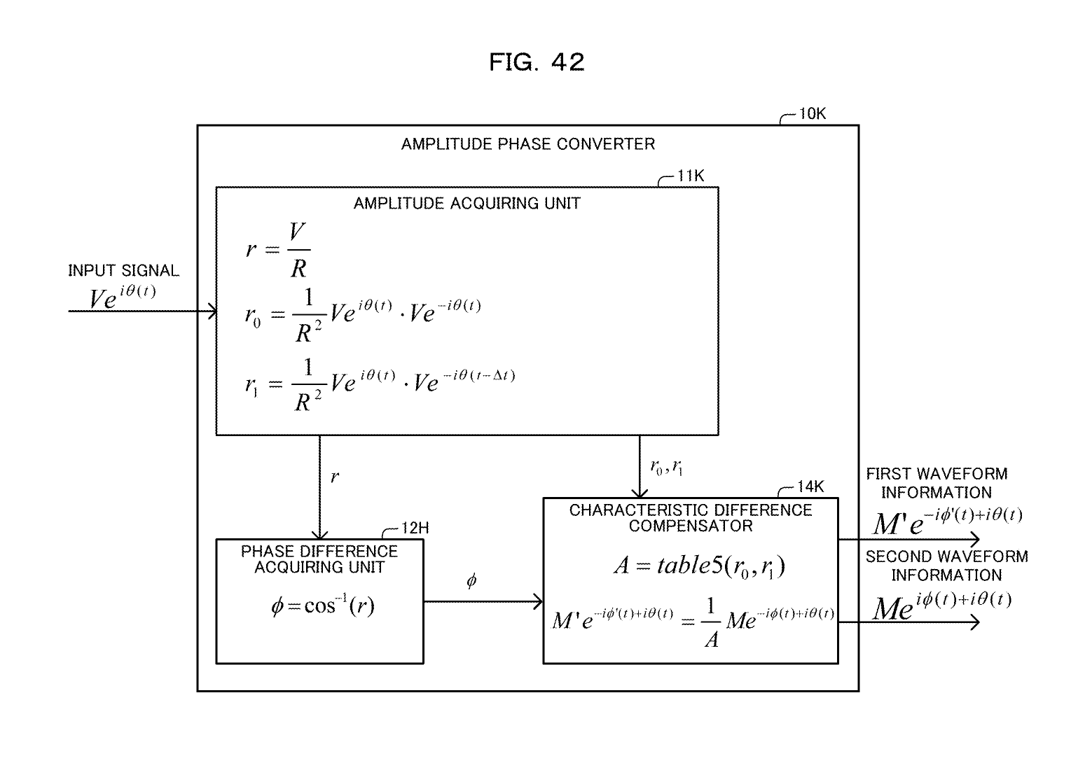

As illustrated in FIG. 42, the amplitude phase converter 10K according to the eighth embodiment includes, instead of the amplitude acquiring unit 11H and the characteristic difference compensation unit 14H of the amplitude phase converter 10H in FIG. 31, an amplitude acquiring unit 11K and a characteristic difference compensation unit 14K.

The amplitude acquiring unit 11K acquires, based on the input signal, the amplitude (normalized amplitude) r of the input signal normalized so that the maximum value thereof is 1 based on the Formula 2. The amplitude acquiring unit 11K outputs the acquired normalized amplitude r without a correction to the phase difference acquiring unit 12H.

The amplitude acquiring unit 11K acquires a first characteristic quantity and a second characteristic quantity based on an input signal s(t) at a first point in time (time t in this example) and an input signal s(t−Δt) at a second point in time (in this example, time t−Δt, a predetermined time interval Δt prior to time t).

A first characteristic quantity r₀ is, as represented in Formula 53, the product of the input signal s(t) at the first point in time t and a conjugate complex number s*(t) of the input signal at the first point in time t. The first characteristic quantity r₀ matches the square of the normalized amplitude r.

$${r}_{0} = \frac{1}{{R}^{2}} V {e}^{i φ ( t )} \cdot V {e}^{- i θ ( t )} \qquad [ Mathematical Formula 53 ]$$

A second characteristic quantity r₁ is, as represented in Formula 54, the product of the input signal s(t) at the first point in time t and a conjugate complex number s*(t−Δt) of the input signal at the second point in time t−Δt.

For example, the amplitude acquiring unit 11K may include a delay unit that delays the input signal s(t) by the time interval Δt so that the output from the delay unit is received as an input signal at the second point in time t−Δt. In this case, the delay unit may be realized by a holding unit that holds the input signal s(t).

$${r}_{1} = \frac{1}{{R}^{2}} V {e}^{i φ ( t )} \cdot V {e}^{- i θ ( t - Δ t )} \qquad [ Mathematical Formula 54 ]$$

The amplitude acquiring unit 11K outputs the acquired first characteristic quantity r₀ and the acquired second characteristic quantity r₁ to the characteristic difference compensation unit 14K.

The characteristic difference compensation unit 14K generates first waveform information and second waveform information based on the decomposition phase φ output by the phase difference acquiring unit 12H.

In this example, the generated first waveform information is, as represented in the Formula 35, information indicating a waveform (for example, a cosine wave or a sine wave) in which the amplitude is the amplification factor M and the phase is represented by −φ+θ. Similarly, the generated second waveform information is, as represented in the Formula 36, information indicating a waveform in which the amplitude is the amplification factor M and the phase is represented by φ+θ.

The characteristic difference compensation unit 14K holds a fifth table associating the first characteristic quantity, the second characteristic quantity, and the output characteristic value of the first amplifier 31 in advance (for example, stored in a memory). The output characteristic value is a value, which is obtained by dividing a value obtained by dividing the output of the first amplifier 31 by the input of the first amplifier 31 by the first amplification factor, for each combination of the first characteristic quantity and the second characteristic quantity.

In this example, the output characteristic value is a value obtained by assuming that the output of the first amplifier 31 does not affect the characteristics of the second amplifier 32 due to the combiner 50 and the output of the second amplifier 32 affects the characteristics of the first amplifier 31 due to the combiner 50. In this example, therefore, the output characteristic value can also be interpreted as a value in a case where the second amplifier 32 is used as a reference. The output characteristic value is, for example, a complex number. The fifth table represents the output characteristics of the first amplifier 31.

The fifth table set such that the output characteristic of the combiner 50 matches a desired characteristic. The desired characteristic includes, for example, a first characteristic, a second characteristic, or both. The first characteristic is a characteristic in which the amplitude of an output signal from the combiner 50 is 0 when the real amplitude of an input signal is 0. The second characteristic is a characteristic in which the relationship between the real amplitude of an input signal and the amplitude of an output signal from the combiner 50 is a linear relationship.

For example, a relationship between the fifth table and the output characteristic of the combiner 50 may be determined by an experiment or a simulation to set the fifth table based on the relationship. For example, the fifth table may be set such that a difference between output characteristics of the two amplifiers 31, 32 is compensated for.

As an example, the fifth table may be set such that the sum of a value obtained by multiplying the first waveform information by the output characteristic value and the second waveform information is matched to a value obtained by dividing the output signal from the combiner 50 by the first amplification factor. As another example, the fifth table may be set such that the magnitude of a difference between the sum of a value obtained by multiplying the first waveform information by the output characteristic value and the second waveform information and a value obtained by dividing the output signal from the combiner 50 by the first amplification factor is minimized (or is made equal to or smaller than a threshold).

The characteristic difference compensation unit 14K acquires, as represented in Formula 55, the output characteristic value A associated with the first characteristic quantity r₀ and the second characteristic quantity r₁ output by the amplitude acquiring unit 11K in the held fifth table.

A=table5(r₀,r₁) [Mathematical Formula 55]

The characteristic difference compensation unit 14K may hold, instead of the fifth table, parameters to identify an output characteristic function as a function defining the relationship among the output characteristic value, the first characteristic quantity and the second characteristic quantity to acquire the output characteristic value A based on the output characteristic function. For example, the output characteristic function is, as represented in Formula 56, the sum of a first polynomial of the first characteristic quantity and a second polynomial of the second characteristic quantity.

In the Formula 56, each of N and M represent natural numbers. In this case, the parameters are the coefficient a₂ₘ₊₁ and the coefficient b₂ⱼ₊₁. m represents an integer from 0 to N. j represents an integer from 1 to M.

$$A = {\sum }_{m = 0}^{N} {a}_{2 m + 1} {r}_{0}^{m} + {\sum }_{j = 1}^{M} {b}_{2 j + 1} {r}_{1}^{j} \qquad [ Mathematical Formula 56 ]$$

The characteristic difference compensation unit 14K corrects the first waveform information by multiplying the generated first waveform information by the value of the inverse characteristic of the output characteristic of the first amplifier 31 (or dividing the first waveform information by the output characteristic value A). In this example, the value of the inverse characteristic of the output characteristic of the first amplifier 31 is a reciprocal of the acquired output characteristic value A. The value of the inverse characteristic of the output characteristic of the first amplifier 31 may be a value other than the reciprocal of the output characteristic value A. The corrected first waveform information is, as represented in the Formula 40, information indicating a waveform in which the amplitude is M′ and the phase is −φ′+θ.

The characteristic difference compensation unit 14K outputs the corrected first waveform information to the first frequency converter 21 and also outputs the generated second waveform information to the second frequency converter 22.

(Operation)

Next, the operation of the amplifying apparatus 1K will be described.

First, when an input signal is input into the amplifying apparatus 1K, the amplitude phase converter 10K acquires the normalized amplitude r, the first characteristic quantity r₀, and the second characteristic quantity r₁ based on the input signal. Next, the amplitude phase converter 10K acquires the decomposition phase φ based on the acquired normalized amplitude r.

Then, the amplitude phase converter 10K generates the first waveform information and the second waveform information based on the acquired decomposition phase φ. Further, the amplitude phase converter 10K acquires the output characteristic value A based on the held fifth table and the acquired first characteristic quantity r₀, and the acquired second characteristic quantity r₁. Then, the amplitude phase converter 10K corrects the generated first waveform information based on the acquired output characteristic value A.

Next, the amplitude phase converter 10K outputs the corrected first waveform information to the first frequency converter 21 and also outputs the generated second waveform information to the second frequency converter 22.

Then, the amplifying apparatus 1K amplifies the input signal by the amplification factor and outputs the amplified signal as an output signal by operating in the same manner as the amplifying apparatus 1H.

According to the amplifying apparatus 1K in the eighth embodiment, as described above, the waveform information, on which the first decomposed signal decomposed from the input signal is based, is controlled such that the output characteristic of the combiner 50 matches the desired characteristic.

Accordingly, the output characteristic of the combiner 50 can be matched to the desired characteristic. For example, when the real amplitude of the input signal is 0, the amplitude of the output signal from the combiner 50 can be brought closer to 0. Also, the relationship between the real amplitude of the input signal and the amplitude of the output signal from the combiner 50 can be brought closer to a linear relationship. As a result, the output characteristic (amplification characteristic) of the amplifying apparatus 1K can be improved.

Further, according to the amplifying apparatus 1K in the eighth embodiment, the difference of output characteristics of the two amplifiers 31, 32 can be compensated for. As a result, the amplification characteristic can be improved.

In addition, the amplifying apparatus 1K according to the eighth embodiment acquires the output characteristic value based on input signals at a plurality of different points in time.

The output characteristic of the first amplifier 31 may change in accordance with a change over time of the input signal. According to the above configuration, therefore, even if the output characteristic of the first amplifier 31 changes in accordance with a change over time of the input signal, the amplification characteristic can be improved.

The amplifying apparatus 1K according to the eighth embodiment corrects both of the amplitude and the phase of the first waveform information, but may correct only one of the amplitude and the phase.

The amplifying apparatus 1K according to the eighth embodiment may have a table, which is associating the first characteristic quantity, the second characteristic quantity, and the output characteristic value of the second amplifier 32, as the fifth table to correct the second waveform information instead of the first waveform information.

The amplifying apparatus 1K according to the eighth embodiment acquires the output characteristic value based on input signals at two different points in time, but may acquire the output characteristic value based on input signals at three or more different points in time.

### Ninth Embodiment

Next, am amplifying apparatus according to the ninth embodiment will be described. The amplifying apparatus according to the ninth embodiment is different from the amplifying apparatus according to the eighth embodiment in that the output characteristic of the first amplifier 31 is estimated and the first waveform information is corrected based on the estimated output characteristic. The following description focuses on such a difference.

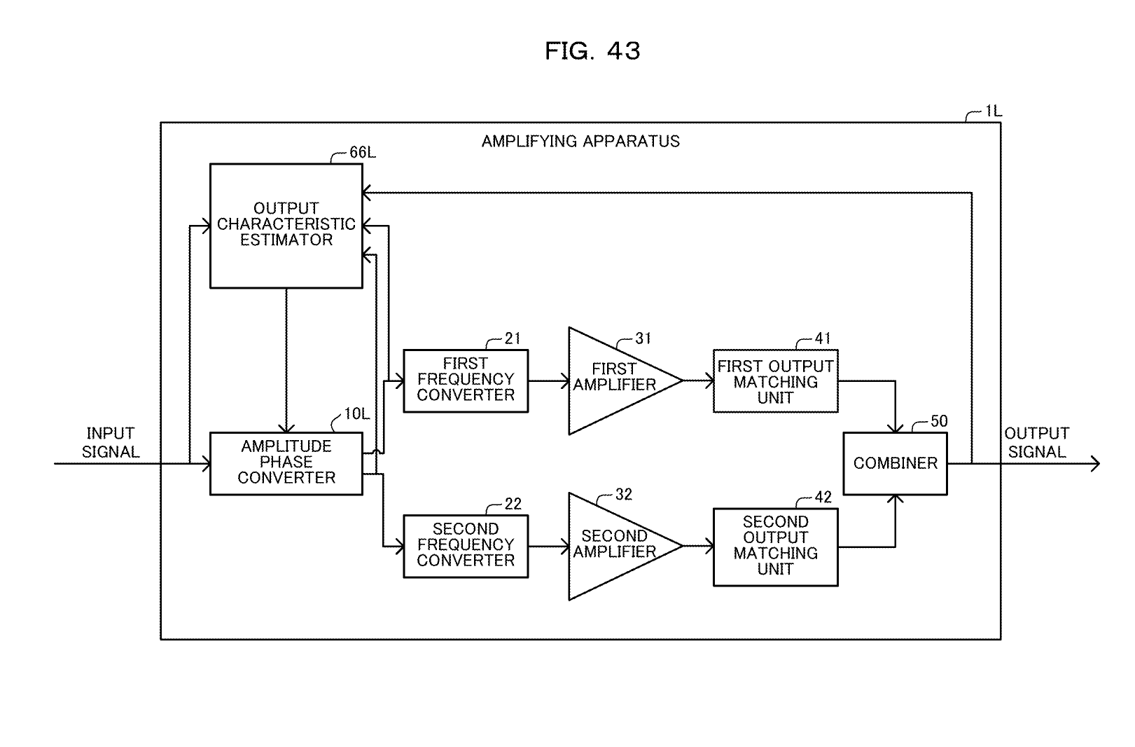

As illustrated in FIG. 43, an amplifying apparatus 1L according to the ninth embodiment includes, instead of the amplitude phase converter 10K of the amplifying apparatus 1K in FIG. 41, an amplitude phase converter 10L. Further, the amplifying apparatus 1L additionally includes an output characteristic estimator 66L when compared with the amplifying apparatus 1K in FIG. 41. The output characteristic estimator 66L is an example of the controller.

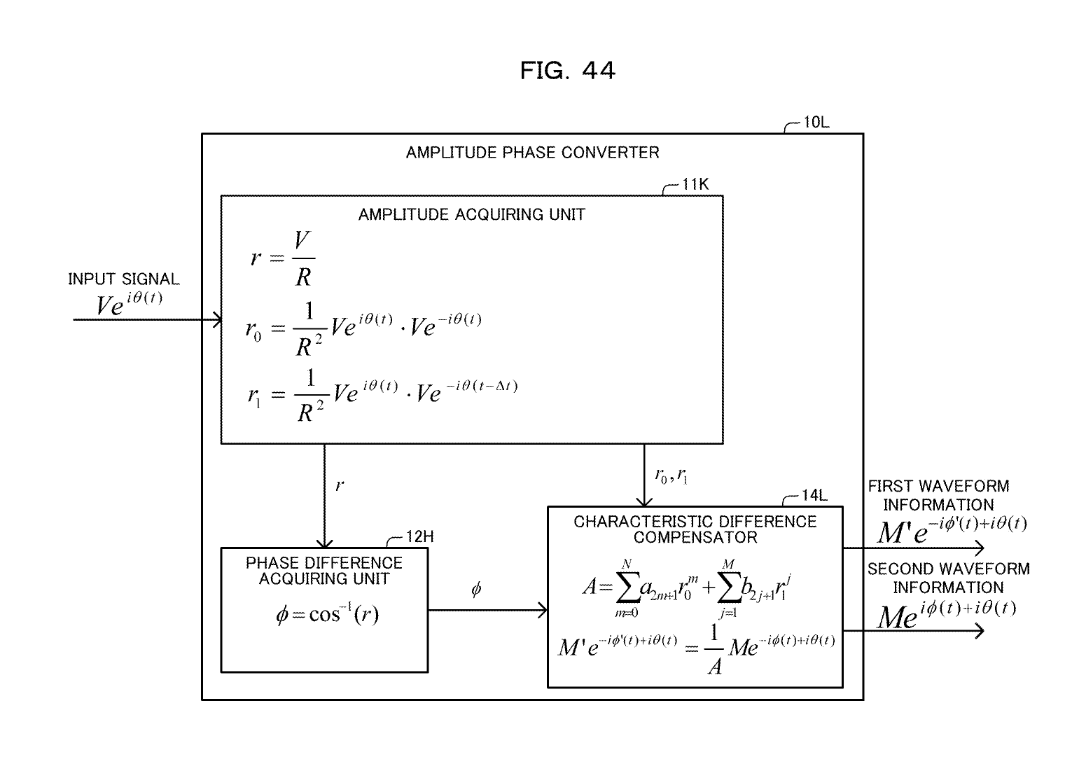

As illustrated in FIG. 44, the amplitude phase converter 10L includes, instead of the characteristic difference compensation unit 14K of the amplitude phase converter 10K in FIG. 42, a characteristic difference compensation unit 14L.

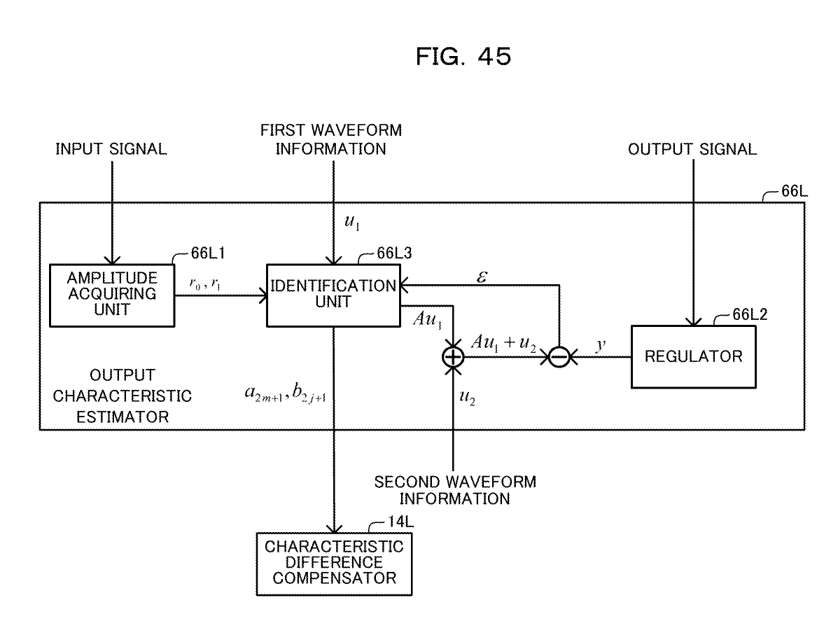

The output characteristic estimator 66L includes, as illustrated in FIG. 45, an amplitude acquiring unit 66L1, a regulator 66L2, and an identification unit 66L3.

The amplitude acquiring unit 66L1 acquires the first characteristic quantity and the second characteristic quantity based on the input signal s(t) at the first point in time and the input signal s(t−Δt) at the second point in time. In this example, the first point in time is time t and the second point in time is time t−Δt, which is prior to time t by a predetermined time interval Δt.

The first characteristic quantity r₀ is, as represented in the Formula 53, the product of the input signal s(t) at the first point in time t and the conjugate complex number s*(t) of the input signal at the first point in time t.

The second characteristic quantity r₁ is, as represented in the Formula 54, the product of the input signal s(t) at the first point in time t and the conjugate complex number s*(t−Δt) of the input signal at the second point in time t−Δt.

For example, the amplitude acquiring unit 66L1 may include a delay unit that delays the input signal s(t) by the time interval Δt so that the output from the delay unit is received as an input signal at the second point in time t−Δt. In this case, the delay unit may be realized by a holding unit that holds the input signal s(t).

The amplitude acquiring unit 66L1 outputs the acquired first characteristic quantity r₀ and the acquired second characteristic quantity r₁ to the identification unit 66L3.

The regulator 66L2 regulates the amplitude and the phase of the output signal. In this example, the regulator 66L2 outputs a value, which is obtained by dividing the output signal by the first amplification factor, as a regulated output signal y.

The identification unit 66L3 identifies the output characteristic function as a function that represents the output characteristic of the first amplifier 31. In this example, the output characteristic function is, as represented in the Formula 56, the sum of the first polynomial of the first characteristic quantity and the second polynomial of the second characteristic quantity.

The method of identifying the output characteristic function will be described later.

The identification unit 66L3 acquires the output characteristic value for a combination of the first characteristic quantity r₀ and the second characteristic quantity r₁ based on the identified output characteristic function and the first characteristic quantity r₀ and the second characteristic quantity r₁ output by the amplitude acquiring unit 66L1. The identification unit 66L3 outputs the value Au₁ obtained by multiplying the acquired output characteristic value A by first waveform information u₁.

The output characteristic estimator 66L inputs a value, which is obtained by subtracting the regulated output signal y output by the regulator 66L2 from the sum of the value Au₁ output by the identification unit 66L3 and the second waveform information u₂, as the error ε into the identification unit 66L3.

The identification unit 66L3 identifies the coefficient a₂ₘ₊₁ and the coefficient b₂ⱼ₊₁ of the output characteristic function based on the Formula 45 by using the method of least squares. More specifically, the identification unit 66L3 determines the coefficient a₂ₘ₊₁ and the coefficient b₂ⱼ₊₁ of the output characteristic function such that the sum of squares of a plurality of errors ε acquired for input signals at a plurality of different points in time is minimized.

Thus, the output characteristic estimator 66L estimates the output characteristic of the first amplifier 31 such that the sum of the value obtained by multiplying the first waveform information by the output characteristic value and the second waveform information is brought closer to the value obtained by dividing the output signal by the first amplification factor. In this example, the output characteristic estimator 66L includes an A/D converter (not illustrated) and estimates the output characteristic by converting an analog signal into a digital signal.

The identification unit 66L3 outputs the determined coefficient a₂ₘ₊₁ and the determined coefficient b₂ⱼ₊₁ of the output characteristic function to the characteristic difference compensation unit 14L.

Referring to FIG. 44 again, the characteristic difference compensation unit 14L generates first waveform information and second waveform information based on the decomposition phase φ output by the phase difference acquiring unit 12H.

In this example, the generated first waveform information is, as represented in the Formula 35, information indicating a waveform in which the amplitude is the amplification factor M and the phase is represented by −φ+θ. Similarly, the generated second waveform information is, as represented in the Formula 36, information indicating a waveform in which the amplitude is the amplification factor M and the phase is represented by φ+θ.

Further, the characteristic difference compensation unit 14L acquires the output characteristic value A based on the first characteristic quantity r₀ and the second characteristic quantity r₁ output by the amplitude acquiring unit 11K and the coefficient a₂ₘ₊₁ and the coefficient b₂ⱼ₊₁ of the output characteristic function output by the output characteristic estimator 66L.

The characteristic difference compensation unit 14L corrects the first waveform information by multiplying the generated first waveform information by the value of the inverse characteristic of the output characteristic of the first amplifier 31 (or dividing the first waveform information by the output characteristic value A). In this example, the value of the inverse characteristic of the output characteristic of the first amplifier 31 is a reciprocal of the acquired output characteristic value A. The value of the inverse characteristic of the output characteristic of the first amplifier 31 may be a value other than the reciprocal of the output characteristic value A. The corrected first waveform information is, as represented in the Formula 40, information indicating a waveform in which the amplitude is M′ and the phase is −φ′+θ.

The characteristic difference compensation unit 14L outputs the corrected first waveform information to the first frequency converter 21 and also outputs the generated second waveform information to the second frequency converter 22.

(Operation)

Next, the operation of the amplifying apparatus 1L will be described.

First, when an input signal is input into the amplifying apparatus 1L, the amplitude phase converter 10L acquires the normalized amplitude r, the first characteristic quantity r₀, and the second characteristic quantity r₁ based on the input signal. Next, the amplitude phase converter 10L acquires the decomposition phase φ based on the acquired normalized amplitude r.

Then, the amplitude phase converter 10L generates the first waveform information and the second waveform information based on the acquired decomposition phase φ. Further, the amplitude phase converter 10L acquires the output characteristic value A based on the coefficient a₂ₘ₊₁ and the coefficient b₂ⱼ₊₁ of the output characteristic function output by the output characteristic estimator 66L and the acquired first characteristic quantity r₀ and the acquired second characteristic quantity r₁. Then, the amplitude phase converter 10L corrects the generated first waveform information based on the acquired output characteristic value A.

Next, the amplitude phase converter 10L outputs the corrected first waveform information to the first frequency converter 21 and also outputs the generated second waveform information to the second frequency converter 22.

Then, the amplifying apparatus 1L amplifies the input signal by the amplification factor and outputs the amplified signal as an output signal by operating in the same manner as the amplifying apparatus 1K.

Further, the output characteristic estimator 66L determines the coefficient a₂ₘ₊₁ and the coefficient b₂ⱼ₊₁ of the output characteristic function based on the input signal, the first waveform information, the second waveform information, and the output signal and outputs the determined coefficient a₂ₘ₊₁ and the determined coefficient b₂ⱼ₊₁ to the amplitude phase converter 10L.

For example, the output characteristic estimator 66L may determine and output the coefficient a₂ₘ₊₁ and the coefficient b₂ⱼ₊₁ in a predetermined period such as a time when the amplifying apparatus 1L is activated. The output characteristic estimator 66L may also determine and output the coefficient a₂ₘ₊₁ and the coefficient b₂ⱼ₊₁ each time a predetermined period passes. The output characteristic estimator 66L may continue to determine and output the coefficient a₂ₘ₊₁ and the coefficient b₂ⱼ₊₁ while the amplifying apparatus 1L operates. For example, the amplitude phase converter 10L may hold the coefficient a₂ₘ₊₁ and the coefficient b₂ⱼ₊₁ output by the output characteristic estimator 66L to use the coefficient a₂ₘ₊₁ and the coefficient b₂ⱼ₊₁ held before the new coefficient a₂ₘ₊₁ and coefficient b₂ⱼ₊₁ are output.

The amplitude phase converter 10L may also generate a table associating the output characteristic value and the combination of the first characteristic quantity and the second characteristic quantity based on the coefficient a₂ₘ₊₁ and the coefficient b₂ⱼ₊₁ output by the output characteristic estimator 66L and the output characteristic function. In this case, the amplitude phase converter 10L may acquire the output characteristic value based on the table.

According to the amplifying apparatus 1L in the ninth embodiment, as described above, just like the amplifying apparatus 1K in the eighth embodiment, the waveform information, on which the first decomposed signal decomposed from the input signal is based, is controlled such that the output characteristic of the combiner 50 matches the desired characteristic.

Accordingly, the output characteristic of the combiner 50 can be matched to the desired characteristic. For example, when the real amplitude of the input signal is 0, the amplitude of the output signal from the combiner 50 can be brought closer to 0. Also, the relationship between the real amplitude of the input signal and the amplitude of the output signal from the combiner 50 can be brought closer to a linear relationship. As a result, the output characteristic (amplification characteristic) of the amplifying apparatus 1L can be improved.

Further, according to the amplifying apparatus 1L in the ninth embodiment, the difference of output characteristics of the two amplifiers 31, 32 can be compensated for. As a result, the amplification characteristic can be improved.

The amplifying apparatus 1L according to the ninth embodiment corrects both of the amplitude and the phase of the first waveform information, but may correct only one of the amplitude and the phase.

The amplifying apparatus 1L according to the ninth embodiment may also estimate, instead of the first amplifier 31, the output characteristic of the second amplifier 32 to correct, instead of the first waveform information, the second waveform information based on the estimated output characteristic.

### Modified Example of the Ninth Embodiment

Next, an amplifying apparatus according to the modified example of the ninth embodiment will be described. The amplifying apparatus according to the modified example of the ninth embodiment is different from the amplifying apparatus according to the ninth embodiment in that the decomposition phase is acquired based on a linear function of the normalized amplitude. The following description focuses on such a difference.

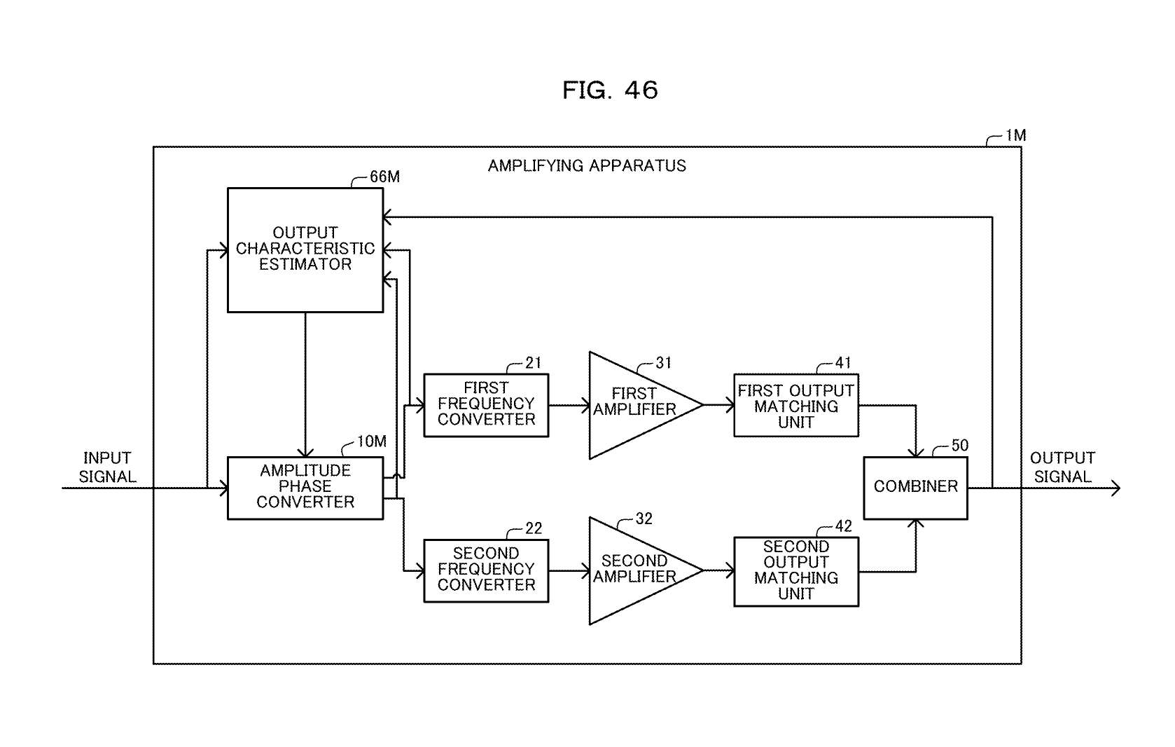

As illustrated in FIG. 46, an amplifying apparatus 1M according to the modified example includes, instead of the amplitude phase converter 10L of the amplifying apparatus 1L in FIG. 43, an amplitude phase converter 10M. Further, the amplifying apparatus 1M includes, instead of the output characteristic estimator 66L of the amplifying apparatus 1L in FIG. 43, an output characteristic estimator 66M.

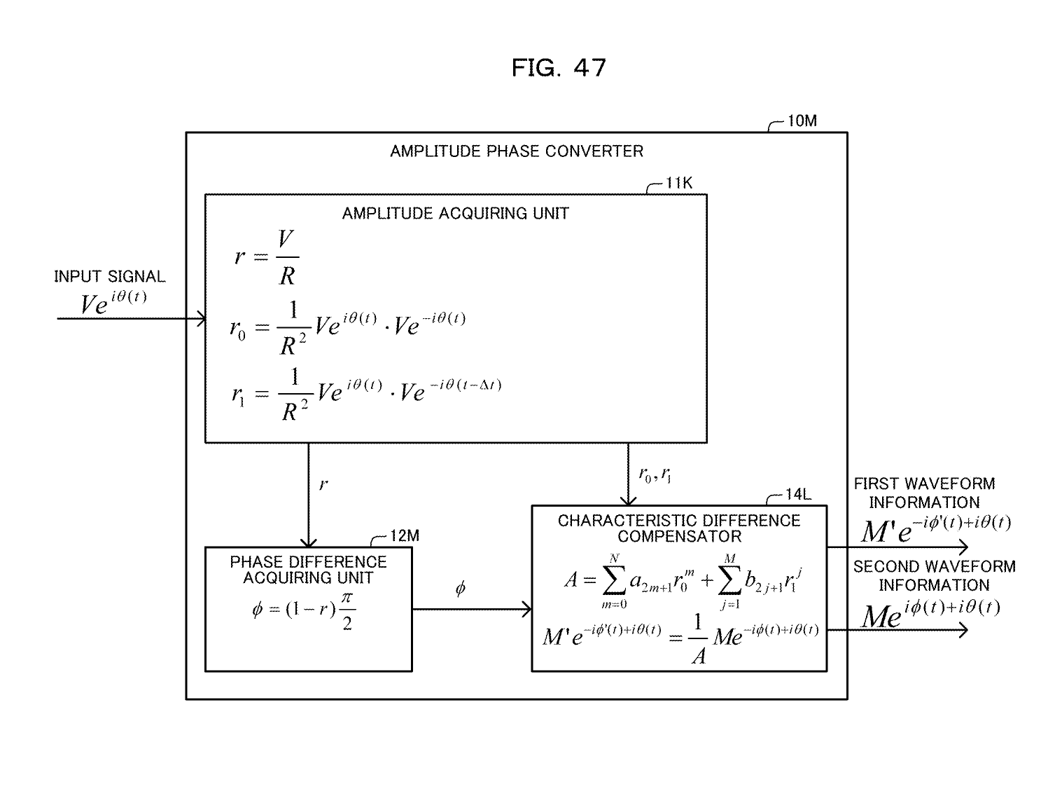

As illustrated in FIG. 47, the amplitude phase converter 10M according to the modified example includes, instead of the phase difference acquiring unit 12H of the amplitude phase converter 10L in FIG. 44, a phase difference acquiring unit 12M.

The phase difference acquiring unit 12M acquires the decomposition phase φ based on the normalized amplitude r output by the amplitude acquiring unit 11K.

For example, as illustrated in FIG. 39, the relationship between the normalized output amplitude and the phase difference is represented by the curve C9 when a Wilkinson combiner is used as the combiner. On the other hand, the inventors found that the relationship between the normalized output amplitude and the phase difference may be represented by the straight line C10 when a Chireix combiner is used as the combiner.

Thus, in this example, the phase difference acquiring unit 12M determines, as represented in the Formula 46, the decomposition phase φ based on a linear function of the normalized amplitude r. The phase difference acquiring unit 12M outputs the acquired decomposition phase φ to the characteristic difference compensation unit 14L.

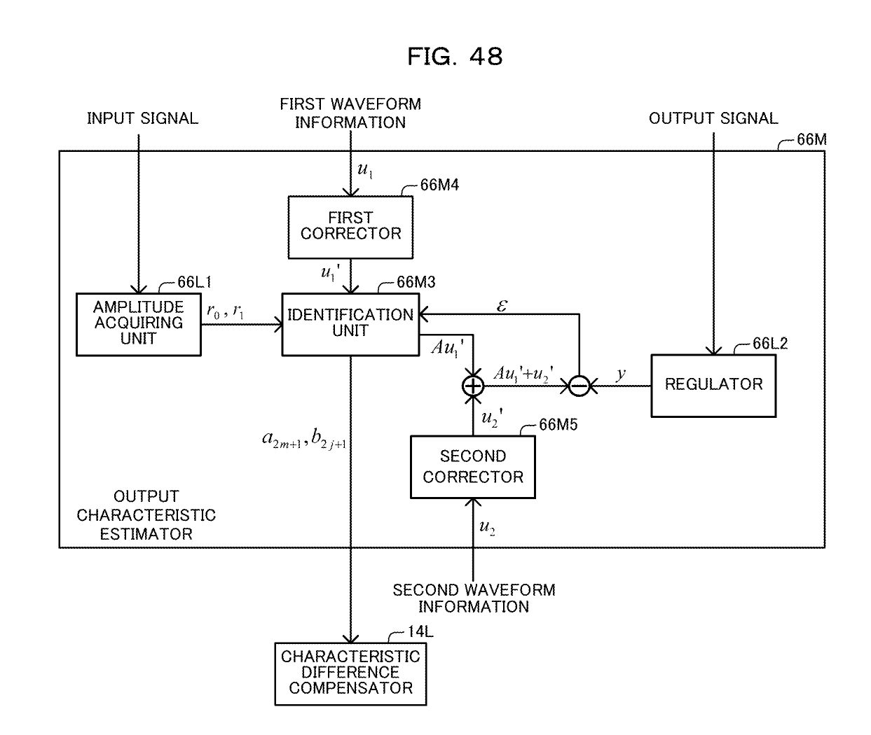

As illustrated in FIG. 48, the output characteristic estimator 66M according to the modified example includes, instead of the identification unit 66L3 of the output characteristic estimator 66L in FIG. 45, an identification unit 66M3. Further, the output characteristic estimator 66M according to the modified example additionally includes a first corrector 66M4 and a second corrector 66M5 when compared with the output characteristic estimator 66L in FIG. 45.

The first corrector 66M4 corrects the first waveform information u₁ based on the Formula 47 and the Formula 48 and outputs the first waveform information (first corrected waveform information) u₁′ after the correction to the identification unit 66M3.

The second corrector 66M5 corrects the second waveform information u₂ based on the Formula 48 and the Formula 49 and outputs the second waveform information (second corrected waveform information) u₂′ after the correction to the identification unit 66M3.

In this manner, the first corrector 66M4 and the second corrector 66M5 correct the first waveform information u₁ and the second waveform information u₂ respectively such that the first waveform information u₁ and the second waveform information u₂ have the value, which is obtained by doubling the arc cosine of the normalized amplitude r, as the phase difference thereof.

The identification unit 66M3 acquires the output characteristic value for the combination of the first characteristic quantity r₀ and the second characteristic quantity r₁ based on the identified output characteristic function and the first characteristic quantity r₀ and the second characteristic quantity r₁ output by the amplitude acquiring unit 66L1. The identification unit 66M3 outputs the value Au₁′ obtained by multiplying the acquired output characteristic value A by the first corrected waveform information u₁′.

The output characteristic estimator 66M inputs a value, which is obtained by subtracting the regulated output signal y output by the regulator 66L2 from the sum of the value Au₁′ output by the identification unit 66M3 and the second corrected waveform information u₂′, as the error ε into the identification unit 66M3.

The identification unit 66M3 identifies the output characteristic function as a function representing the output characteristic of the first amplifier 31. The identification unit 66M3 identifies the coefficient a₂ₘ₊₂ and the coefficient b₂ⱼ₊₂ of the output characteristic function based on the Formula 50 by using the method of least squares.

Thus, the output characteristic estimator 66M estimates the output characteristic of the first amplifier 31 such that the sum of a value obtained by multiplying the first corrected waveform information by the output characteristic value and the second corrected waveform information is brought closer to a value obtained by dividing the output signal by the first amplification factor. In this example, the output characteristic estimator 66M includes an A/D converter (not illustrated) and estimates the output characteristic by converting an analog signal into a digital signal.

The identification unit 66M3 outputs the determined coefficient a₂ₘ₊₁ and the determined coefficient b₂ⱼ₊₁ of the output characteristic function to the characteristic difference compensation unit 14L.

The amplifying apparatus 1M according to the modified example acquires, as described above, in contrast to the amplifying apparatus 1L according to the ninth embodiment, the decomposition phase based on a linear function of the normalized amplitude.

Accordingly, the amplification characteristic can be improved more than when a value, which is obtained by doubling the arc cosine of the normalized amplitude, is determined as the decomposition phase.

The amplifying apparatus 1M according to the modified example may use, instead of the output characteristic estimator 66M, the output characteristic estimator 66L according to the ninth embodiment.

When the normalized amplitude is 0, the amplifying apparatus 1M according to the modified example may use a function having a value larger than 180 degrees as a linear function.

Accordingly, the amplification characteristic can be improved more than when a value equal to or smaller than 180 degrees is determined as the phase difference between the two signals.

For example, the phase difference acquiring unit 12M determines, as represented in the Formula 51, the decomposition phase φ based on a linear function of the normalized amplitude r.

In this case, the first corrector 66M4 and the second corrector 66M5 may use the Formula 52 instead of the Formula 48.

### Tenth Embodiment

Next, an amplifying apparatus according to the tenth embodiment will be described. The amplifying apparatus according to the tenth embodiment is different from the amplifying apparatus according to the sixth embodiment in that the reciprocal of the output characteristic value is acquired based on the normalized amplitude. The following description focuses on such a difference.

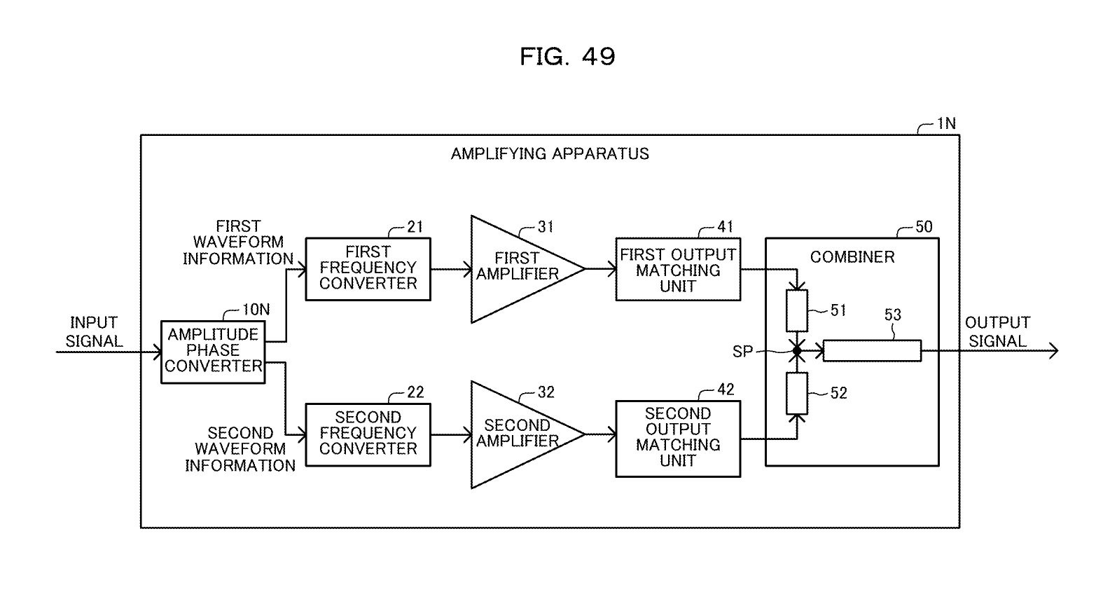

As illustrated in FIG. 49, an amplifying apparatus 1N according to the tenth embodiment includes, instead of the amplitude phase converter 10H of the amplifying apparatus 1H in FIG. 30, an amplitude phase converter 10N.

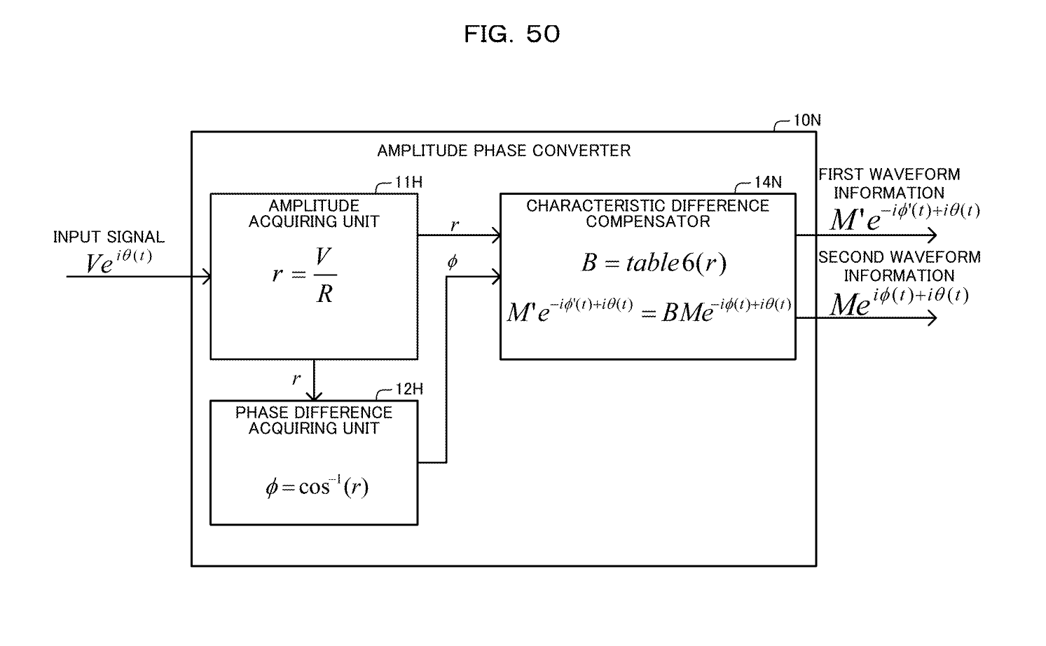

As illustrated in FIG. 50, the amplitude phase converter 10N includes, instead of the characteristic difference compensation unit 14H of the amplitude phase converter 10H in FIG. 31, a characteristic difference compensation unit 14N.

The characteristic difference compensation unit 14N is different from the characteristic difference compensation unit 14H in that, instead of the fourth table, a sixth table is held. The sixth table is a table associating the normalized amplitude and the value of the inverse characteristic of the output characteristic (for example, a reciprocal of the output characteristic value) of the first amplifier 31. The value of the inverse characteristic of the output characteristic is a value, which is obtained by multiplying a value obtained by dividing the input of the first amplifier 31 by the output thereof by the first amplification factor, for each normalized amplitude. The sixth table represents the inverse characteristic of the output characteristic of the first amplifier 31.

The sixth table is set, just like the fourth table, such that the output characteristic of the combiner 50 matches the desired characteristic.

As an example, the sixth table may be set such that the value, which is obtained by multiplying a value obtained by subtracting the second waveform information from a value obtained by dividing the output signal from the combiner 50 by the first amplification factor by the value of the inverse characteristic of the output characteristic, and the first waveform information are matched. As another example, the sixth table may be set such that the magnitude of a difference between the value, which is obtained by multiplying the value obtained by subtracting the second waveform information from the value obtained by dividing the output signal from the combiner 50 by the first amplification factor by the value of the inverse characteristic of the output characteristic, and the first waveform information is minimized (or is made equal to or smaller than a threshold).

The characteristic difference compensation unit 14N acquires, as represented in Formula 57, a value B of the inverse characteristic of the output characteristic associated with the normalized amplitude r output by the amplitude acquiring unit 11H in the held sixth table.

B=table6(r) [Mathematical Formula 57]

The characteristic difference compensation unit 14N may hold, instead of the sixth table, a parameter to identify an output characteristic inverse function as a function defining the relationship between the value of the inverse characteristic of the output characteristic and the normalized amplitude to acquire the value B of the inverse characteristic of the output characteristic based on the output characteristic inverse function.

The characteristic difference compensation unit 14N corrects the first waveform information by multiplying the generated first waveform information by the acquired value B of the inverse characteristic of the output characteristic. The corrected first waveform information is, as represented in the Formula 40, information indicating a waveform in which the amplitude is M′ and the phase is represented by −φ′+θ.

The characteristic difference compensation unit 14N outputs the corrected first waveform information to the first frequency converter 21 and also outputs the generated second waveform information to the second frequency converter 22.

According to the amplifying apparatus 1N in the tenth embodiment, as described above, just like the amplifying apparatus 1H in the sixth embodiment, the amplification characteristic can be improved.

Further, according to the amplifying apparatus 1N in the tenth embodiment, the difference between output characteristics of the two amplifiers 31, 32 can be compensated for. As a result, the amplification characteristic can be improved.

The amplifying apparatus 1N in the tenth embodiment corrects both of the amplitude and the phase of the first waveform information, but may correct only one of the amplitude and the phase.

The amplifying apparatus 1N in the tenth embodiment may have a table, which is associating the normalized amplitude and the value of the inverse characteristic of the output characteristic of the second amplifier 32, as the sixth table to correct the second waveform information instead of the first waveform information.

### Modified Example of the Tenth Embodiment

Next, an amplifying apparatus according to the modified example of the tenth embodiment will be described. The amplifying apparatus according to the modified example of the tenth embodiment is different from the amplifying apparatus according to the tenth embodiment in that the inverse characteristic of the output characteristic of the first amplifier 31 is estimated and the first waveform information is corrected based on the estimated inverse characteristic. The following description focuses on such a difference.

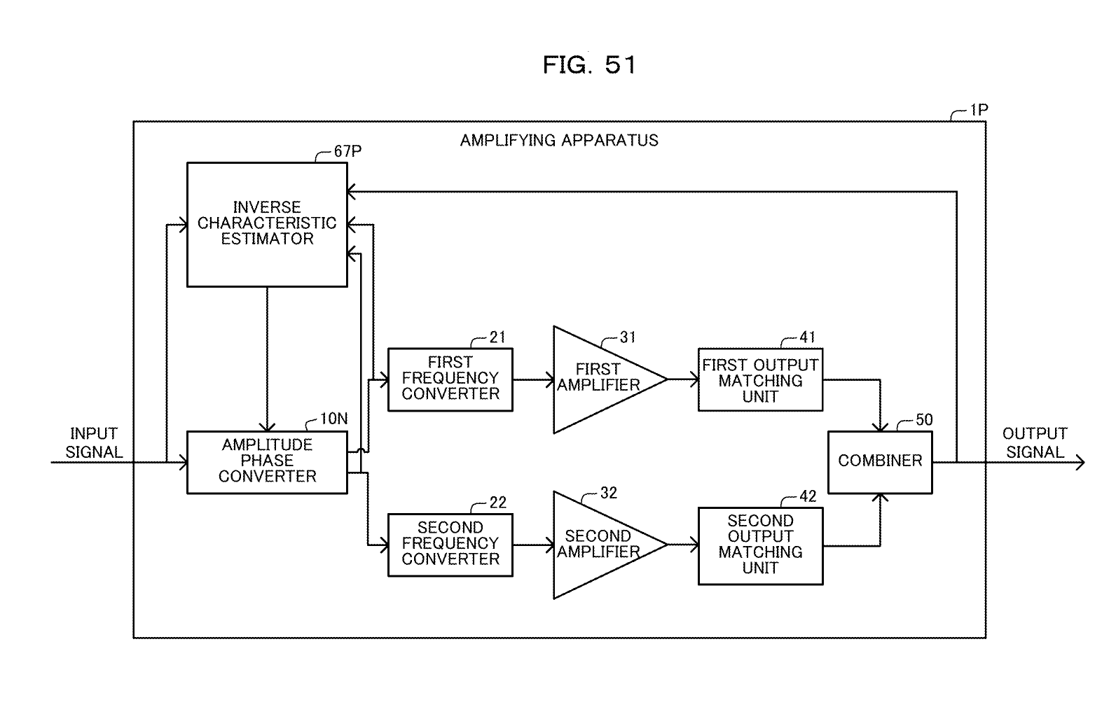

As illustrated in FIG. 51, an amplifying apparatus 1P according to the modified example additionally includes an inverse characteristic estimator 67P when compared with the amplifying apparatus 1N in FIG. 49.

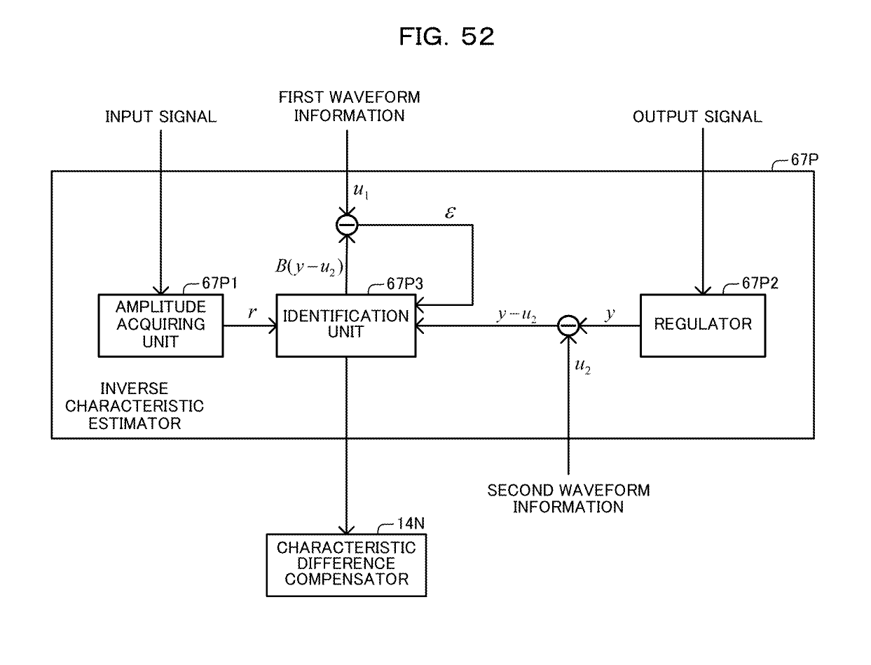

The inverse characteristic estimator 67P includes, as illustrated in FIG. 52, an amplitude acquiring unit 67P1, a regulator 67P2, and an identification unit 67P3.

The amplitude acquiring unit 67P1 acquires, based on the input signal, the amplitude (normalized amplitude) r of the input signal normalized so that the maximum value thereof is 1 based on the Formula 2. The amplitude acquiring unit 67P1 outputs the acquired normalized amplitude r to the identification unit 67P3.

The regulator 67P2 regulates the amplitude and the phase of the output signal. In this example, the regulator 67P2 outputs a value, which is obtained by dividing the output signal by the first amplification factor, as the regulated output signal y.

The identification unit 67P3 identifies the inverse characteristic of the output characteristic of the first amplifier 31. In this example, the identification unit 67P3 identifies the value B of the inverse characteristic of the output characteristic for each normalized amplitude r. The method of identifying the inverse characteristic will be described later.

The inverse characteristic estimator 67P inputs a value y−u₂ obtained by subtracting the second waveform information u₂ from the regulated output signal y output by the regulator 67P2 into the identification unit 67P3.

The identification unit 67P3 acquires the value B of the inverse characteristic of the output characteristic for the normalized amplitude r based on the identified inverse characteristic and the normalized amplitude r output by the amplitude acquiring unit 67P1. The identification unit 67P3 outputs a value B(y−u₂) obtained by multiplying the input value y−u₂ by the acquired value B of the inverse characteristic of the output characteristic.

The inverse characteristic estimator 67P inputs, as the error ε, a difference between the first waveform information u₁ and the value B(y−u₂) output by the identification unit 67P3 into the identification unit 67P3.

The identification unit 67P3 determines the value B of the inverse characteristic of the output characteristic for each normalized amplitude r such that the sum of squares of a plurality of errors ε acquired for a plurality of different normalized amplitudes r is minimized.

Thus, the inverse characteristic estimator 67P estimates the inverse characteristic of the output characteristic of the first amplifier 31 such that the value obtained by multiplying the value obtained by subtracting the second waveform information u₂ from the regulated output signal y by the value B of the inverse characteristic of the output characteristic is brought closer to the first waveform information u₁. In this example, the inverse characteristic estimator 67P includes an A/D converter (not illustrated) and estimates the inverse characteristic by converting an analog signal into a digital signal.

The identification unit 67P3 outputs the determined value B of the inverse characteristic of the output characteristic for each normalized amplitude r to the characteristic difference compensation unit 14N.

The inverse characteristic estimator 67P may determine and output the value B of the inverse characteristic of the output characteristic in a predetermined period such as a time when the amplifying apparatus 1P is activated. The inverse characteristic estimator 67P may also determine and output the value B of the inverse characteristic of the output characteristic each time a predetermined period passes. The inverse characteristic estimator 67P may continue to determine and output the value B of the inverse characteristic of the output characteristic while the amplifying apparatus 1P operates. For example, the amplitude phase converter 10N may hold the value B of the inverse characteristic of the output characteristic output by the inverse characteristic estimator 67P to use the held value B before the new value B of the inverse characteristic of the output characteristic is output.

According to the amplifying apparatus 1P in the modified example of the tenth embodiment, as described above, just like the amplifying apparatus 1N in the tenth embodiment, the amplification characteristic can be improved.

Further, according to the amplifying apparatus 1P in the modified example of the tenth embodiment, the difference between output characteristics of the two amplifiers 31, 32 can be compensated for. As a result, the amplification characteristic can be improved.

The amplifying apparatus 1P according to the modified example of the tenth embodiment corrects both of the amplitude and the phase of the first waveform information, but may correct only one of the amplitude and the phase.

The amplifying apparatus 1P according to the modified example of the tenth embodiment may estimate an inverse characteristic of the output characteristic of, instead of the first amplifier 31, the second amplifier 32 to correct, instead of the first waveform information, the second waveform information based on the estimated inverse characteristic.

### Eleventh Embodiment

Next, an amplifying apparatus according to the eleventh embodiment will be described. The amplifying apparatus according to the eleventh embodiment is different from the amplifying apparatus according to the sixth embodiment in that the first waveform information is determined such that the difference between output characteristics of the two amplifiers is compensated for. The following description focuses on such a difference.

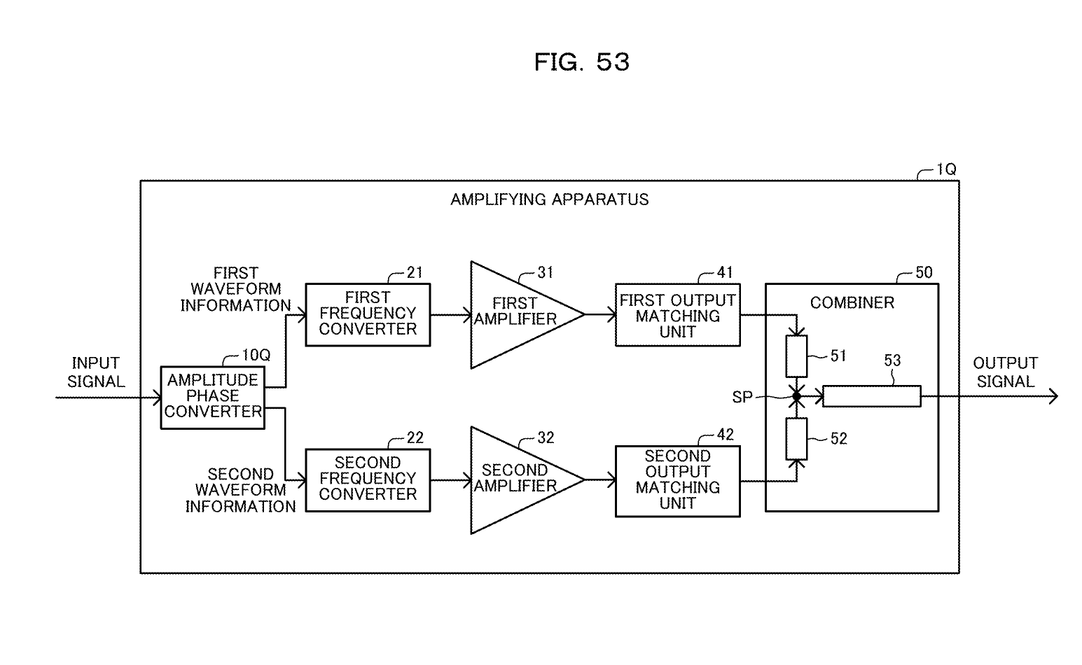

As illustrated in FIG. 53, an amplifying apparatus 1Q according to the eleventh embodiment includes, instead of the amplitude phase converter 10H of the amplifying apparatus 1H in FIG. 30, an amplitude phase converter 10Q.

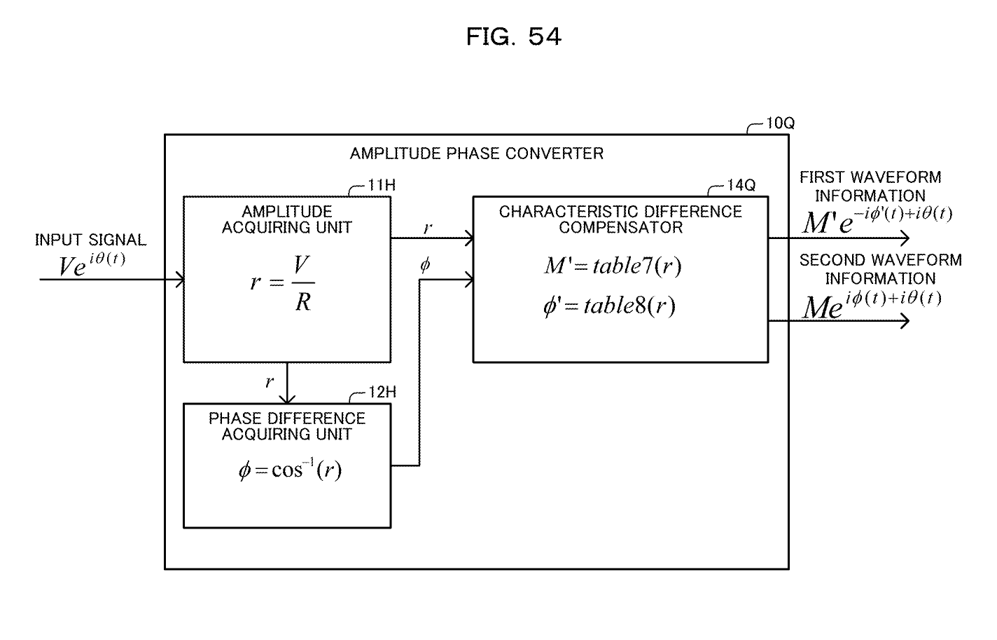

As illustrated in FIG. 54, the amplitude phase converter 10Q includes, instead of the characteristic difference compensation unit 14H of the amplitude phase converter 10H in FIG. 31, a characteristic difference compensation unit 14Q.

The characteristic difference compensation unit 14Q generates first waveform information and second waveform information based on the normalized amplitude r output by the amplitude acquiring unit 11H and the decomposition phase φ output by the phase difference acquiring unit 12H.

In this example, as represented in the Formula 36, the characteristic difference compensation unit 14Q generates information, which is indicating a waveform in which the amplitude is the amplification factor M and the phase is represented by φ+θ, as the second waveform information.

In addition, the characteristic difference compensation unit 14Q holds a seventh table associating the normalized amplitude r and a compensated amplitude M′ in advance (for example, stored in a memory).

The seventh table is set such that the output characteristic of the combiner 50 matches a desired characteristic. The desired characteristic includes, for example, a first characteristic, a second characteristic, or both. The first characteristic is a characteristic in which the amplitude of an output signal from the combiner 50 is 0 when the real amplitude of an input signal is 0. The second characteristic is a characteristic in which the relationship between the real amplitude of an input signal and the amplitude of an output signal from the combiner 50 is a linear relationship.

For example, a relationship between the seventh table and the output characteristic of the combiner 50 may be determined by an experiment or a simulation to set the seventh table based on the relationship. For example, the seventh table may be set such that the difference between output characteristics of the two amplifiers 31, 32 is compensated for. In this case, as will be described later, the characteristic difference compensation unit 14Q generates the first waveform information such that the difference between output characteristics of the two amplifiers 31, 32 is compensated for. The generation of the first waveform information is an example of the determination of the first waveform information.

As an example, the seventh table may be set such that a value, which is obtained by subtracting the second waveform information from the value obtained by dividing the output signal from the combiner 50 by the first amplification factor, and a predetermined reference signal are matched. The reference signal is, for example, a signal acquired based on the Formula 2 and the Formula 27 and represented by the Formula 35. As another example, the seventh table may be set such that the magnitude of a difference between a value, which is obtained by subtracting the second waveform information from the value obtained by dividing the output signal from the combiner 50 by the first amplification factor, and the reference signal is minimized (or is made equal to or smaller than a threshold).

The characteristic difference compensation unit 14Q acquires, as represented in Formula 58, the compensated amplitude M′ associated with the normalized amplitude r output by the amplitude acquiring unit 11H in the held seventh table.

M′=table7(r) [Mathematical Formula 58]

Similarly, the characteristic difference compensation unit 14Q holds an eighth table associating the normalized amplitude r and a compensated phase φ′ in advance (for example, stored in a memory). Just like the seventh table, the eighth table is set such that the output characteristic of the combiner 50 matches the desired characteristic.

The characteristic difference compensation unit 14Q acquires, as represented in Formula 59, the compensated phase φ′ associated with the normalized amplitude r output by the amplitude acquiring unit 11H in the held eighth table.

φ′=table8(r) [Mathematical Formula 59]

In this example, as represented in the Formula 40, the characteristic difference compensation unit 14Q generates information, which is indicating a waveform in which the amplitude is the acquired compensated amplitude M′ and the phase is represented by −φ′+θ, as the first waveform information.

The characteristic difference compensation unit 14Q outputs the generated first waveform information to the first frequency converter 21 and also outputs the generated second waveform information to the second frequency converter 22.

According to the amplifying apparatus 1Q in the eleventh embodiment, as described above, just like the amplifying apparatus 1H in the sixth embodiment, the amplification characteristic can be improved.

Further, according to the amplifying apparatus 1Q in the eleventh embodiment, the difference between output characteristics of the two amplifiers 31, 32 can be compensated for. As a result, the amplification characteristic can be improved.

The amplifying apparatus 1Q in the eleventh embodiment corrects both of the amplitude and the phase of the first waveform information, but may correct only one of the amplitude and the phase.

The amplifying apparatus 1Q in the eleventh embodiment may also correct, instead of the first waveform information, the second waveform information.

### Modified Example of the Eleventh Embodiment

Next, an amplifying apparatus according to the modified example of the eleventh embodiment will be described. The amplifying apparatus according to the modified example of the eleventh embodiment is different from the amplifying apparatus according to the eleventh embodiment in that the seventh table and the eighth table are corrected based on the input signal and the output signal. The following description focuses on such a difference.

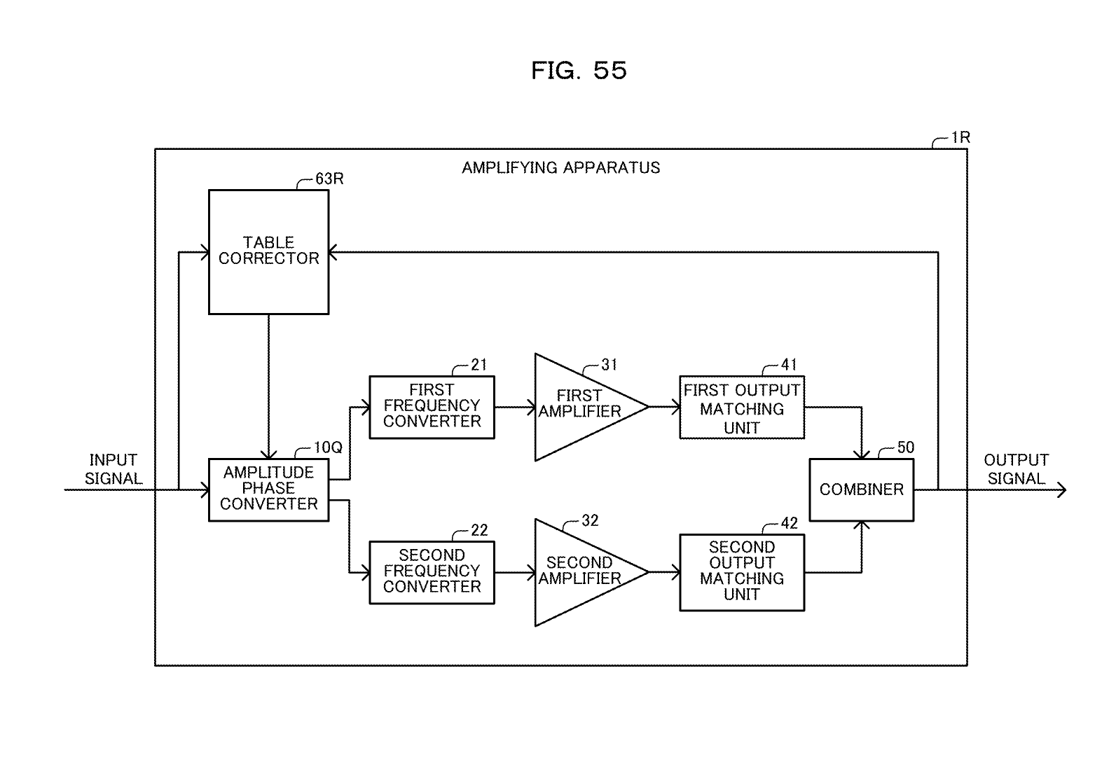

As illustrated in FIG. 55, an amplifying apparatus 1R according to the modified example additionally includes a table corrector 63R when compared with the amplifying apparatus 1Q in FIG. 53.

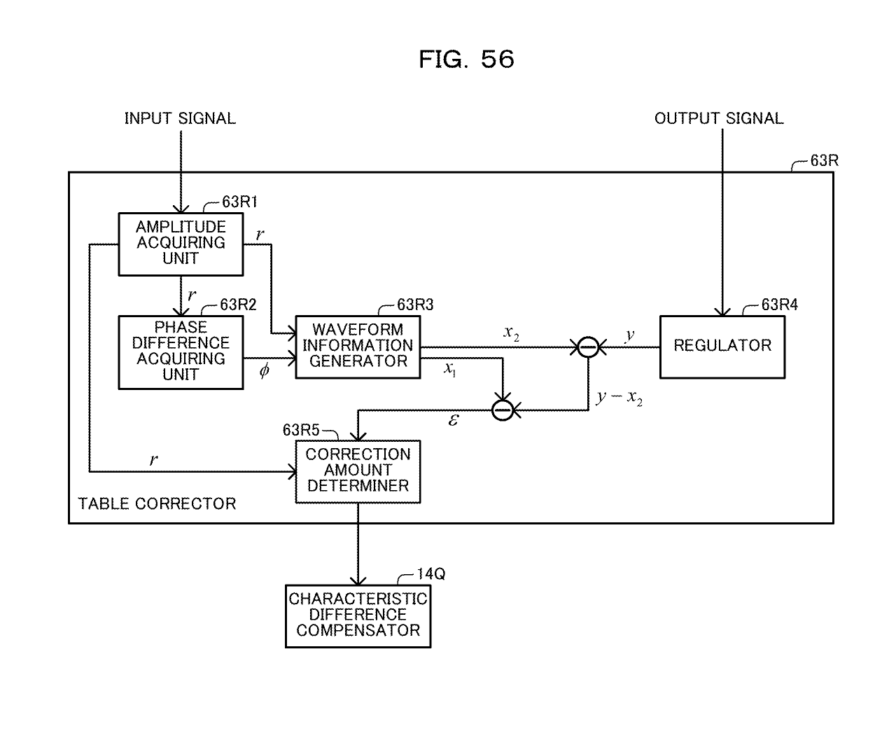

The table corrector 63R includes, as illustrated in FIG. 56, an amplitude acquiring unit 63R1, a phase difference acquiring unit 63R2, a waveform information generator 63R3, a regulator 63R4, and a correction amount determiner 63R5.

The amplitude acquiring unit 63R1 acquires, based on the input signal, the amplitude (normalized amplitude) r of the input signal normalized so that the maximum value thereof is 1 based on the Formula 2. The amplitude acquiring unit 63R1 outputs the acquired normalized amplitude r to each of the phase difference acquiring unit 63R2, the waveform information generator 63R3, and the correction amount determiner 63R5.

The phase difference acquiring unit 63R2 acquires the decomposition phase φ based on the normalized amplitude r output by the amplitude acquiring unit 63R1. In this example, the phase difference acquiring unit 63R2 acquires, as represented in the Formula 27, the arc cosine of the normalized amplitude r as the decomposition phase φ. The phase difference acquiring unit 63R2 outputs the acquired decomposition phase φ to the waveform information generator 63R3.

The waveform information generator 63R3 generates first waveform information x₁ and second waveform information x₂ based on the normalized amplitude r output by the amplitude acquiring unit 63R1 and the decomposition phase φ output by the phase difference acquiring unit 63R2.

In this example, the first waveform information x₁ is, as represented in the Formula 35, information indicating a waveform in which the amplitude is the amplification factor M and the phase is represented by −φ+θ. Similarly, the second waveform information x₂ is, as represented in the Formula 36, information indicating a waveform in which the amplitude is the amplification factor M and the phase is represented by φ+θ.

The waveform information generator 63R3 outputs the generated first waveform information x₁ and the generated second waveform information x₂.

The regulator 63R4 regulates the amplitude and the phase of the output signal. In this example, the regulator 63R4 outputs a value, which is obtained by dividing the output signal by the first amplification factor, as the regulated output signal y.

The table corrector 63R inputs a value y−x₂−x₁, which is obtained by further subtracting the first waveform information x₁ from a value y−x₂ obtained by subtracting the second waveform information x₂ from the regulated output signal y output by the regulator 63R4, as the error ε into the correction amount determiner 63R5.

The correction amount determiner 63R5 determines a correction amount of the compensated amplitude M′ and a correction amount of the compensated phase φ′ for each normalized amplitude r such that the sum of squares of a plurality of errors ε acquired for a plurality of different normalized amplitudes r is minimized.

Thus, the table corrector 63R determines the correction amount of the compensated amplitude M′ and the correction amount of the compensated phase φ′ such that the value y−x₂ obtained by subtracting the second waveform information x₂ from the regulated output signal y is brought closer to the first waveform information x₁. The first waveform information x₁ is an example of the reference signal.

The table corrector 63R outputs the determined correction amount of the compensated amplitude M′ and the determined correction amount of the compensated phase φ′ for each normalized amplitude r to the characteristic difference compensation unit 14Q.

The characteristic difference compensation unit 14Q corrects each of the seventh table and the eighth table based on the correction amount of the compensated amplitude M′ and the correction amount of the compensated phase φ′ output by the table corrector 63R.

The table corrector 63R may determine and output the correction amount in a predetermined period such as a time when the amplifying apparatus 1R is activated. The table corrector 63R may also determine and output the correction amount each time a predetermined period passes. The table corrector 63R may continue to determine and output the correction amount while the amplifying apparatus 1R operates.

In this example, the table corrector 63R includes an A/D converter (not illustrated) and corrects the above tables by converting an analog signal into a digital signal.

According to the amplifying apparatus 1R in the embodiment of the eleventh embodiment, as described above, just like the amplifying apparatus 1Q in the eleventh embodiment, the amplification characteristic can be improved.

Further, according to the amplifying apparatus 1R in the embodiment of the eleventh embodiment, the difference between output characteristics of the two amplifiers 31, 32 can be compensated for. As a result, the amplification characteristic can be improved.

The amplifying apparatus 1R in the embodiment of the eleventh embodiment may determine, instead of the first waveform information, the second waveform information based on the seventh table and the eighth table.

### Twelfth Embodiment

Next, an amplifying apparatus according to the twelfth embodiment will be described. The amplifying apparatus according to the twelfth embodiment is different from the amplifying apparatus according to the second embodiment in that the decomposition phase is acquired based on a linear function of the normalized amplitude. The following description focuses on such a difference.

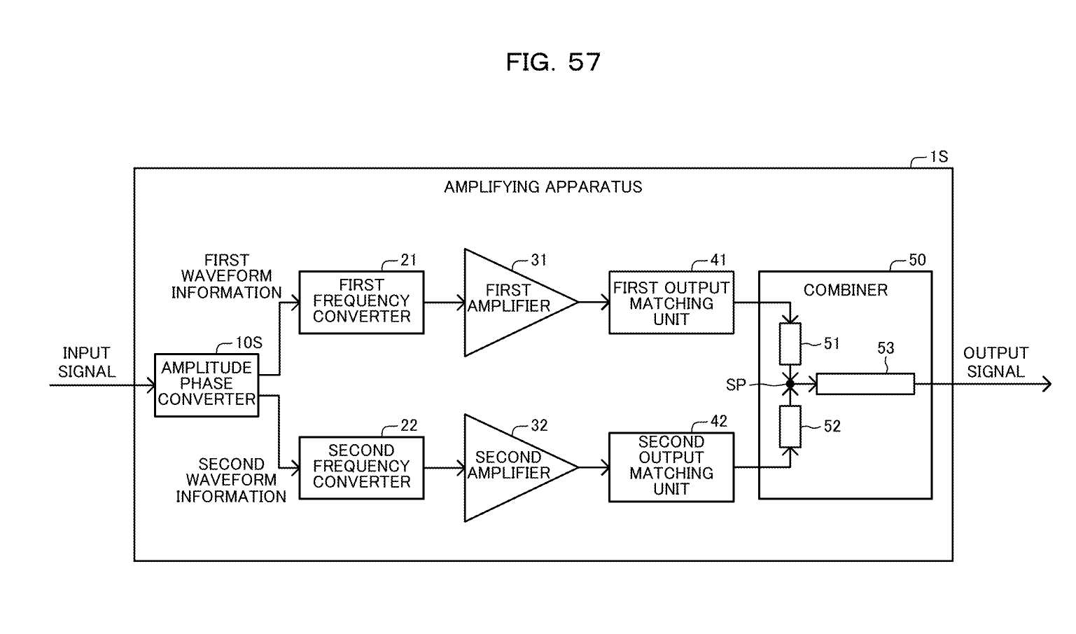

As illustrated in FIG. 57, an amplifying apparatus 1S according to the twelfth embodiment includes, instead of the amplitude phase converter 10C of the amplifying apparatus 1C in FIG. 11, an amplitude phase converter 10S.

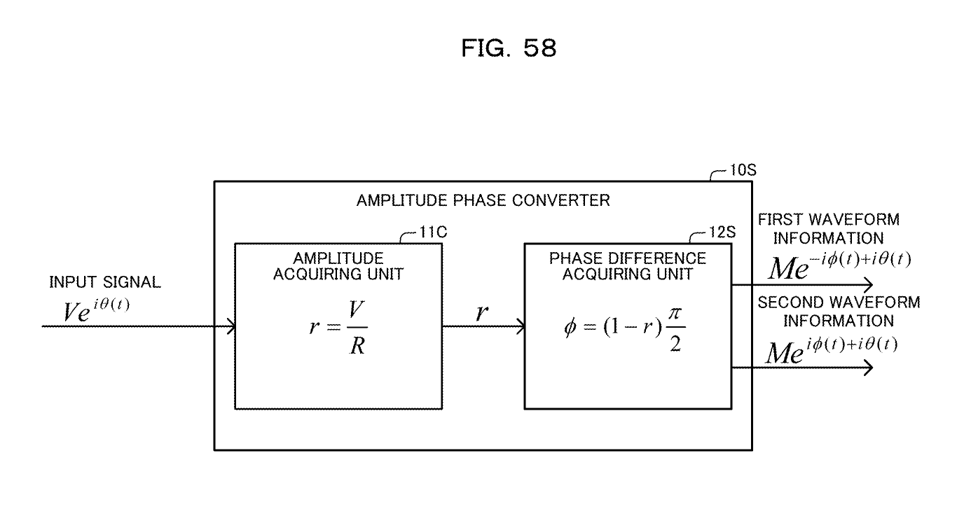

As illustrated in FIG. 58, the amplitude phase converter 10S includes, instead of the phase difference acquiring unit 12C of the amplitude phase converter 10C in FIG. 12, a phase difference acquiring unit 12S.

The phase difference acquiring unit 12S acquires the decomposition phase φ based on the normalized amplitude r output by the amplitude acquiring unit 11C.

For example, as illustrated in FIG. 39, the relationship between the normalized output amplitude and the phase difference is represented by the curve C9 when a Wilkinson combiner is used as the combiner. On the other hand, the inventors found that the relationship between the normalized output amplitude and the phase difference may be represented by the straight line C10 when a Chireix combiner is used as the combiner.

Thus, in this example, the phase difference acquiring unit 12S acquires, as represented in the Formula 46, the decomposition phase φ based on a linear function of the normalized amplitude r. The phase difference acquiring unit 12S generates first waveform information and second waveform information based on the acquired decomposition phase φ and outputs the generated first waveform information to the first frequency converter 21 and also outputs the generated second waveform information to the second frequency converter 22.

In this example, the first waveform information is, as represented in the Formula 35, information indicating a waveform in which the amplitude is the amplification factor M and the phase is represented by −φ+θ. Similarly, the second waveform information is, as represented in the Formula 36, information indicating a waveform in which the amplitude is the amplification factor M and the phase is represented by φ+θ.

The amplifying apparatus 1S according to the twelfth embodiment acquires, as described above, in contrast to the amplifying apparatus 1C according to the second embodiment, the decomposition phase based on a linear function of the normalized amplitude.

Accordingly, the amplification characteristic can be improved more than when the value, which is obtained by doubling the arc cosine of the normalized amplitude, is determined as the decomposition phase.

When the normalized amplitude is 0, the amplifying apparatus 1S according to the twelfth embodiment may use a function having a value larger than 180 degrees as a linear function.

Accordingly, the amplification characteristic can be improved more than when a value equal to or smaller than 180 degrees is determined as the phase difference between the two signals.

For example, the phase difference acquiring unit 12S determines, as represented in the Formula 51, the decomposition phase φ based on a linear function of the normalized amplitude r.

### Thirteenth Embodiment

Next, an amplifying apparatus according to the thirteenth embodiment will be described. The amplifying apparatus according to the thirteenth embodiment is different from the amplifying apparatus according to the third embodiment in that the amplitude of the signal input into the amplifier is limited to a maximum amplitude. The following description focuses on such a difference.

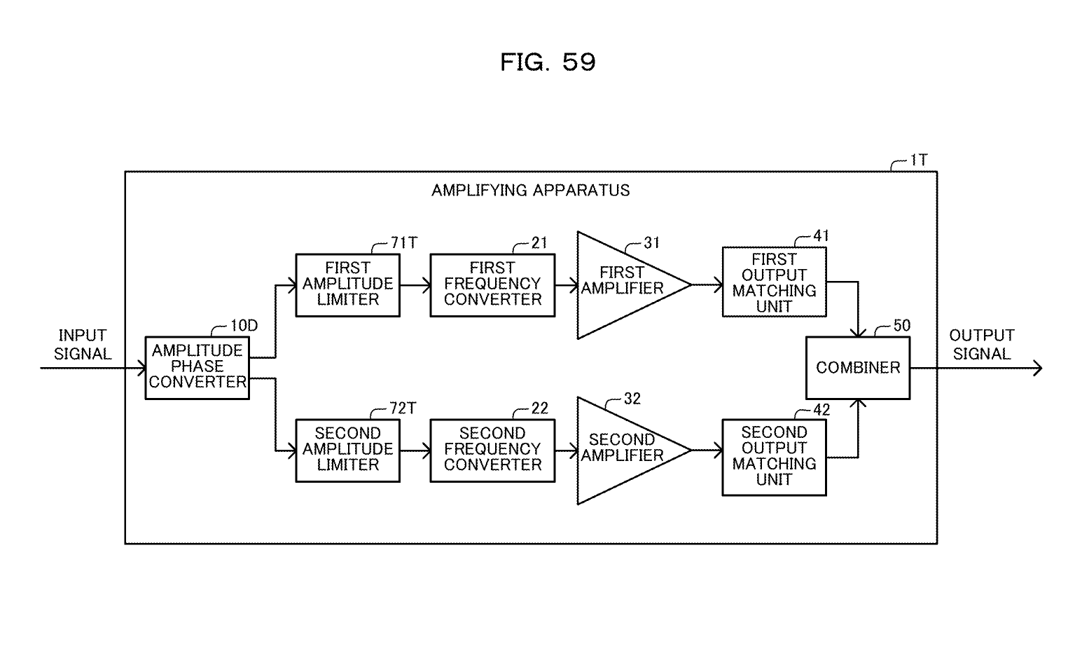

As illustrated in FIG. 59, an amplifying apparatus 1I according to the thirteenth embodiment additionally includes a first amplitude limiter 71T and a second amplitude limiter 72T when compared with the amplifying apparatus 1D in FIG. 16.

When the amplitude of the first waveform information output by the amplitude phase converter 10D is larger than a predetermined maximum amplitude, the first amplitude limiter 71T corrects the amplitude of the first waveform information to the maximum amplitude. The maximum amplitude is set to, for example, a value larger than the amplification factor M by a predetermined allowable value. The maximum amplitude may be set to a value equal to the amplification factor M.

When the amplitude of the first waveform information output by the amplitude phase converter 10D is equal to or smaller than the maximum amplitude, the first amplitude limiter 71T outputs the first waveform information to the first frequency converter 21 without the correction. When the amplitude of the first waveform information output by the amplitude phase converter 10D is larger than the maximum amplitude, the first amplitude limiter 71T outputs the corrected first waveform information to the first frequency converter 21.

When the amplitude of the second waveform information output by the amplitude phase converter 10D is larger than the maximum amplitude, the second amplitude limiter 72T corrects the amplitude of the second waveform information to the maximum amplitude. When the amplitude of the second waveform information output by the amplitude phase converter 10D is equal to or smaller than the maximum amplitude, the second amplitude limiter 72T outputs the second waveform information to the second frequency converter 22 without the correction. When the amplitude of the second waveform information output by the amplitude phase converter 10D is larger than the maximum amplitude, the second amplitude limiter 72T outputs the corrected second waveform information to the second frequency converter 22.

The amplifying apparatus 1I according to the thirteenth embodiment avoids, as described above, the amplitude of signals input into the amplifiers 31, 32 being too large. As a result, the amplification characteristic can be improved.

The amplifying apparatus 1I according to the thirteenth embodiment corrects the both amplitudes of the first waveform information and the second waveform information, but may correct the amplitude of only one of the first waveform information and the second waveform information.

The amplifying apparatuses according to the fifth to twelfth embodiments described above may include both or one of the first amplitude limiter 71T and the second amplitude limiter 72T according to the thirteenth embodiment.

### Fourteenth Embodiment

Next, a communication apparatus according to the fourteenth embodiment will be described.

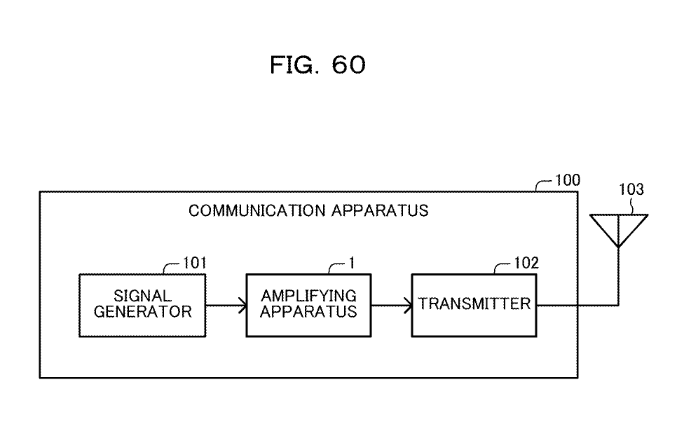

As illustrated in FIG. 60, a communication apparatus 100 according to the fourteenth embodiment includes, the amplifying apparatus 1 according to the first embodiment, a signal generator 101, a transmitter 102, and an antenna 103.

The signal generator 101 generates an input signal based on information received from an external apparatus (not illustrated) and information generated by the communication apparatus 100. The signal generator 101 outputs the generated input signal to the amplifying apparatus 1.

As described above, the amplifying apparatus 1 amplifies the input signal output by the signal generator 101 by the amplification factor and outputs the amplified signal as an output signal to the transmitter 102.

The transmitter 102 transmits the output signal output by the amplifying apparatus 1 via the antenna 103. The output signal output by the amplifying apparatus 1 is an example of the signal combined by the combiner 50.

According to the communication apparatus 100 in the fourteenth embodiment, the output characteristic (amplification characteristic) of the amplifying apparatus 1 can be improved and therefore, quality of a transmitted signal can be enhanced.

The communication apparatus 100 according to the fourteenth embodiment may include, instead of the amplifying apparatus 1, one of the amplifying apparatuses 1B to, 1N, 1P to 1T.

The amplifying apparatus according to each of the above embodiments may include, instead of the lossless combiner, a combiner that is different from the lossless combiner.

Any function unit of the amplifying apparatus according to each of the above embodiments may omit, among functions of the function unit, a function also held by another function unit to share the function of the other function unit.

As another modified example of each of the above embodiments, any combination of the above embodiments and modified examples may be adopted.

An amplification characteristic of the amplifying apparatus can be improved.

All examples and conditional language provided herein are intended for pedagogical purposes of aiding the reader in understanding the invention and the concepts contributed by the inventor to furthering the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. An amplifying apparatus comprising:
a decomposer that decomposes an input signal into two signals having different phases;
two amplifiers that amplify the decomposed two signals, respectively;
a combiner that combines output of the amplifiers; and
a controller that controls at least one of waveform information of at least one of the two signals and an operating state of the two amplifiers such that an output characteristic of the combiner matches a desired characteristic.

2. The amplifying apparatus according to claim 1, wherein
the waveform information contains the phase of the signal and
the controller determines a phase difference of the two signals based on a second amplitude obtained by correcting a first amplitude as an amplitude of the input signal in accordance with the first amplitude.

3. The amplifying apparatus according to claim 2, wherein
the controller
holds a first table associating the first amplitude and the second amplitude and
corrects the held first table based on power consumption consumed by the amplifiers and output power of the combined signal, or on the input signal and the combined signal.

4. The amplifying apparatus according to claim 2, wherein
the second amplitude is a square root of the first amplitude.

5. The amplifying apparatus according to claim 2, wherein
the controller determines a value, which is obtained by doubling an arc cosine of the second amplitude, as the phase difference.

6. The amplifying apparatus according to claim 1, wherein
the waveform information contains the phase of the signal and
the controller determines a value larger than 180 degrees as a phase difference of the two signals.

7. The amplifying apparatus according to claim 6, wherein
the controller corrects a first phase difference determined based on an amplitude of the input signal within a range of 0 degrees to 180 degrees to a second phase difference determined in a range of the 0 degrees to an upper limit larger than 180 degrees in accordance with the first phase difference and determines the corrected second phase difference as the phase difference of the two signals.

8. The amplifying apparatus according to claim 7, wherein
the controller
holds a second table associating the first phase difference and the second phase difference and
corrects the held second table based on power consumption consumed by the amplifiers and output power of the combined signal, or on the input signal and the combined signal.

9. The amplifying apparatus according to claim 1, wherein
the waveform information contains the amplitude of the signal and
the controller determines each of the amplitudes of the two signals as a third amplitude when the amplitude of the input signal is larger than a first threshold and determines the amplitude of at least one of the two signals as a fourth amplitude, which is smaller than the third amplitude, when the amplitude of the input signal is smaller than the first threshold.

10. The amplifying apparatus according to claim 9, wherein
the fourth amplitude has a value changing in accordance with the amplitude of the input signal and
the controller
holds a third table associating the amplitude of the input signal and the fourth amplitude and
corrects the held third table based on power consumption consumed by the amplifiers and output power of the combined signal, or on the input signal and the combined signal.

11. The amplifying apparatus according to claim 1, wherein
the waveform information contains at least one of the amplitude and the phase of the signal and
the controller corrects at least one of the amplitude and the phase of one of the two signals based on a first amplitude as the amplitude of the input signal.

12. The amplifying apparatus according to claim 11, wherein
the controller makes the correction such that a difference of the output characteristics of the two amplifiers is compensated for.

13. The amplifying apparatus according to claim 12, wherein
the controller, for the first amplitude based on the output characteristic of one of the two amplifiers and the first amplitude, acquires an output characteristic value as a value obtained by dividing the value obtained by dividing the output of the one amplifier by input of the one amplifier by a predetermined amplification factor and makes the correction by multiplying the signal input into the one amplifier by the value of an inverse characteristic of the output characteristic based on the acquired output characteristic value.

14. The amplifying apparatus according to claim 13, wherein
the controller estimates the output characteristic such that a sum of the value obtained by multiplying the signal input into the one amplifier by the output characteristic value and the signal input into the other of the two amplifiers is brought closer to the value obtained by dividing the combined signal by the amplification factor.

15. The amplifying apparatus according to claim 12, wherein
the output characteristic is represented by a polynomial concerning a product of the input signal and a conjugate complex number of the input signal.

16. The amplifying apparatus according to claim 12, wherein
the output characteristic is represented by a sum of a first polynomial concerning a product of the input signal at a first point in time and a conjugate complex number of the input signal at the first point in time and a second polynomial concerning a product of the input signal at the first point in time and a conjugate complex number of the input signal at a second point in time, which is different from the first point in time.

17. The amplifying apparatus according to claim 11, wherein
the controller determines a phase difference of the two signals based on a linear function of the first amplitude.

18. The amplifying apparatus according to claim 14, wherein
the controller
determines a phase difference of the two signals based on a linear function of the first amplitude and
corrects the two signals input into the two amplifiers so as to have a value, which is obtained by doubling an arc cosine of the first amplitude, as the phase difference and estimates the output characteristic such that the sum of the value obtained by multiplying the signal corresponding to the signal input into the one amplifier of the corrected signals by the output characteristic value and the signal corresponding to the signal input into the other amplifier of the corrected signals is brought closer to the value obtained by dividing the combined signal by the amplification factor.

19. The amplifying apparatus according to claim 17, wherein
the linear function has the value larger than 180 degrees when the first amplitude is 0.

20. The amplifying apparatus according to claim 12, wherein
the controller, for the first amplitude based on an inverse characteristic of the output characteristic of one of the two amplifiers and the first amplitude, acquires a value of the inverse characteristic of the output characteristic based on an output characteristic value as the value obtained by dividing the value obtained by dividing the output of the one amplifier by input of the one amplifier by a predetermined amplification factor and makes the correction by multiplying the signal input into the one amplifier by the acquired value of the inverse characteristic.

21. The amplifying apparatus according to claim 20, wherein
the controller estimates the inverse characteristic of the output characteristic such that the value obtained by multiplying the value obtained by subtracting the signal input into the other of the two amplifiers from the value obtained by dividing the combined signal by the amplification factor by the value of the inverse characteristic is brought closer to the signal input into the one amplifier.

22. The amplifying apparatus according to claim 1, wherein
the waveform information contains at least one of the amplitude and the phase of the signal and
the controller determines at least one of the amplitude and the phase of one of the two signals based on a first amplitude as the amplitude of the input signal such that a difference of the output characteristics of the two amplifiers is compensated for.

23. The amplifying apparatus according to claim 22, wherein
the controller makes a decision such that the value obtained by subtracting the other of the two signals from the value obtained by dividing the combined signal by the amplification factor is brought closer to a predetermined reference signal.

24. The amplifying apparatus according to claim 1, wherein
the waveform information contains the phase of the signal and
the controller determines a phase difference of the two signals based on a linear function of a first amplitude as an amplitude of the input signal.

25. The amplifying apparatus according to claim 24, wherein
the linear function has a value larger than 180 degrees when the first amplitude is 0.

26. The amplifying apparatus according to claim 1, wherein
when an amplitude of the signal input into the amplifier is larger than an upper limit amplitude, the controller corrects the amplitude of the signal to the upper limit amplitude.

27. The amplifying apparatus according to claim 1, wherein
each of the two amplifiers performs the amplification by performing a saturated operation and
when an amplitude of the input signal is smaller than a second threshold, the controller controls at least one of the two amplifiers such that a state of the amplifier is brought closer to an unsaturated operation state in which the amplifier performs an unsaturated operation.

28. The amplifying apparatus according to claim 27, wherein
when the amplitude of the input signal is smaller than the second threshold, the controller controls a power supply voltage of the amplifier to be larger than the power supply voltage of the amplifier when the amplitude is larger than the second threshold.

29. The amplifying apparatus according to claim 27, wherein
when the amplitude of the input signal is smaller than the second threshold, the controller controls a bias voltage of the amplifier to be larger than the power supply voltage of the amplifier when the amplitude is larger than the second threshold.

30. The amplifying apparatus according to claim 27, further comprising:
a harmonic processor connected to a line on which the amplified signal is transmitted so that each harmonic component of the amplified signal is processed, wherein
when the amplitude of the input signal is smaller than the second threshold, the controller disconnects the harmonic processor from the line.

31. The amplifying apparatus according to claim 1, wherein
an Outphasing method is followed and the combiner is a lossless combiner.

32. A communication apparatus comprising:
a decomposer that decomposes an input signal into two signals having different phases;
two amplifiers that amplify the decomposed two signals, respectively;
a combiner that combines output of the amplifiers;
a controller that controls at least one of waveform information of at least one of the two signals and an operating state of the two amplifiers such that an output characteristic of the combiner matches a desired characteristic; and
a transmitter that transmits the combined signal.

33. The communication apparatus according to claim 32, wherein
the waveform information contains the phase of the signal and
the controller determines a phase difference of the two signals based on a second amplitude obtained by correcting a first amplitude as an amplitude of the input signal in accordance with the first amplitude.

34. The communication apparatus according to claim 32, wherein
the waveform information contains the phase of the signal and
the controller determines a value larger than 180 degrees as a phase difference of the two signals.

35. The communication apparatus according to claim 32, wherein
the waveform information contains the amplitude of the signal and
the controller determines each of the amplitudes of the two signals as a third amplitude when the amplitude of the input signal is larger than a first threshold and determines the amplitude of at least one of the two signals as a fourth amplitude, which is smaller than the third amplitude, when the amplitude of the input signal is smaller than the first threshold.

36. The communication apparatus according to claim 32, wherein
the waveform information contains at least one of the amplitude and the phase of the signal and
the controller corrects at least one of the amplitude and the phase of one of the two signals based on a first amplitude as the amplitude of the input signal.

37. The communication apparatus according to claim 32, wherein
the waveform information contains at least one of the amplitude and the phase of the signal and
the controller determines at least one of the amplitude and the phase of one of the two signals based on a first amplitude as the amplitude of the input signal such that a difference of the output characteristics of the two amplifiers is compensated for.

38. The communication apparatus according to claim 32, wherein
the waveform information contains the phase of the signal and
the controller determines a phase difference of the two signals based on a linear function of a first amplitude as an amplitude of the input signal.

39. The communication apparatus according to claim 32, wherein
each of the two amplifiers performs the amplification by performing a saturated operation and
when an amplitude of the input signal is smaller than a second threshold, the controller controls at least one of the two amplifiers such that a state of the amplifier is brought closer to an unsaturated operation state in which the amplifier performs an unsaturated operation.

40. An amplification method comprising:
decomposing an input signal into two signals having different phases;
amplifying the decomposed two signals by two amplifiers, respectively;
combining output the amplifiers by a combiner; and
controlling at least one of waveform information of at least one of the two signals and an operating state of the two amplifiers such that an output characteristic of the combiner matches a desired characteristic.
